(19) United States
(12) Patent Application Publication
(10) Pub. No.: US 2026/0231744 A1
(43) Pub. Date: Aug. 6, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Yi-Hsiang CHAO, New Taipei City (TW); Sheng-Hsuan LIN, Zhubei City (TW); Pei-Hsuan LEE, Taipei City (TW); Chia-Han LAI, Zhubei City (TW); Min-Hsiu HUNG, Tainan City (TW); Chih-Chien CHI, Hsinchu City (TW); Chih-Wei CHANG, Hsin-Chu (TW); Wei-Jung LIN, Hsinchu City (TW); Ming-Hsing TSAI, Chu-Pei City (TW)

(21) Appl. No.: 19/230,644

(22) Filed: Jun. 6, 2025

Related U.S. Application Data
(60) Provisional application No. 63/754,946, filed on Feb. 6, 2025.

(51) Int. Cl. H01L 21/768; H01L 23/522

(52) U.S. Cl. CPC H10W 20/042; H10W 20/056; H10W 20/081; H10W 20/42

(57) ABSTRACT

Electrically conductive material of an interconnect structure in an interconnect layer of a semiconductor device is deposited in a manner that reduces the likelihood of void formation in the interconnect structure. A recess may be formed in a dielectric layer in the interconnect layer. A seed layer may be deposited on sidewalls and on a bottom surface of the recess. An oxidation treatment operation may be performed to oxidize portions of the seed layer on the sidewalls of the recess, and an etch operation may be performed to etch the seed layer to remove the oxidized portions of the seed layer from the sidewalls. The remaining portions of the seed layer at the bottom of the recess is then used as a base on which additional material of the interconnect structure is deposited.

### CROSS-REFERENCE TO RELATED APPLICATION

This Patent Application claims priority to U.S. Provisional Patent Application No. 63/754,946, filed on Feb. 6, 2025, and entitled “SEMICONDUCTOR DEVICE AND METHODS OF FORMATION.” The disclosure of the prior Application is considered part of and is incorporated by reference into this Patent Application.

### BACKGROUND

An interconnect layer (sometimes referred to as a back end region or a back end of line (BEOL) region) is a region of a semiconductor device that includes a plurality of layers of conductive structures that are arranged to carry signals and/or to provide power distribution throughout the semiconductor device. The plurality of layers of conductive structures may include various vertically-arranged layers of interconnect structures (e.g., vias) and layers of metallization structures (e.g., trenches, conductive lines, traces).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1D are diagrams of a portion of an example semiconductor device described herein.

FIGS. 2A-2D are diagrams of an example implementation of forming a device layer (or a portion thereof) a semiconductor device described herein.

FIGS. 3A-3O are diagrams of an example implementation of forming an interconnect layer (or a portion thereof) of a semiconductor device described herein.

FIGS. 4A-4E are diagrams of examples of interconnect structures that may be included in a semiconductor device described herein.

FIGS. 5A-5K are diagrams of an example implementation of forming an interconnect layer (or a portion thereof) of a semiconductor device described herein.

FIGS. 6A-6E are diagrams of examples of interconnect structures that may be included in a semiconductor device described herein.

FIGS. 7A-7I are diagrams of an example implementation of forming an interconnect layer (or a portion thereof) of a semiconductor device described herein.

FIG. 8 is a diagram of an example of an interconnect structure that may be included in a semiconductor device described herein.

FIG. 9 is a diagram of an example of an interconnect structure that may be included in a semiconductor device described herein.

FIG. 10 is a flowchart of an example process associated with forming a semiconductor device described herein.

FIG. 11 is a flowchart of an example process associated with forming a semiconductor device described herein.

FIGS. 12A-12E are diagrams of examples of interconnect structures that may be included in a semiconductor device described herein.

FIGS. 13A-13E are diagrams of examples of interconnect structures that may be included in a semiconductor device described herein.

FIGS. 14A-14I are diagrams of an example implementation of forming an interconnect layer (or a portion thereof) of a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An interconnect layer of a semiconductor device may be formed above a device layer of the semiconductor device. The device layer may include a substrate layer of the semiconductor device and integrated circuit devices (e.g., transistors, capacitor, diodes, memory cells) in and/or on the semiconductor substrate. A layer of contact structures (referred to as source/drain contacts) may be included between the integrated circuit devices and the interconnect layer, and may electrically connect the integrated circuit devices to a bottom-most layer of conductive structures. The bottom-most layer of conductive structures in the interconnect layer may include source/drain interconnect structures coupled to source/drain regions of the integrated circuit devices and/or gate interconnect structures coupled to gate structures of the integrated circuit devices.

To form an interconnect structure (e.g., a source/drain interconnect structure, a gate interconnect structure) in the bottom-most layer of conductive structures in the interconnect layer, a recess may be formed through one or more dielectric layers to expose the top surface of a contact structure and/or the top surface of a gate structure. The electrically conductive material of the interconnect structure may then be deposited in the recess such that the electrically conductive material fills in the recess.

In some cases, voids and/or other defects may occur in an interconnect structure formed in an interconnect layer of a semiconductor device. A void may occur where the electrically conductive material does not completely fill in a recess in which the interconnect structure is formed. These voids and/or other defects may increase the electrical resistance of the interconnect structure and/or may lead to an electrical disconnect (e.g., an open circuit) between a layer of conductive structures in the interconnect layer and a contact structure or a gate structure of an integrated circuit device in a device layer of the semiconductor device. This may decrease the performance of the semiconductor device and/or may decrease the yield of semiconductor devices formed on a semiconductor substrate.

In some implementations described herein, electrically conductive material of an interconnect structure (e.g., a source/drain interconnect structure, a gate interconnect structure) in an interconnect layer of a semiconductor device is deposited in a manner that reduces the likelihood of void formation in the interconnect structure. A recess may be formed in a dielectric layer in the interconnect layer. A seed layer may be deposited on sidewalls and on a bottom surface of the recess. An oxidation treatment operation may be performed to oxidize portions of the seed layer on the sidewalls of the recess, and an etch operation may be performed to etch the seed layer to remove the oxidized portions of the seed layer from the sidewalls. The remaining portions of the seed layer at the bottom of the recess is then used as a base on which additional material of the interconnect structure is deposited. The seed layer at the bottom of the recess facilitates bottom-up growth of the interconnect structure with minimal to no growth from the sidewalls of the recess, which reduces the likelihood that the electrically conductive material will coalesce at the top of the recess and form a void. In this way, the interconnect structure may be formed substantially free of voids, which enables a low electrical resistance to be achieved for the interconnect structure and reduces the likelihood of an electrical open circuit being formed in the interconnect structure. This enables a high performance and a high yield to be achieved for semiconductor devices formed on a semiconductor substrate.

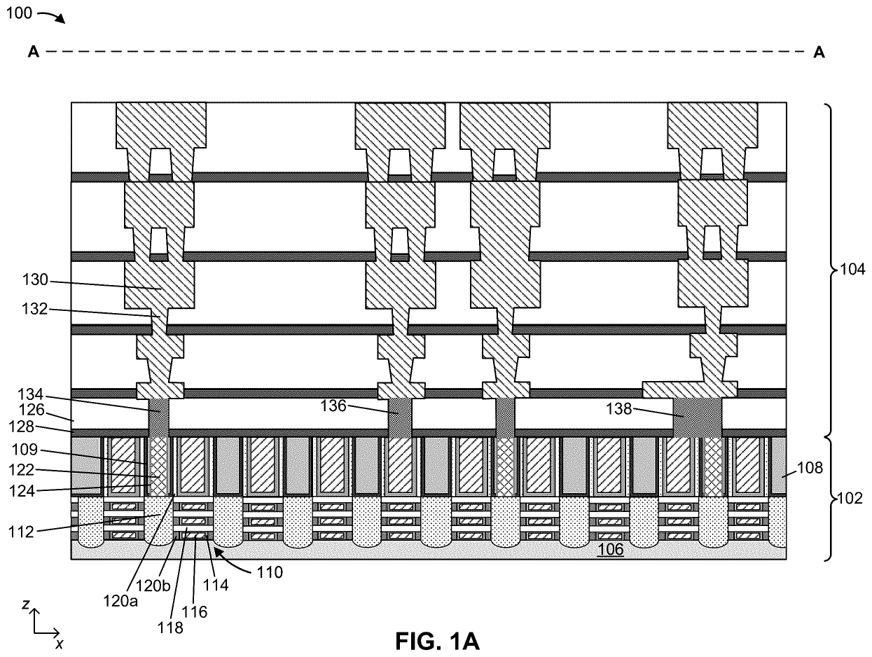

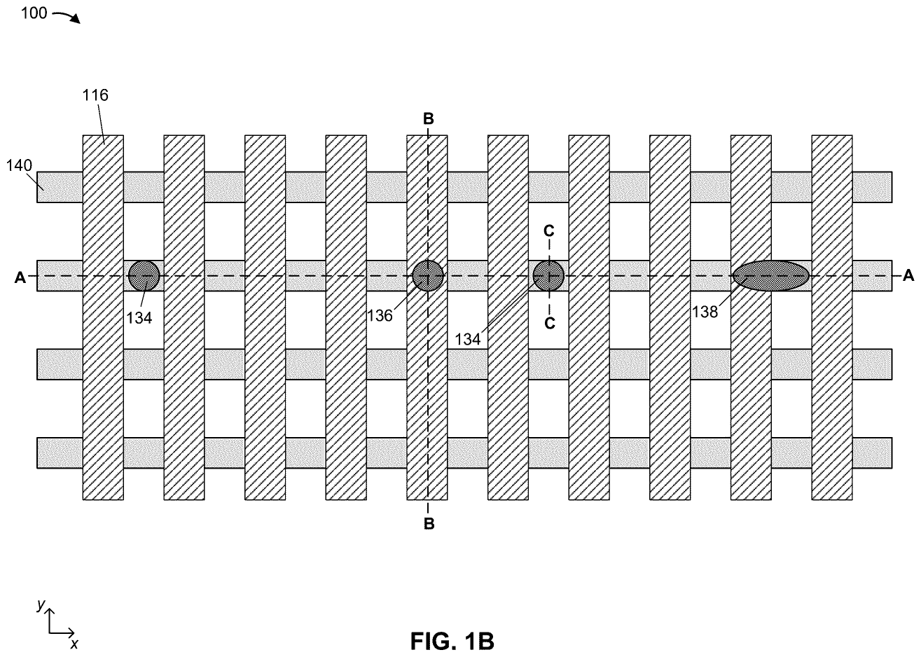

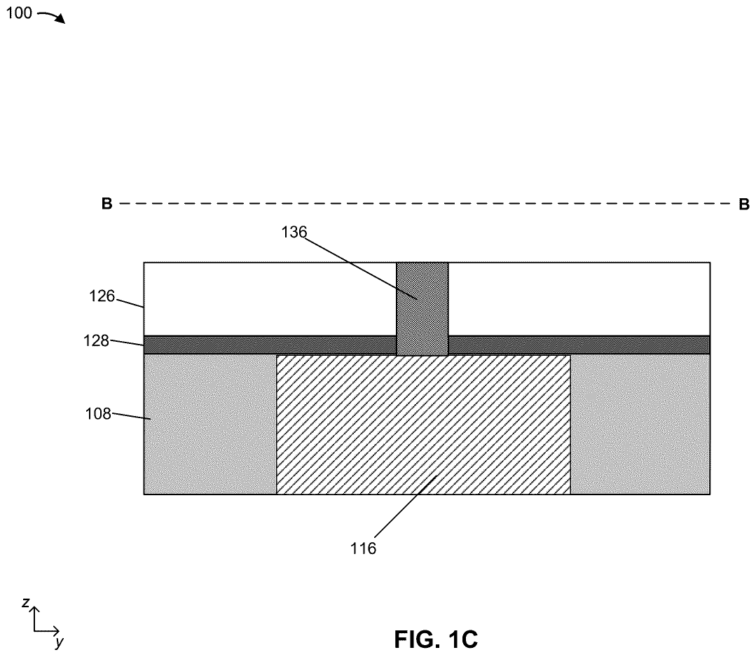

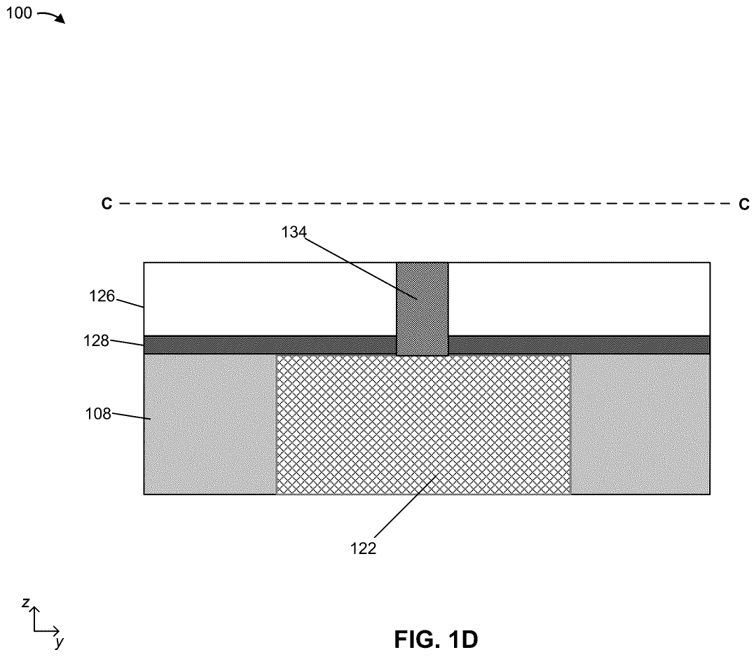

FIGS. 1A-1D are diagrams of a portion of an example semiconductor device 100 described herein. The semiconductor device 100 may include a system on chip (SoC) device, a logic device such as a central processing unit (CPU) or a graphics processing unit (GPU), a memory device (e.g., a high bandwidth memory (HBM) device), a panel driver device, an integrated circuit (IC) driver, a radio frequency (RF) power amplifier, a display driver IC (DDIC), and/or another type of semiconductor device.

As shown in FIG. 1A, the semiconductor device 100 may include a device layer 102 and an interconnect layer 104 above the device layer 102 in a z-direction in the semiconductor device 100. The device layer 102 includes a substrate layer 106. The substrate layer 106 may correspond to a portion of a semiconductor wafer on which the semiconductor device 100 is formed. The substrate layer 106 includes a silicon (Si) substrate, a substrate formed of a material including silicon, a III-V compound semiconductor material substrate such as gallium arsenide (GaAs), a silicon on insulator (SOI) substrate, or another type of semiconductor substrate. The substrate layer 106 may extend in an x-direction and/or in a y-direction in the semiconductor device 100.

A dielectric layer 108 is included over the substrate layer 106. The dielectric layer 108 includes an interlayer dielectric (ILD) layer (e.g., an ILD0 layer), an etch stop layer (ESL), and/or another type of dielectric layer. The dielectric layer 108 includes dielectric material(s) that enable various portions of the substrate layer 106 to be selectively etched or protected from etching, and/or may electrically isolate integrated circuit devices 110 in the device layer 102. The dielectric layer 108 includes an oxide (e.g., a silicon oxide (SiOₓ) and/or another oxide material), and/or another type of dielectric material. The dielectric layer 108 may extend in the x-direction and/or in a y-direction in the semiconductor device 100.

The dielectric layer 108 may be included on a contact etch stop layer (CESL) 109. The CESL 109 may wrap around the sides and bottoms of the portions of the dielectric layer 108. The CESL 109 may include a silicon nitride (SiₓN_{y}) material and/or another suitable dielectric material that is different from the material of the dielectric layer 108.

The integrated circuit devices 110 may be included in and/or on the substrate layer 106, and/or in the dielectric layer 108 in the device layer 102 of the semiconductor device 100. The integrated circuit devices 110 include transistors (e.g., planar transistors, fin field effect transistors (finFETs), gate all around (GAA) transistors), pixel sensors, capacitors, resistors, inductors, photodetectors, transceivers, transmitters, receives, optical circuits, and/or other types of semiconductor devices.

An integrated circuit device 110 may include a plurality of source/drain regions 112 that are grown and/or otherwise formed on and/or around portions of the substrate layer 106. “Source/drain region(s)” may refer to a source or a drain, individually or collectively, dependent upon the context. The source/drain regions 112 may be formed by epitaxially growing doped semiconductor regions and/or by another semiconductor process. In some implementations, the source/drain regions 112 are formed in recessed portions in the substrate layer 106. The recessed portions may be formed by strained source/drain (SSD) etching of the substrate layer 106 and/or another type etching operation. In some implementations, the source/drain regions 112 are formed in recesses that are formed in an alternating stack of channel layers and sacrificial layers (e.g., silicon germanium (SiGe) layers).

An integrated circuit device 110 may further include a gate dielectric layer 114 between a gate structure 116 and channel layers 118 of the integrated circuit device 110. The channel layers 118 may extend between the source/drain regions 112 of the integrated circuit device 110, and gate dielectric layer 114 and the gate structure 116 may wrap around two or more sides of the channel layers 118. In some implementations, the gate dielectric layer 114 and the gate structure 116 wrap around all four sides of the channel layers 118. In these implementations, the integrated circuit device 110 may be referred to as a nanostructure transistor such as a GAA transistor.

The channel layers 118 may include nanoscale layers of semiconductor material, such as silicon (Si), silicon germanium (SiGe), and/or doped silicon, among other examples. The channel layers 118 may be formed from silicon nanosheets that are formed as part of a nanosheet stack above the substrate layer 106.

In some implementations, the gate dielectric layer 114 includes a low dielectric constant (low-k) dielectric material such as silicon oxide (SiOₓ). In some implementations, the gate dielectric layer 114 includes a high dielectric constant (high-k) dielectric material such as hafnium oxide (HfOₓ).

The gate structure 116 may be located laterally between the source/drain regions 112. In some implementations, the gate structure 116 is formed of a polysilicon material. In these implementations, the polysilicon material may be doped with one or more types of dopants (e.g., p-type dopants, n-type dopants) to tune a work function of the gate structure 116.

In some implementations, the gate structure 116 is formed of one or more metal materials (e.g., tungsten (W), titanium (Ti), cobalt (Co), and/or another metal). In these implementations, the gate structure 116 may include one or more work function metal layers (e.g., p-type metal layers, n-type metal layers) for tuning the work function of the gate structure 116. The work function metal layer(s) may be included between the gate dielectric layer 114 and the gate structure 116.

A p-type work function metal layer may include one or more p-type metals, such as tungsten (W), cobalt (Co), titanium nitride (TiN), tungsten nitride (WN), and/or another metal having a work function that is greater than approximately 4.7 electron volts (eV), among other examples. A p-type work function metal layer may be included to tune the work function of the gate structure 116 such that the work function is adjusted close to the valence band of the material of the channel layers 118.

An n-type work function metal layer may include one or more metal materials that tune or adjust the work function of the gate structure 116 near the conduction band of the material of the channel layers 118 of the semiconductor device 100. In some implementations, an n-type work function metal layer may include titanium aluminum (TiAl). In some implementations, an n-type work function metal layer includes titanium aluminum carbon (TiAlC). In some implementations, an n-type work function metal layer may include another aluminum-containing metal. In some implementations, another n-type metal material is included in an n-type work function metal layer.

Various spacers may be included in the integrated circuit devices 110. For example, sidewall spacers 120a may be included on the sidewalls of the gate structure 116 to provide electrical isolation for the gate structure 116, among other examples. In some implementations, the sidewall spacers 120a are in contact with the gate dielectric layer 114 and the CESL 109. In some implementations, the sidewall spacers 120a are in contact with the work function metal layer. The ends of the channel layers 118 interfaced with a gate structure 116 may be aligned with outer sidewalls of the sidewall spacers 120a on opposing sides of the gate structure 116. The sidewall spacers 120a may include a silicon oxide (SiOₓ), a silicon nitride (SiₓN_{y}), a silicon oxycarbide (SiOC), a silicon oxycarbonitride (SiOCN), and/or another suitable material.

As another example, inner spacers 120b may be included laterally between the gate structure 116 and the source/drain regions 112 of an integrated circuit device 110. The inner spacer 120b may be included to reduce parasitic capacitance in the integrated circuit device 110 and to protect the source/drain regions 112 from being etched in a nanosheet release operation to remove sacrificial layers between the channel layers 118. The inner spacers 120b may include a silicon nitride (SiₓN_{y}), a silicon oxide (SiOₓ), a silicon oxynitride (SiON), a silicon oxycarbide (SiOC), a silicon carbon nitride (SiCN), a silicon oxycarbonitride (SiOCN), and/or another dielectric material.

The source/drain regions 112 are electrically coupled and/or physically coupled with source/drain contact structures 122. A source/drain contact structure 122 may extend through a portion of the dielectric layer 108 and an associated CESL 109. The source/drain contact structures 122 may include contact vias, contact plugs, and/or another type of contact structures that electrically connect the source/drain regions 112 of the integrated circuit devices 110 with the interconnect layer 104 of the semiconductor device 100. The source/drain contact structures 122 include cobalt (Co), ruthenium (Ru), tungsten (W), molybdenum (Mo), copper (Cu), and/or another electrically conductive material or metal material. One or more liner layers 124 may be included on sidewalls of the source/drain contact structures 122. The liner layer(s) 124 may include a barrier layer that is included to prevent or minimize diffusion of materials from the source/drain contact structures 122 to the surrounding dielectric layers, an adhesion layer or glue layer that is included to promote adhesion between the source/drain contact structures 122 and the surrounding dielectric layers, and/or another type of liner. Examples of materials for the liner layer(s) 124 include titanium nitride (TiN), tantalum nitride (TaN), and/or another suitable liner material.

The interconnect layer 104 of the semiconductor device 100 is included above the device layer 102 and above the integrated circuit devices 110 in the z-direction in the semiconductor device 100. The interconnect layer 104 includes a plurality of dielectric layers that are arranged in a direction (e.g., the z-direction) that is approximately perpendicular to the substrate layer 106. The dielectric layers may include ILD layers 126 and ESLs 128 that are arranged in an alternating manner in the z-direction. The ILD layers 126 and the ESLs 128 may extend in the x-direction and/or in the y-direction in the semiconductor device 100.

The ILD layers 126 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 126 includes an extreme low dielectric constant (ELK) dielectric material having a dielectric constant that is less than approximately 2.5. Examples of ELK dielectric materials include carbon doped silicon oxide (C-SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples.

The ESLs 128 may each include a silicon nitride (SiₓN_{y}), silicon carbide (SiC), silicon oxynitride (SiON), and/or another suitable dielectric material. In some implementations, an ILD layer 126 and an ESL 128 include different dielectric materials to provide etch selectivity to enable various structures to be formed in the interconnect layer 104.

The interconnect layer 104 may further include a plurality of layers of conductive structures in the dielectric layers (e.g., the ILD layers 126 and the ESLs 128) of the interconnect layer 104. The conductive structures in the interconnect layer 104 may be interconnected to enable signals and/or power to be distributed throughout the semiconductor device 100 through the interconnect layer 104. The conductive structures include a combination of metallization structures 130 and interconnect structures 132. The metallization structures 130 may include trenches, conductive traces, and/or other types of conductive structures that primarily extend in the x-direction and/or in the y-direction in the interconnect layer 104. The interconnect structures 132 may include vias, plugs, conductive columns, and/or other types of conductive structures that primarily extend in the z-direction in the semiconductor device. In some implementations, a conductive structure in the interconnect layer 104 includes a dual damascene structure, which includes a combination of a metallization structure 130 and an interconnect structure 132.

The metallization structures 130 and the interconnect structures 132 may each include one or more electrically conductive materials such as tungsten (W), cobalt (Co), ruthenium (Ru), molybdenum (Mo), titanium (Ti), aluminum (Al), copper (Cu), gold (Au), and/or a combination thereof, among other examples of electrically conductive materials. In some implementations, one or more liner layers are included between the metallization structures 130 and/or the interconnect structures 132 and the surrounding dielectric layers in the interconnect layer 104. The one or more liner layers may include barrier liners, adhesion liners, and/or another type of liners. Examples of materials for the one or more liners include tantalum nitride (TaN) and/or titanium nitride (TiN), among other examples.

In some implementations, the metallization structures 130 and the interconnect structures 132 of the interconnect layer 104 may be arranged in a vertical manner (e.g., in the z-direction). In other words, a plurality of stacked metallization structures 130 and interconnect structures 132 may extend between the device layer 102 and a top of the interconnect layer 104 to facilitate electrical signals and/or power to be routed between the device layer 102 and connection structures (not shown) of the semiconductor device 100.

The plurality of stacked metallization structures 130 may be arranged in layers that may be referred to as M-layers, and the plurality of stacked interconnect structures 132 may be arranged in layers that may be referred to as V-layers. A bottom-most layer of interconnect structures 132 in the interconnect layer 104 may be referred to as a V0 layer. The V0 layer may include source/drain interconnect structures 134 that are electrically coupled and/or physically coupled to the source/drain contact structures 122 of one or more integrated circuit devices 110. The V0 layer may also include one or more gate interconnect structures 136 that are electrically coupled and/or physically coupled to the gate structures 116 of one or more integrated circuit devices 110. The source/drain interconnect structures 134 are referred to source/drain vias (VDs), and the gate interconnect structures 136 are referred to as gate vias (VGs). In some implementations, gate contacts (not shown) are included between the gate structures 116 and the gate interconnect structures 136.

As further shown in FIG. 1A, in some implementations, the V0 layer may include one or more merged interconnect structures 138. A merged interconnect structure 138 is a combination of a source/drain interconnect structure 134 and a gate interconnect structure 136. A portion of the merged interconnect structure 138 is located over and electrically coupled to a gate structure 116, and another portion of the merged interconnect structure 138 is located over and electrically coupled to a source/drain contact structure 122. Thus, the merged interconnect structure 138 electrically coupled the gate structure 116 and the source/drain contact structure 122 together.

The source/drain interconnect structures 134, the gate interconnect structures 136, and the merged interconnect structures 138 may each include one or more electrically conductive materials such as tungsten (W), cobalt (Co), ruthenium (Ru), molybdenum (Mo), titanium (Ti), aluminum (Al), copper (Cu), gold (Au), and/or a combination thereof, among other examples of electrically conductive materials. In some implementations, one or more liner layers are included between the source/drain interconnect structures 134, the gate interconnect structures 136, the merged interconnect structures 138 and the surrounding dielectric layers in the interconnect layer 104. The one or more liner layers may include barrier liners, adhesion liners, and/or another type of liners. Examples of materials for the one or more liners include tantalum nitride (TaN) and/or titanium nitride (TiN), among other examples.

A bottom-most layer of metallization structures 130 coupled to the bottom-most layer of interconnect structures 132 may be referred to as a metal-0 (M0) layer, and may be located above the bottom-most layer of interconnect structures 132 (e.g., the layer that includes the source/drain interconnect structures 134, the gate interconnect structures 136, and the merged interconnect structures 138) in the interconnect layer 104. Thus, the metallization structures 130 in the M0 layer may be electrically coupled and/or physically coupled with the source/drain interconnect structures 134, the gate interconnect structures 136, and/or the merged interconnect structures 138.

Additional layers of conductive structures may be arranged in a similar manner in the interconnect layer 104. For example, a layer of interconnect structures 132 may be referred to as a via-1 (V1) layer that is located above and electrically coupled and/or physically coupled to the layer of metallization structures 130 in the M0 layer. A layer of metallization structures 130 may be referred to as a metal-1 (M1) layer that is located above and electrically coupled and/or physically coupled to the layer of interconnect structures 132 in the V1 layer. A layer of interconnect structures 132 may be referred to as a via-2 (V2) layer that is located above and electrically coupled and/or physically coupled to the layer of metallization structures 130 in the M1 layer. A layer of metallization structures 130 may be referred to as a metal-2 (M2) layer that is located above and electrically coupled and/or physically coupled to the layer of interconnect structures 132 in the V2 layer. A layer of interconnect structures 132 may be referred to as a via-3 (V3) layer that is located above and electrically coupled and/or physically coupled to the layer of metallization structures 130 in the M2 layer. A layer of metallization structures 130 may be referred to as a metal-3 (M3) layer that is located above and electrically coupled and/or physically coupled to the layer of interconnect structures 132 in the V3 layer. A layer of interconnect structures 132 may be referred to as a via-4 (V4) layer that is located above and electrically coupled and/or physically coupled to the layer of metallization structures 130 in the M3 layer. A layer of metallization structures 130 may be referred to as a metal-4 (M4) layer that is located above and electrically coupled and/or physically coupled to the layer of interconnect structures 132 in the V4 layer. In some implementations, the interconnect layer 104 includes a different quantity of layers of metallization structures 130 and/or a different quantity of layers of interconnect structures 132 than the quantities shown in FIG. 1A.

FIG. 1B illustrates a top view of a portion of the semiconductor device 100. As shown in FIG. 1B, the gate structures 116 of the integrated circuit devices 110 of the semiconductor device 100 may extend in the y-direction across one or more fin structures 140 of the integrated circuit devices 110. The fin structures 140 include the stacks of channel layers 118 that extend in the x-direction. The source/drain regions 112 (not shown for purposes of clarity) of the integrated circuit devices 110 may be located on the fin structures 140 on opposing sides of a gate structure 116.

As further shown in FIG. 1B, a source/drain interconnect structure 134 may be located over a fin structure 140 laterally between gate structures 116 in the x-direction. A gate interconnect structure 136 may be located over a gate structure 116. A merged interconnect structure 138 may be located over a gate structure 116 and an adjacent source/drain contact structure 122.

FIG. 1B further illustrates the locations of various cross-section views, including a cross-section view along a line A-A (which is illustrated in FIG. 1A), a cross-section view along a line B-B (which is illustrated in FIG. 1C), and a cross-section view along line C-C (which is illustrated in FIG. 1D).

FIG. 1C illustrates the cross-section view of a portion of the semiconductor device 100 along the line B-B in FIG. 1B. The cross-section view illustrated in FIG. 1C includes a y-direction cross-section view of a gate interconnect structure 136. As shown in FIG. 1C, the gate interconnect structure 136 may be located above and/or on a gate structure 116 of an integrated circuit device 110 of the semiconductor device 100. As shown in the example in FIG. 1C, the gate interconnect structure 136 may have substantially vertical sidewalls. However, in other implementations, a gate interconnect structure 136 may have angled or tapered sidewalls in the x-direction and/or in the y-direction.

FIG. 1D illustrates the cross-section view of a portion of the semiconductor device 100 along the line C-C in FIG. 1B. The cross-section view illustrated in FIG. 1D includes a y-direction cross-section view of a source/drain interconnect structure 134. As shown in FIG. 1D, the source/drain interconnect structure 134 may be located above and/or on a source/drain contact structure 122 of an integrated circuit device 110 of the semiconductor device 100. As shown in the example in FIG. 1D, the source/drain interconnect structure 134 may have substantially vertical sidewalls. However, in other implementations, a source/drain interconnect structure 134 may have angled or tapered sidewalls in the x-direction and/or in the y-direction.

As indicated above, FIGS. 1A-1D are provided as an example. Other examples may differ from what is described with regard to FIGS. 1A-1D.

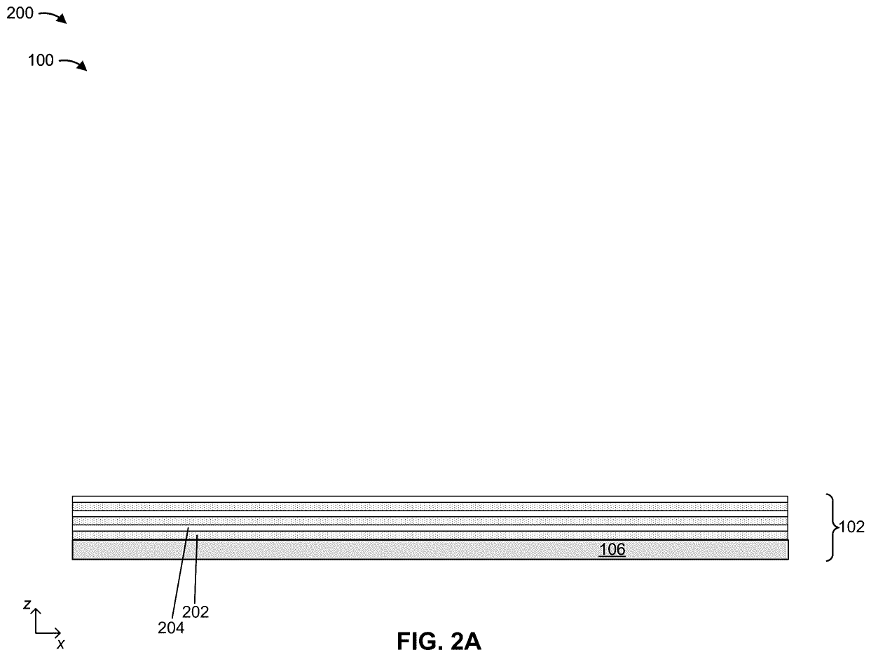

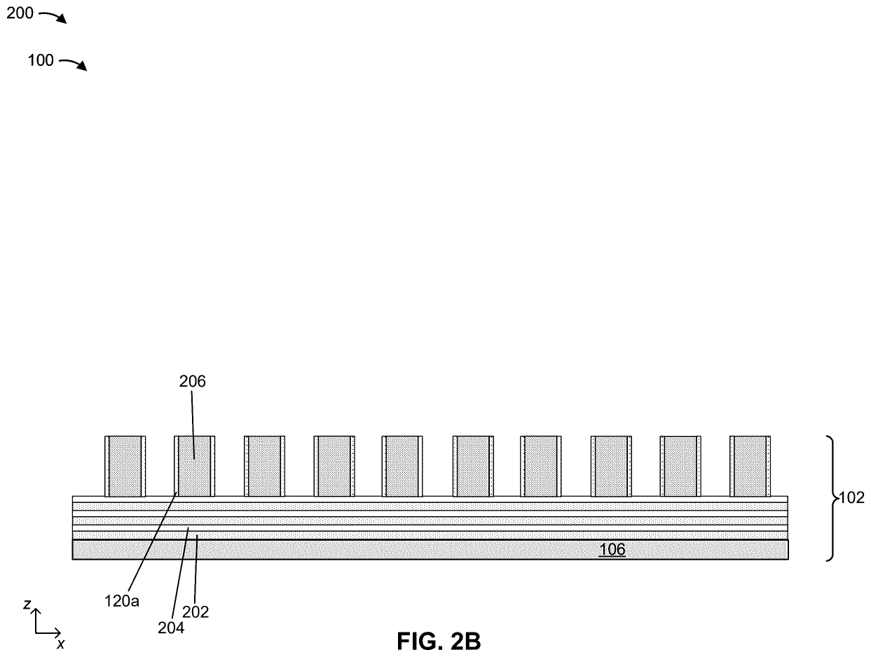

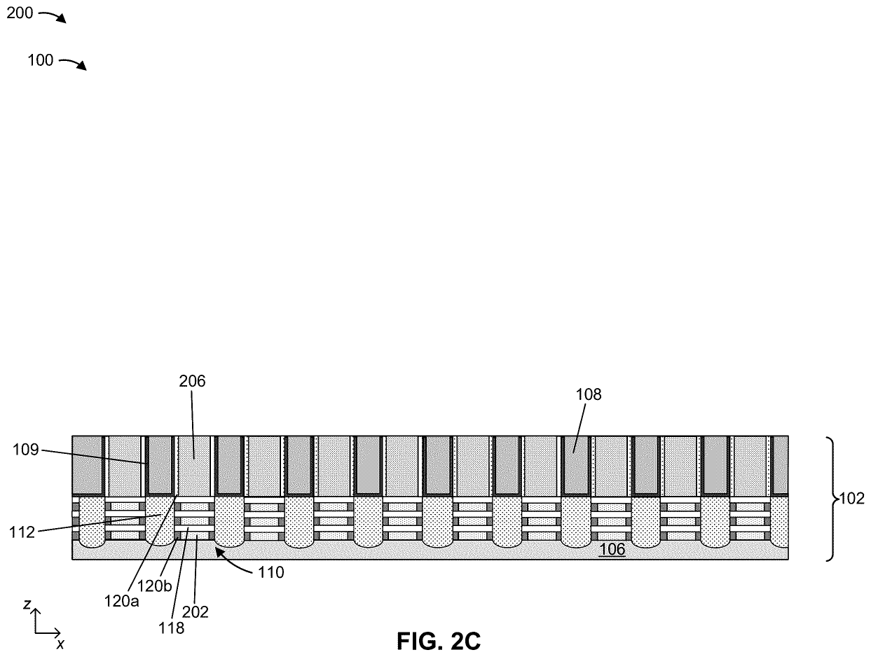

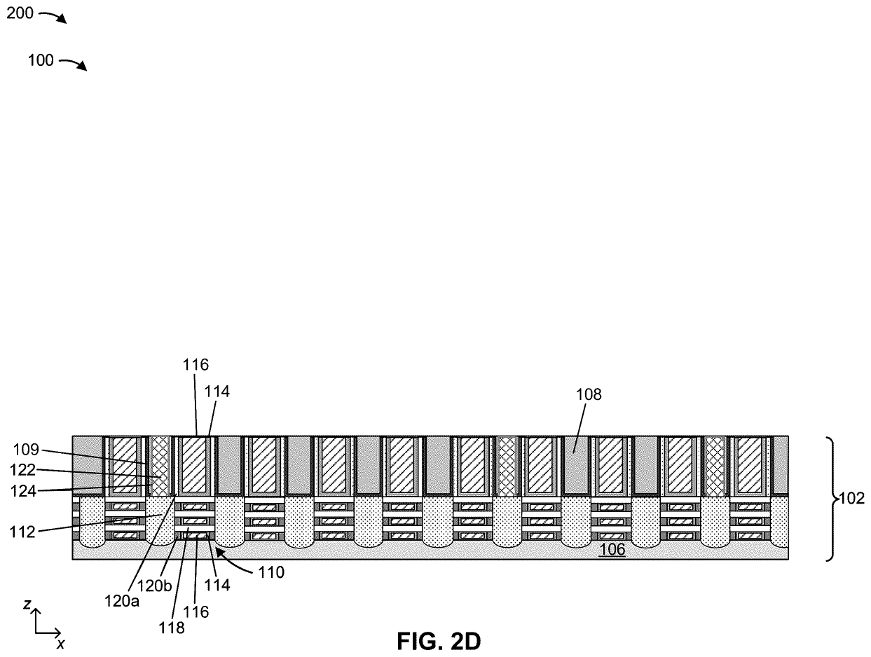

FIGS. 2A-2D are diagrams of an example implementation 200 of forming a device layer 102 (or a portion thereof) the semiconductor device 100 described herein. In some implementations, one or more of the semiconductor processing operations described in connection with FIGS. 2A-2D may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

As shown in FIG. 2A, the substrate layer 106 is provided. The substrate layer 106 may be provided in the form of a semiconductor wafer such as a silicon (Si) wafer, a silicon-on-insulator (SOI) wafer, and/or another type of semiconductor work piece. The semiconductor device 100 may be formed on the semiconductor wafer with other semiconductor devices.

A layer stack may be formed on the substrate layer 106. The layer stack may be referred to as a superlattice. The layer stack may include a plurality of alternating layers that are arranged in a direction (e.g., the z-direction) that is approximately perpendicular to the substrate layer 106. For example, the layer stack may include vertically alternating layers of sacrificial layers 202 and nanostructure channel layers 204 above the substrate layer 106. The quantity of the sacrificial layers 202 and the quantity of the nanostructure channel layers 204 illustrated in FIG. 2A are examples, and other quantities of the sacrificial layers 202 and the nanostructure channel layers 204 are within the scope of the present disclosure.

The sacrificial layers 202 enable a vertical distance to be defined between adjacent nanostructure channels that are formed from the nanostructure channel layers 204, and serve as placeholder layers for subsequently-formed gate structures of the integrated circuit devices 110 of the semiconductor device 100 that are formed around the nanostructure channels.

The sacrificial layers 202 include a first material composition, and the nanostructure channel layers 204 include a second material composition. In some implementations, the first material composition and the second material composition are the same material composition. In some implementations, the first material composition and the second material composition are different material compositions. As an example, the sacrificial layers 202 may include silicon germanium (SiGe) and the nanostructure channel layers 204 may include silicon (Si). This enables the sacrificial layers 202 and/or the nanostructure channel layers 204 to be selectively etched (e.g., enables the sacrificial layers 202 and not the nanostructure channel layers 204 to be etched, enables the nanostructure channel layers 204 and not the sacrificial layers 202 to be etched) depending on the type of etchant that is used.

One or more types of deposition tools may be used to deposit and/or grow the alternating layers of the layer stack to include nanostructures (e.g., nanosheets) on the substrate layer 106. For example, a deposition tool may be used to grow the sacrificial layers 202 and/or the nanostructure channel layers 204 by epitaxial growth, which may include epitaxy techniques such as a molecular beam epitaxy (MBE), metalorganic chemical vapor deposition (MOCVD) process, and/or another suitable epitaxy technique. Additionally and/or alternatively, the sacrificial layers 202 and/or the nanostructure channel layers 204 may be deposited by chemical vapor deposition (CVD), physical vapor deposition (PVD), atomic layer deposition (ALD), and/or another suitable deposition technique.

In the y-direction, which is not visible in the view in FIG. 2A, the layer stack and the substrate layer 106 may be etched to form fin structures that extend in the x-direction. A fin structure may include a portion of the layer stack and a portion of the substrate layer 106 under the layer stack. The fin structures may be formed by patterning the one or more masking layers and etching based on a pattern formed in one or more of the masking layers. The one or more masking layers may be patterned using photolithography techniques, including double-patterning or multi-patterning techniques. An etch tool may be used to etch the layer stack and the substrate layer 106 based on the pattern using a dry etch technique (e.g., reactive ion etching), a wet etch technique, and/or a combination thereof. In some implementations, shallow trench isolation (STI) regions (not shown) may be formed between adjacent fin structures in the y-direction.

As shown in FIG. 2B, dummy gate structures 206 (also referred to as dummy gate stacks or temporary gate structures) may be formed over portions of the layer stack of sacrificial layers 202 and nanostructure channel layers 204. The dummy gate structures 206 may extend in the y-direction and may be arranged in the x-direction such that the dummy gate structures 206 are approximately perpendicular to the fin structures. The dummy gate structures 206 are sacrificial structures that are to be replaced by replacement gate structures or replacement gate stacks at a subsequent processing stage for the integrated circuit devices 110 of the semiconductor device 100. The dummy gate structures 206 may also be used to define source/drain (S/D) recesses in which source/drain regions of the nanostructure transistors are formed in the layer stack of sacrificial layers 202 and nanostructure channel layers 204.

The dummy gate structures 206 may include polycrystalline silicon (polysilicon or PO) or another material. The layers of the dummy gate structures 206 may be formed using various semiconductor processing techniques such depositing the layers of the dummy gate structures 206, patterning the layers of the dummy gate structures 206 to define the dummy gate structures 206, and/or other semiconductor processing techniques. The sidewall spacers 120a may be formed on the sidewalls of the dummy gate structures 206.

As shown in FIG. 2C, the source/drain regions 112 of the integrated circuit devices 110 are formed in the layer stack of sacrificial layers 202 and nanostructure channel layers 204. To form the source/drain regions 112, source/drain recesses may be formed through the layer stack of sacrificial layers 202 and nanostructure channel layers 204 in an etch operation. The source/drain recesses may be formed on opposing sides of a dummy gate structure 206 in the x-direction. The etch operation may be performed using the etch tool and may be referred to a strained source/drain (SSD) etch operation. In some implementations, the etch operation includes the use of a plasma etch technique, a wet chemical etch technique, and/or another type of etch technique.

Formation of the source/drain recesses may define the channel layers 118. The channel layers 118 may include silicon-based nanostructures (e.g., nanosheets or nanowires, among other examples) that function as the semiconductive channels of the integrated circuit devices 110 of the semiconductor device 100. The channel layers 118 are arranged in a direction (e.g., the z-direction) that is approximately perpendicular to the substrate layer 106. In other words, the channel layers 118 are vertically arranged or stacked above the substrate layer 106.

Prior to formation of the source/drain regions 112 in the source/drain recesses, the ends of the sacrificial layers 202 that are exposed in the source/drain recesses may be laterally etched in an etch operation, thereby forming cavities in the ends of the sacrificial layers 202. The inner spacers 120b may be formed in the cavities. To form the inner spacers 120b, a deposition tool may be used to deposit a layer of dielectric material in the cavities and along the sidewalls and bottom surface of the source/drain recesses. A CVD technique, a PVD technique, and ALD technique, and/or another deposition technique may be used to deposit the layer of dielectric material. An etch tool is used to subsequently remove excess material of the layer of dielectric material from the source/drain recesses such that remaining portions correspond to the inner spacers 120b in the cavities.

After formation of the inner spacers 120b, the source/drain recesses may be filled with one or more layers of epitaxial material to form the source/drain regions 112 in the source/drain recesses. For example, a deposition tool may be used to deposit a buffer region at the bottom of the source/drain recess, and a deposition tool may deposit a source/drain region 112 on the buffer region in the source/drain recess. In some implementations, a deposition tool is used to deposit a capping layer on the source/drain region 112 in the source/drain recess. As another example, a deposition tool may epitaxially grow a first layer of a source/drain region 112 (referred to as an L1) over an associated buffer region (which may be referred to as an L0), and may epitaxially grow a second layer of the source/drain region 112 (referred to as an L2, an L2-1, and/or an L2-2) over the first layer. The first layer may include a lightly doped silicon (e.g., doped with boron (B), phosphorous (P), and/or another dopant), and may be included as shielding layer to reduce short channel effects in the semiconductor device 100 and to reduce dopant extrusion or migration into the channel layers 118. The second layer may include a highly doped silicon or highly doped silicon germanium. The second layer may be included to provide a compressive stress in the source/drain regions 112 to reduce boron loss.

As further shown in FIG. 2C, the dielectric layer 108 may be formed over the source/drain regions 112 and around the dummy gate structures 206. The dielectric layer 108 may fill in areas between the dummy gate structures 206. In some implementations, a contact etch stop layer (CESL) is conformally deposited (e.g., by a deposition tool) over the source/drain regions 112 prior to formation of the dielectric layer 108. The dielectric layer 108 is then formed on the CESL. The CESL may provide a mechanism to stop an etch process when forming source/drain contact structures 122 for the source/drain regions 112. The CESL may be formed of a dielectric material having a different etch selectivity from adjacent layers or components. The CESL may include or may be a nitrogen containing material, a silicon containing material, and/or a carbon containing material. Furthermore, the CESL may include or may be silicon nitride (SiₓN_{y}), silicon carbon nitride (SiCN), carbon nitride (CN), silicon oxynitride (SiON), silicon carbon oxide (SiCO), or a combination thereof, among other examples. The CESL may be deposited using a deposition process, such as ALD, CVD, or another deposition technique.

As shown in FIG. 2D, a replacement gate process may be performed to replace the dummy gate structures 206 with the gate structures 116 of the integrated circuit devices 110. A dummy gate removal operation may be performed to remove the dummy gate structures 206 from the semiconductor device 100. The removal of the dummy gate structures 206 leaves behind openings (or recesses) in the dielectric layer 108, and provides access to the underlying sacrificial layers 202. The dummy gate structures 206 may be removed in one or more etch operations. Such etch operations may include a plasma etch technique, a wet chemical etch technique, and/or another type of etch technique.

The replacement gate process may include a nanostructure release operation (e.g., an SiGe release operation). The nanostructure release operation is performed to remove the sacrificial layers 202 (e.g., the silicon germanium layers). This results in openings between the channel layers 118 (e.g., the areas around the channel layers 118). The sacrificial layers 202 may be removed through the spaces that were previously occupied by the dummy gate structures 206. The nanostructure release operation may include the use of an etch tool to perform an etch operation to remove the sacrificial layers 202 based on a difference in etch selectivity between the material of the sacrificial layers 202 and the material of the channel layers 118, and between the material of the sacrificial layers 202 and the material of the inner spacers 120b. The inner spacers 120b may function as etch stop layers in the etch operation to protect the source/drain regions 112 from being etched.

The replacement gate operation includes forming gate dielectric layers 114 and gate structures (e.g., replacement gate structures) 116 of the integrated circuit devices 110 in the openings between the source/drain regions 112 and between the inner spacers 120b. In particular, the gate dielectric layers 114 and the gate structures 116 fill the areas between and around the channel layers 118 that were previously occupied by the sacrificial layers 202 such that the gate structures 116 fully wrap around the channel layers 118 and surround the channel layers 118. This increases control of the channel layers 118, increases drive current for the integrated circuit devices 110, and/or reduces short channel effects (SCEs) for the integrated circuit devices 110, among other examples. The gate structures 116 may also fill in the spaces that were previously occupied by the dummy gate structures 206. Portions of a gate structure 116 are formed in between pairs of channel layers 118 in an alternating vertical arrangement. In other words, the semiconductor device 100 includes one or more vertical stacks of alternating channel layers 118 and portions of a gate structure 116.

As further shown in FIG. 2D, the source/drain contact structures 122 of the integrated circuit devices 110 may be formed through the dielectric layer 108. The source/drain contact structures 122 may be formed in recesses in the dielectric layer 108. In some implementations, a pattern in a photoresist layer is used to etch the dielectric layer 108 to form the recesses. In these implementations, a deposition tool may be used to form the photoresist layer on the dielectric layer 108. An exposure tool may be used to expose the photoresist layer to a radiation source to pattern the photoresist layer. A developer tool may be used to develop and remove portions of the photoresist layer to expose the pattern. An etch tool may be used to etch the dielectric layer based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 108 based on a pattern to form the recesses.

The source/drain contact structures 122 may be formed in the recesses such that the source/drain contact structures 122 land on the source/drain regions 112. A deposition tool may be used to deposit the material of the source/drain contact structures 122 in the recesses using a CVD technique, a PVD technique, an ALD technique, an electroplating technique, and/or another suitable deposition technique. The material of the source/drain contact structures 122 may be deposited in one or more deposition operations. In some implementations, a seed layer is first deposited, and the material of the source/drain contact structures 122 is deposited on the seed layer. In some implementations, one or more liner layers 124 are deposited in the recesses, and the source/drain contact structures 122 are deposited on the liner layer(s) 124. In some implementations, a planarization tool is used to perform a planarization operation (e.g., a chemical-mechanical planarization (CMP) operation) to planarize the source/drain contact structures 122 after the source/drain contact structures 122 are deposited such that the tops of the source/drain contact structures 122 are approximately co-planar with the top of the dielectric layer 108.

As indicated above, FIGS. 2A-2D are provided as an example. Other examples may differ from what is described with regard to FIGS. 2A-2D.

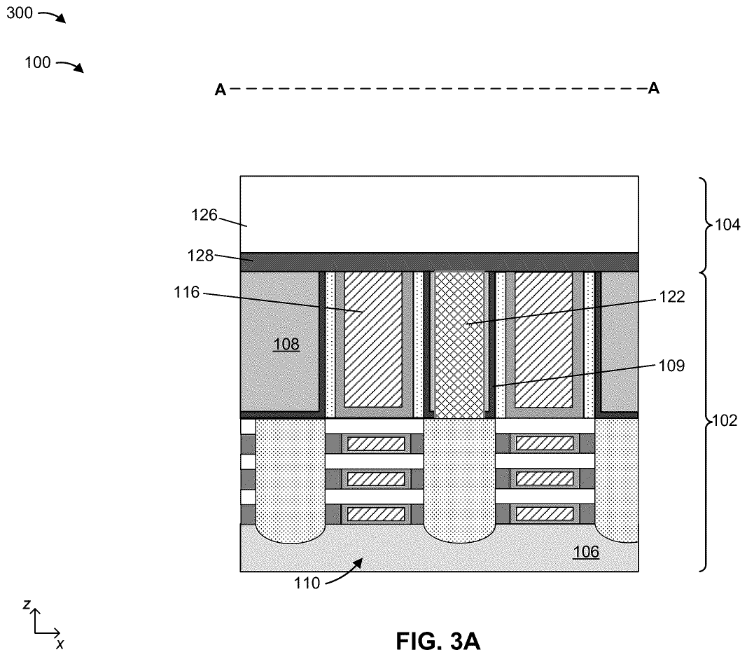

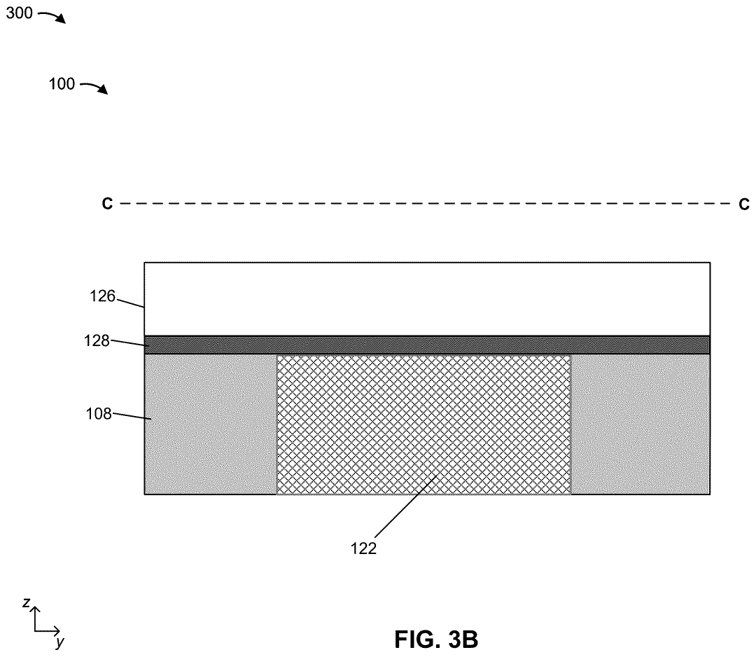

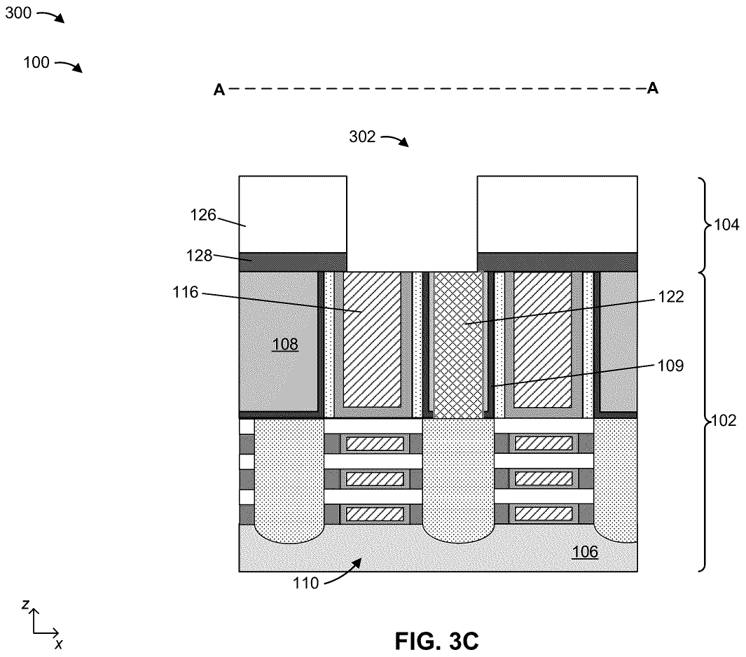

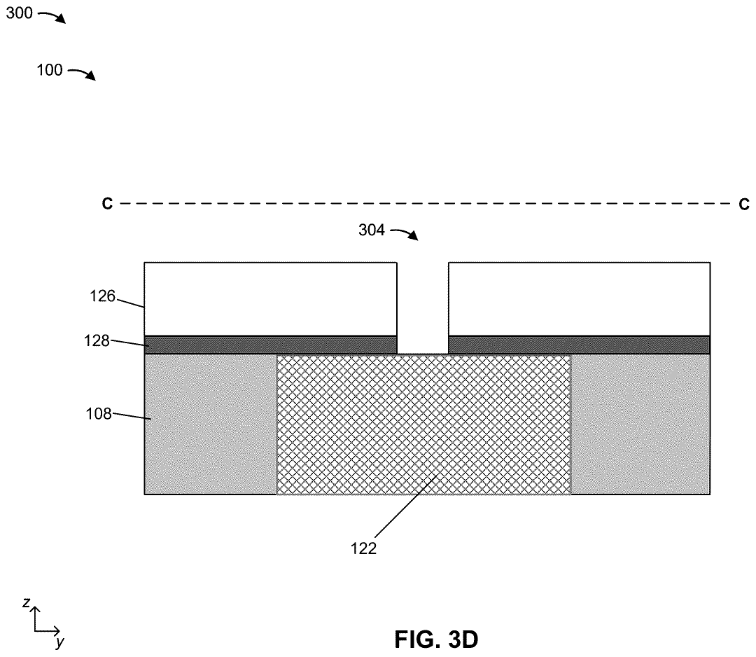

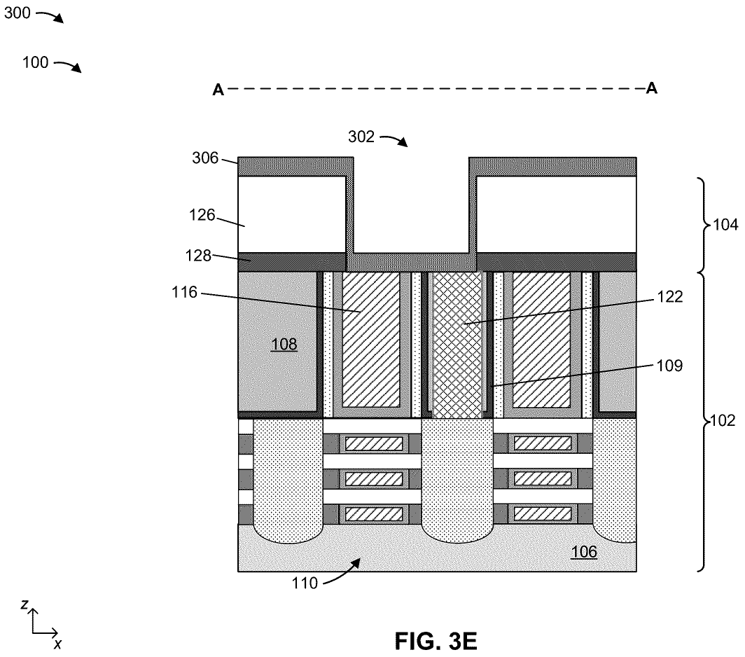

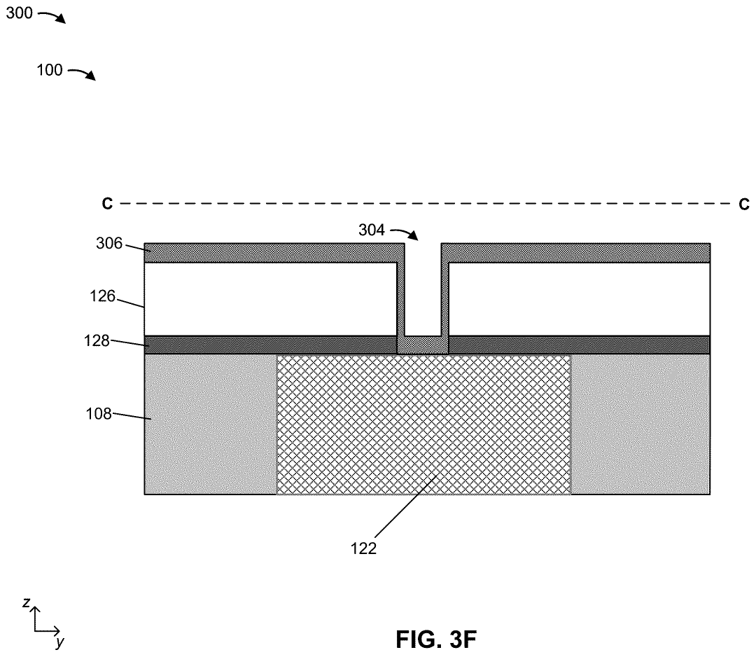

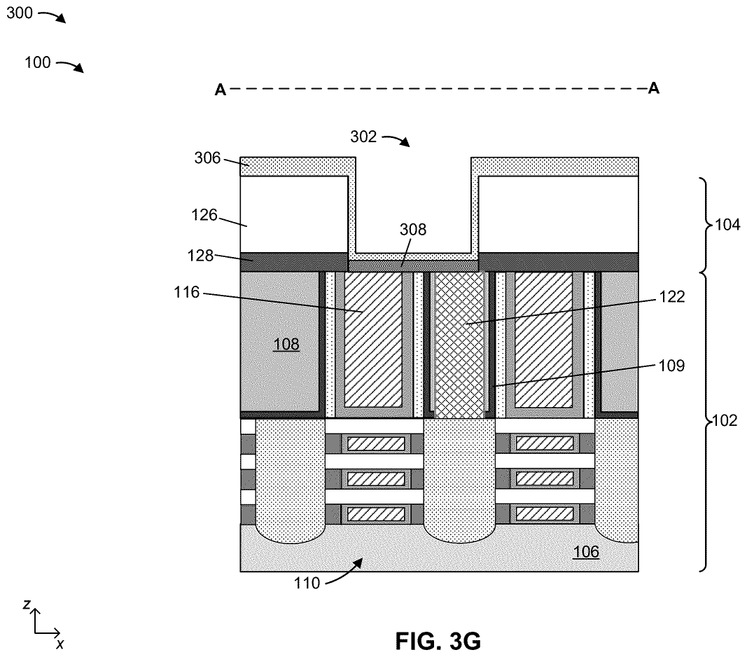

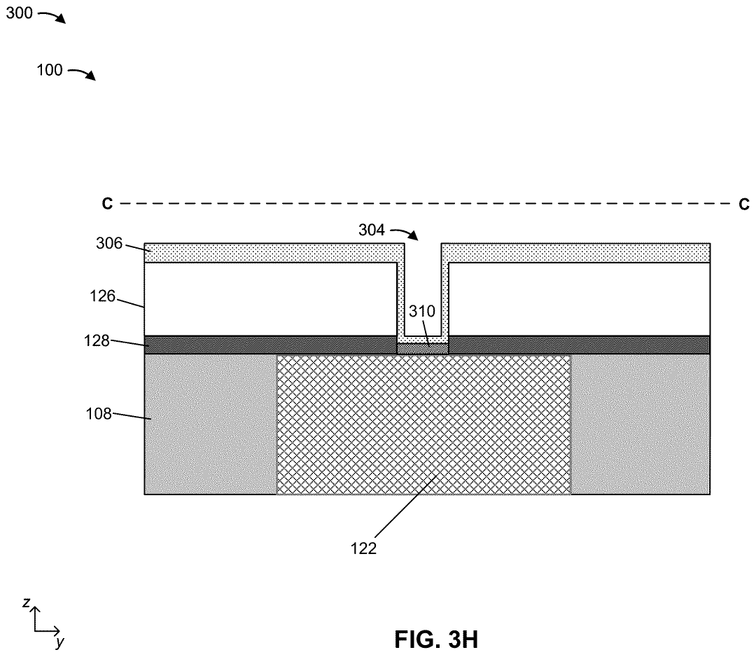

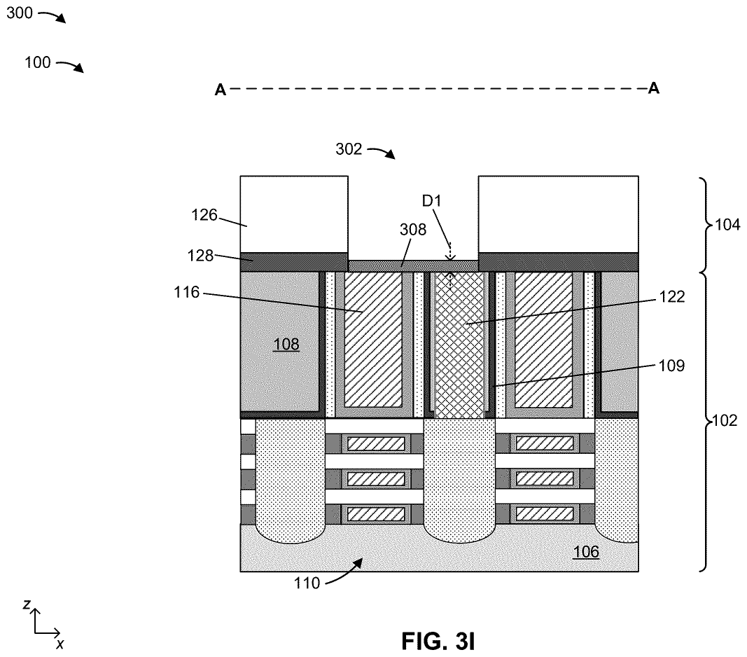

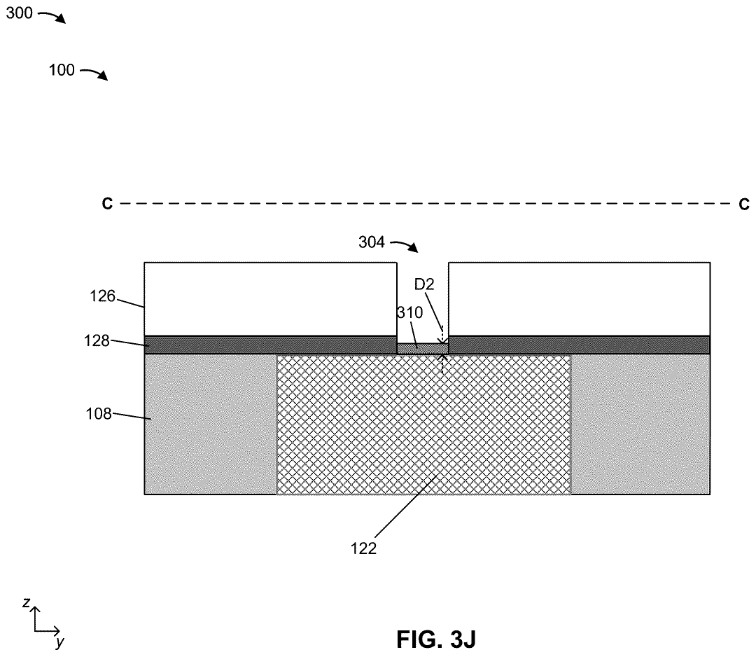

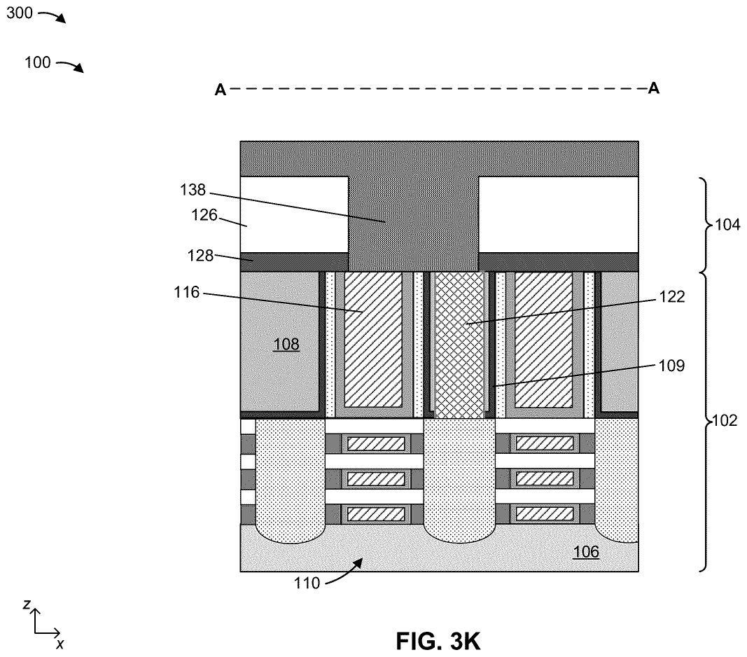

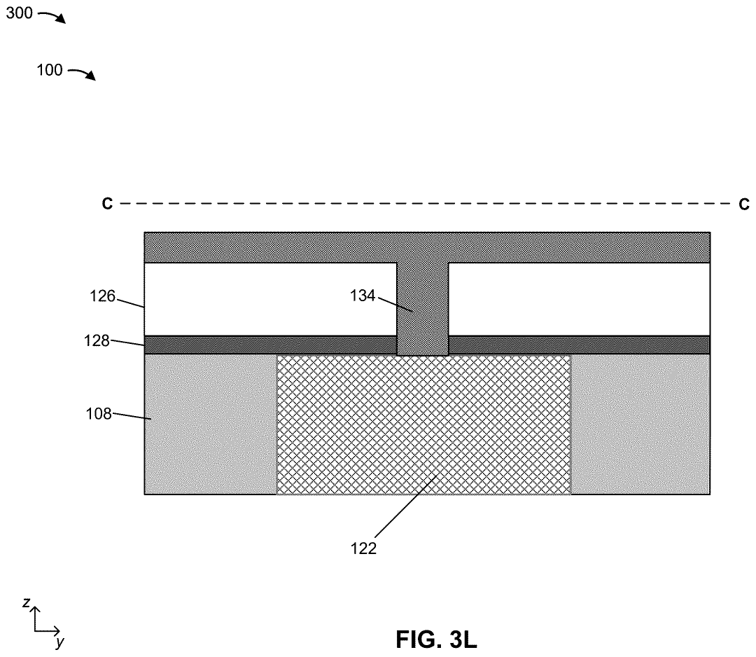

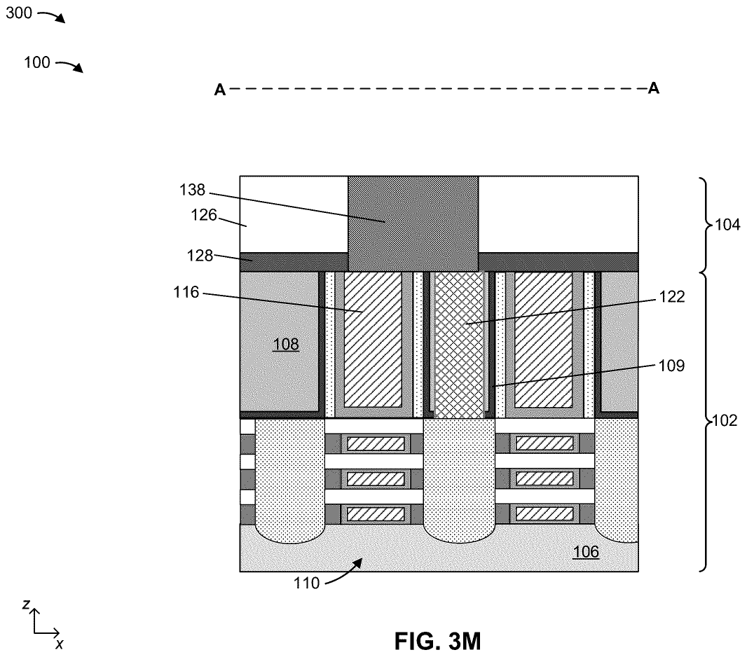

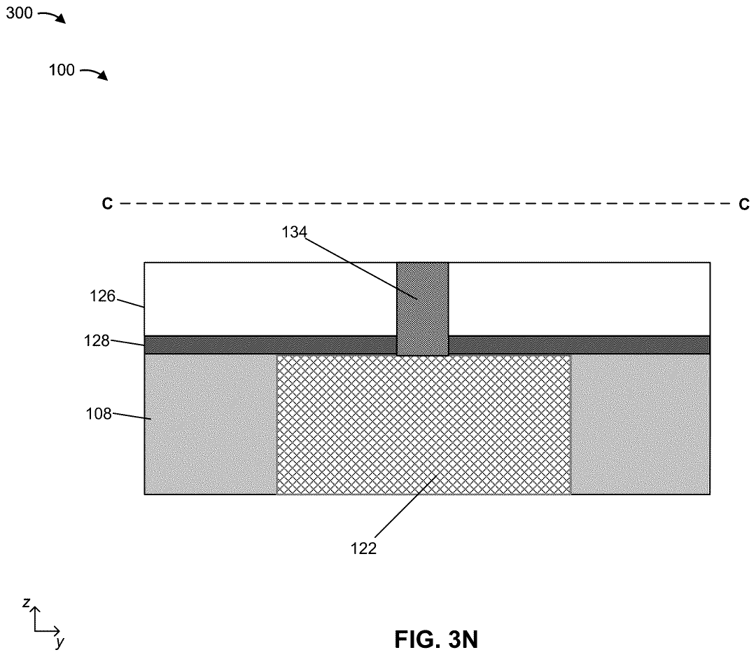

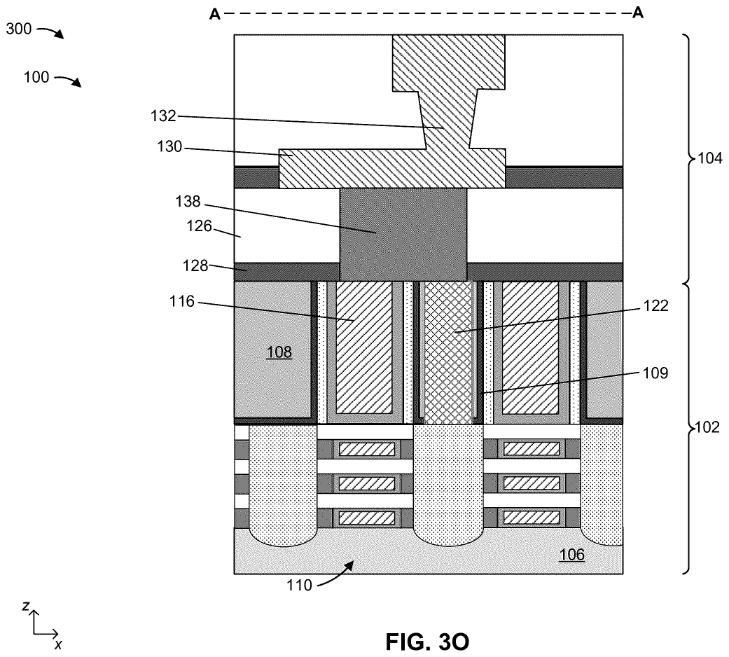

FIGS. 3A-3O are diagrams of an example implementation 300 of forming an interconnect layer 104 (or a portion thereof) of the semiconductor device 100 described herein. In particular, the example implementation 300 includes an example of forming the interconnect layer 104 (e.g., the back end region or BEOL region) of the semiconductor device 100. In some implementations, one or more of the semiconductor processing operations described in connection with FIGS. 3A-3O may be performed after one or more processes described in connection with FIGS. 2A-2D. In some implementations, one or more of the semiconductor processing operations described in connection with FIGS. 3A-3O may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

As shown in FIGS. 3A and 3B, the interconnect layer 104 of the semiconductor device 100 is formed above the dielectric layer 108 of the device layer 102. Forming the interconnect layer 104 may include forming a first ESL 128 and a first ILD layer 126 over and/or on the dielectric layer 108 such that the first ESL 128 and the first ILD layer 126 cover the gate structures 116 and the source/drain contact structures 122 of the integrated circuit devices 110. A deposition tool may be used to deposit the first ESL 128 and/or the first ILD layer 126 using a PVD technique, an ALD technique, a CVD technique, an oxidation technique, and/or another suitable deposition technique. The first ESL 128 and/or the first ILD layer 126 may be deposited in one or more deposition operations. In some implementations, a planarization tool may be used to perform a planarization operation (e.g., a CMP operation) to planarize the first ESL 128 and/or the first ILD layer 126 after the first ESL 128 and/or the first ILD layer 126 is deposited.

As shown in FIGS. 3C and 3D, recesses may be formed in and/or through the ILD layer 126 and the ESL 128. For example, and as shown in FIG. 3C, a recess 302 may be formed over a gate structure 116 and a source/drain contact structure 122 in preparation for formation of a merged interconnect structure 138. The top surfaces (or portions thereof) of the gate structure 116 and the source/drain contact structure 122 may be exposed in the recess 302. As another example, and as shown in FIG. 3D, another recess 304 may be formed over another source/drain contact structure 122 in preparation for formation of a source/drain interconnect structure 134. The top surface of the source/drain contact structure 122 may be exposed in the recess 304. In some implementations, additional recesses are formed, such as a recess that is formed over a gate structure 116 in preparation for formation of a gate interconnect structure 136.

In some implementations, a pattern in a photoresist layer is used to etch the first ILD layer 126 and/or the first ESL 128 to form the recesses 302, 304. In these implementations, a deposition tool may be used to form the photoresist layer on the first ILD layer 126 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the first ILD layer 126 and/or the first ESL 128 based on the pattern to form the recesses 302, 304. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recesses 302, 304 based on a pattern.

As shown in FIGS. 3C and 3D, in some implementations, the recesses 302, 304 are formed to have substantially vertical sidewalls with minimal sidewall taper. In some implementations, the recesses 302, 304 are formed to have tapered sidewalls (e.g., tapered in the x-direction, tapered in the y-direction) such that lateral widths of the recesses 302, 304 decrease from the tops of the recesses 302, 304 to the bottom of the recesses 302, 304.

As shown in FIGS. 3E and 3F, a seed layer 306 may be deposited over the ILD layer 126 and in the recesses 302, 304. In particular, the seed layer 306 may be deposited on the sidewalls and on the bottom surfaces of the recesses 302, 304. The seed layer 306 may be formed as a growth substrate for the interconnect structures that are to be formed in the recesses 302, 304. The seed layer 306 may promote a particular direction of material growth, and may promote adhesion of the material of the interconnect structures to the surfaces of the recesses 302, 304.

In some implementations, the seed layer 306 includes the same metal material that is to be deposited for the interconnect structures. For example, the source/drain interconnect structures 134, the gate interconnect structures 136, and/or the merged interconnect structures 138 may be subsequently formed of a metal material such as tungsten (W), and the seed layer 306 may also include tungsten. In some implementations, the seed layer 306 includes a different metal material than the metal material that is to be deposited for the interconnect structures.

A deposition tool may be used to deposit the material of the seed layer using a deposition technique such as CVD, PVD, ALD, and/or another suitable deposition technique. In some implementations, PVD may be used to deposit the seed layer 306. In these implementations, the seed layer 306 is substantially fluorine-free and substantially chlorine-free. This is because PVD is a physical process in which the material of the seed layer 306 is deposited by physical bombardment (e.g., sputtering) of the material of the seed layer 306 from a material target.

As shown in FIGS. 3G and 3H, an oxidation treatment operation may be performed for the seed layer 306 to oxidize portions of the seed layer 306. In particular, the oxidation treatment operation results in formation of oxidized portions of the seed layer on the sidewalls of the recesses 302, 304, and on the first ILD layer 126. This enables these portions of the seed layer 306 to be subsequently removed.

As further shown in FIGS. 3G and 3H, portions of the seed layer 306 on the bottom surfaces of the recesses 302, 304 are also oxidized in the oxidation treatment operation. However, portions of the seed layer 306 under the oxidized portions remain unoxidized. The unoxidized portions remain in the recesses 302, 304 respectively as remaining portions 308, 310 of the seed layer 306. These remaining portions 308, 310 are subsequently used as growth substrates for achieving primarily bottom-up growth (e.g., as opposed to lateral growth from the sidewalls) of the material of the interconnect structures that are subsequently formed in the recesses 302, 304. The bottom-up growth enables the interconnect structures to be formed substantially free of voids and other discontinuities.

The oxidation treatment operation includes exposing the seed layer 306 to a source of oxygen (O), which increases the oxygen concentration in the material of the seed layer 306. Thus, the oxygen oxidized portions of the seed layer 306 contain an oxide of the material of the seed layer 306. For example, if the seed layer 306 contains tungsten (W), the oxidized portions of the seed layer 306 may contain a tungsten oxide (WOₓ).

Exposing the seed layer 306 to an oxygen source may include a gas-based oxidation treatment operation, a wet chemical-based oxidation treatment operation, a plasma-based oxidation treatment operation, and/or another type of oxidation treatment operation.

In implementations in which a gas-based oxidation treatment operation is performed, a gas-based etch tool (or another type of gas-based semiconductor processing tool) may be used to expose the seed layer 306 to an oxygen-containing reactant that includes an oxygen-containing gas. The oxygen-containing gas may include oxygen (O₂), a nitrogen oxide (NₓO_{y} such as NO, NO₂, N₂O, N₂O₄), ozone (O₃), and/or another type oxygen-containing gas. In some implementations, the oxygen-containing gas may be provided using an inert carrier gas such as argon (Ar).

The oxidation of the material of the seed layer 306 using the oxygen-containing gas may result from a thermal reaction between the material of the seed layer 306 and the oxygen-containing gas. To facilitate the thermal reaction, the temperature in the processing chamber of the gas-based etch tool may be elevated to a temperature that is included in a range of room temperature to approximately 500 degrees Celsius. However, other values and ranges are within the scope of the present disclosure.

The flow rate of the combined gas into a processing chamber of the gas-based etch tool may be included in a range of approximately 10 standard cubic centimeters per minute (sccm) to approximately 1000 sccm to achieve a sufficiently high oxidation rate to oxidize the seed layer 306 without the oxidation rate being too high so as to leave no remaining unoxidized portions. However, other ranges and values are within the scope of the present disclosure.

The pressure in the processing chamber of the gas-based etch tool for the gas-based oxidation treatment operation may be included in a range of approximately 0.10 torr to approximately 10 torr to achieve a high uniformed in the oxidation rate across the seed layer 306 with minimal damage to other layers and/or structures of the semiconductor device 100. However, other ranges and values are within the scope of the present disclosure.

In implementations in which a plasma-based oxidation treatment operation is performed, a plasma-based etch tool (or another type of plasma-based semiconductor processing tool) may be used to expose the seed layer 306 to an oxygen-containing plasma (e.g., an O₂ plasma). In some implementations, other types of plasma, such as a hydrogen (H₂) plasma, may be used along with the oxygen-containing plasma to oxidize the material of the seed layer 306.

The plasma(s) may be remotely-generated and provided into the processing chamber of the plasma-based etch tool, and/or may be generated within the processing chamber of the plasma-based etch tool. The plasma(s) may be generated by inductive coupling, capacitive coupling, and/or by microwave generation, among other examples. A plasma generation power included in a range of approximately 100 watts to approximately 2000 watts may be used to generate the plasma(s) to achieve sufficient penetration of oxidants with minimal damage to surrounding layers and/or structures. However, other ranges and values are within the scope of the present disclosure.

In implementations in which a wet chemical-based oxidation treatment operation is performed, a wet chemical-based etch tool (or another type of wet chemical-based semiconductor processing tool) may be used to expose the seed layer 306 to a wet oxygen-containing reactant, which oxidizes the material of the seed layer 306. The wet oxygen-containing reactant may include an oxidizing agent such as ozone-deionized water, sulfuric acid (H₂SO₄), and/or another liquid-based oxygen-containing chemical. In some implementations, the oxidizing agent may be mixed hydrochloric acid (HCL) to achieve oxidization.

As shown in FIGS. 3I and 3J, the seed layer 306 may be etched to remove the oxidized portions of the seed layer 306 from the semiconductor device 100. The remaining portions 308, 310 (e.g., the unoxidized portions) remain at the bottom of the recesses 302, 304 as growth substrates for the material of the interconnect structures that are subsequently formed in the recesses 302, 304. The thickness of the remaining portions 308, 310 (indicated in FIG. 3I as a dimension D1, and in FIG. 3J as a dimension D2) may be included in a range of approximately 2 nanometers to approximately 8 nanometers to provide a sufficiently thick growth substrate for the interconnect structures that are subsequently formed in the recesses 302, 304. However, other values and ranges are within the scope of the present disclosure.

In some implementations, a gas-based etch tool is used to etch the seed layer 306 to remove the oxidized portions of the seed layer 306. In these implementations, a gas-based etchant that contains a metal that is included in the material of the seed layer 306 may be used to etch the seed layer 306. In particular, the gas-based etchant may include a metal precursor of the metal element of the seed layer 306 and/or a metal precursor of a metal element in a material of the interconnect structures that are to be deposited in the recesses 302, 304. For example, if the seed layer 306 is formed of tungsten (W) (and/or the interconnect structures are to be formed of tungsten), the gas-based etchant may include a tungsten precursor such as tungsten pentachloride (WCl₅) and/or another chloride of the metal that is included in the material of the seed layer 306. As another example, if the seed layer 306 is formed of tungsten (W) (and/or the interconnect structures are to be formed of tungsten), the gas-based etchant may include a tungsten precursor such as tungsten hexafluoride (WF₆) and/or another fluoride of the metal that is included in the material of the seed layer 306. In some implementations, additional reactant gasses such as a chlorine (Cl₂) gas, a fluorine (F₂) gas, and/or a hydrogen (H₂) gas may be used along with the precursor gas to etch the seed layer 306.

The etching of the material of the seed layer 306 using the gas-based etchant may result from a thermal reaction between the material of the seed layer 306 and the gas-based etchant. To facilitate the thermal reaction, the temperature in the processing chamber of the gas-based etch tool may be elevated to a temperature that is included in a range of room temperature to approximately 500 degrees Celsius. However, other values and ranges are within the scope of the present disclosure.

The flow rate of the gas-based etchant into a processing chamber of the gas-based etch tool may be included in a range of approximately 50 sccm to approximately 1000 sccm to achieve a removal rate of the oxidized portions of the seed layer 306 with minimal removal of unoxidized portions of the seed layer 306. However, other ranges and values are within the scope of the present disclosure.

The pressure in the processing chamber of the gas-based etch tool may be included in a range of approximately 500 torr to approximately 30000 torr to achieve a high uniformity in the material removal rate across the seed layer 306 with minimal damage to other layers and/or structures of the semiconductor device 100. However, other ranges and values are within the scope of the present disclosure.

In some implementations, a plasma-based etchant is used to etch the seed layer 306, and a plasma-based etch tool (or another type of plasma-based semiconductor processing tool) may be used to expose the seed layer 306 to plasma (e.g., an O₂ plasma, a hydrogen (H₂) plasma) that is used to etch the seed layer 306. The plasma may be remotely-generated and provided into the processing chamber of the plasma-based etch tool, and/or may be generated within the processing chamber of the plasma-based etch tool. The plasma may be generated by inductive coupling, capacitive coupling, and/or by microwave generation, among other examples. A plasma generation power included in a range of approximately 100 watts to approximately 2000 watts may be used to generate the plasma(s) to achieve sufficient penetration for ion bombardment in the seed layer 306 with minimal damage to surrounding layers and/or structures. However, other ranges and values are within the scope of the present disclosure.

As shown in FIGS. 3K and 3L, the material of the interconnect structures may be deposited on the remaining portions of the seed layer 306 in the recesses 302, 304 so that the interconnect structures grow on the remaining portions of the seed layer 306 from a bottoms of the recesses 302, 304 to a tops of the recesses 302, 304. For example, and as shown in FIG. 3K, the material of the merged interconnect structure 138 may be deposited on the remaining portion 308 of the seed layer 306 at the bottom of the recess 302 to achieve bottom-up growth of the merged interconnect structure 138 in the recess 302. As another example, and as shown in FIG. 3L, the material of the source/drain interconnect structure 134 may be deposited on the remaining portion 310 of the seed layer 306 at the bottom of the recess 304 to achieve bottom-up growth of the source/drain interconnect structure 134 in the recess 304. The material of a gate interconnect structure 136 may be deposited on a remaining portion of the seed layer 306 to achieve bottom-up growth in a similar manner.

This bottom-up growth (e.g., as opposed to lateral growth from the sidewalls of the recesses 302, 304) minimizes the likelihood of the formation of voids in the interconnect structures, and therefore the interconnect structures may be substantially void free.

A deposition tool may be used to deposit the material of the source/drain interconnect structures 134, the gate interconnect structures 136, and the merged interconnect structures 138 using a CVD technique, a PVD technique, an ALD technique, an electroplating technique, and/or another suitable deposition technique. The material of the source/drain interconnect structures 134, the gate interconnect structures 136, and the merged interconnect structures 138 may be the same metal material as the seed layer 306, such as tungsten (W) among other examples. Thus, the same metal precursor(s) that were used to deposit the material of the seed layer 306 and/or that were used to etch the seed layer 306, may also be used to deposit the material of the source/drain interconnect structures 134, the gate interconnect structures 136, and the merged interconnect structures 138. In other implementations, different precursors are used to deposit the material of the seed layer 306 and to deposit the material of the source/drain interconnect structures 134, the gate interconnect structures 136, and the merged interconnect structures 138.

In some implementations, the material of the seed layer 306 and the material of the source/drain interconnect structures 134, the gate interconnect structures 136, and the merged interconnect structures 138 are deposited using different deposition techniques. For example, and as described above in connection with FIGS. 3E and 3F, the material of the seed layer 306 may be deposited using a PVD technique so that the seed layer 306 is substantially fluorine-free and substantially chlorine-free. The material of the source/drain interconnect structures 134, the gate interconnect structures 136, and the merged interconnect structures 138 may instead be deposited using a CVD technique or another chemical-based deposition technique to achieve a high step coverage to minimize void formation in the source/drain interconnect structures 134, the gate interconnect structures 136, and the merged interconnect structures 138. The CVD technique may involve the use of chemical precursors of the material of the source/drain interconnect structures 134, the gate interconnect structures 136, and the merged interconnect structures 138, which may contain fluorine (F) and/or chlorine (Cl). Thus, the material of the source/drain interconnect structures 134, the gate interconnect structures 136, and the merged interconnect structures 138 may have a greater fluorine concentration and/or a greater chlorine concentration than the remaining portions 308, 310, of the seed layer 306.

As shown in FIGS. 3M and 3N, the interconnect structures (e.g., the source/drain interconnect structures 134, the gate interconnect structures 136, the merged interconnect structures 138) may be planarized to remove excess material from the interconnect structures. A planarization tool may be used to perform a planarization operation (e.g., a CMP operation) to planarize the interconnect structures. The planarization operation may result in the tops of the interconnect structures being approximately co-planar with the top of the first ILD layer 126.

As shown in FIG. 3O, additional layers of the interconnect layer 104 of the semiconductor device 100 may be formed above the layer of interconnect structures (e.g., the layer that includes the source/drain interconnect structures 134, the gate interconnect structures 136, the merged interconnect structures 138). One or more deposition tools are used to deposit additional alternating layers of ILD layers 126 and ESLs 128 in the interconnect layer 104 of the semiconductor device 100. In this way, the ILD layers 126 and ESLs 128 may be arranged in the z-direction in the semiconductor device 100. One or more deposition tools may be used to deposit each of the ILD layers 126 and each of the ESLs 128 using a PVD technique, an ALD technique, a CVD technique, an oxidation technique, and/or another suitable deposition technique. In some implementations, a planarization tool may be used to planarize the ILD layers 126 and/or the ESLs 128 after the ILD layers 126 and/or the ESLs 128 are deposited.

A deposition tool, an exposure tool, a developer tool, an etch tool, a planarization tool, a plating tool, and/or another semiconductor processing tool may be used to perform various operations to form the metallization structures 130 and to form the interconnect structures 132 in the interconnect layer 104 of the semiconductor device 100. In some implementations, the metallization structures 130 and the interconnect structures 132 are formed in a plurality of vertically-arranged layers in the interconnect layer 104. For example, an ILD layer 126 and an ESL 128 may be formed (e.g., using one or more deposition tools and/or one or more planarization tools), recesses may be formed in and/or through the ILD layer 126 and the ESL 128 (e.g., using an exposure tool, a developer tool, and/or an etch tool), and a layer of metallization structures 130 (e.g., the M0 layer) may be formed in the ILD layer 126 and the ESL 128 (e.g., using one or more deposition tools and/or one or more planarization tools) above the layer of source/drain interconnect structures 134, gate interconnect structures 136, and/or merged interconnect structures 138. Another ILD layer 126 and another ESL 128 may be formed, and a layer of interconnect structures 132 (e.g., the V1 layer) may be formed in the ILD layer 126 and the ESL 128. Additional layers of metallization structures 130 and additional layers of interconnect structures 132 may be formed in a similar manner.

One or more deposition tools may be used to deposit the metallization structures 130 and/or the interconnect structures 132 using a PVD technique, an ALD technique, a CVD technique, an electroplating technique (e.g., an electro-chemical plating technique), and/or another suitable deposition technique. In some implementations, a planarization tool may be used to planarize the metallization structures 130 and/or the interconnect structures 132 after the metallization structures 130, and/or the interconnect structures 132 are deposited.

As indicated above, FIGS. 3A-3O are provided as an example. Other examples may differ from what is described with regard to FIGS. 3A-3O.

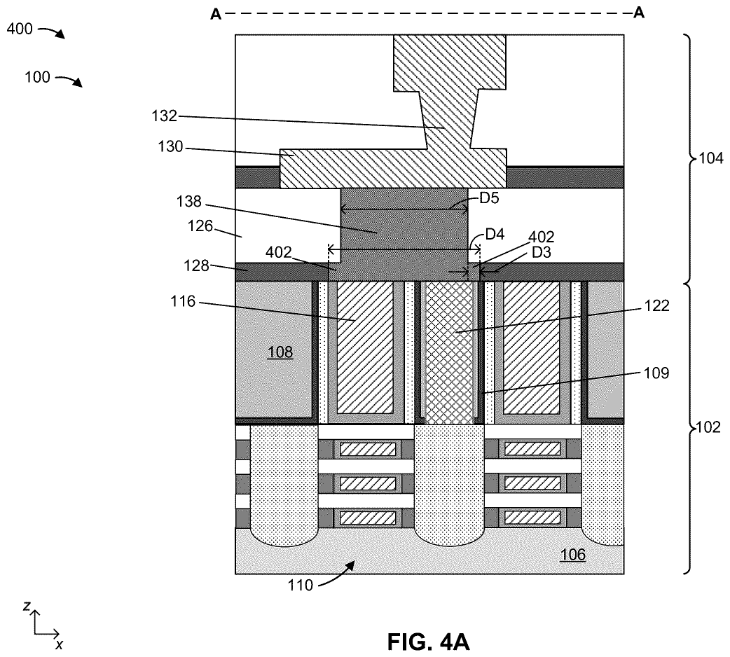

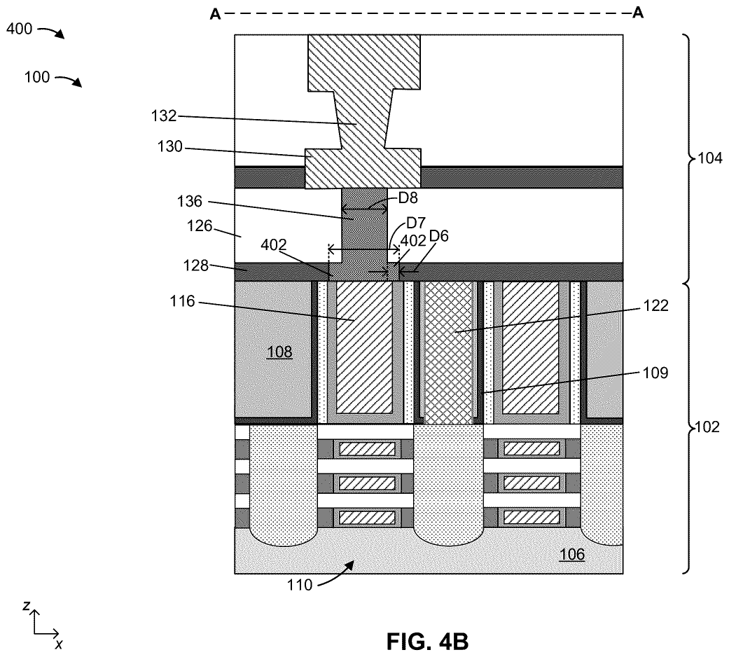

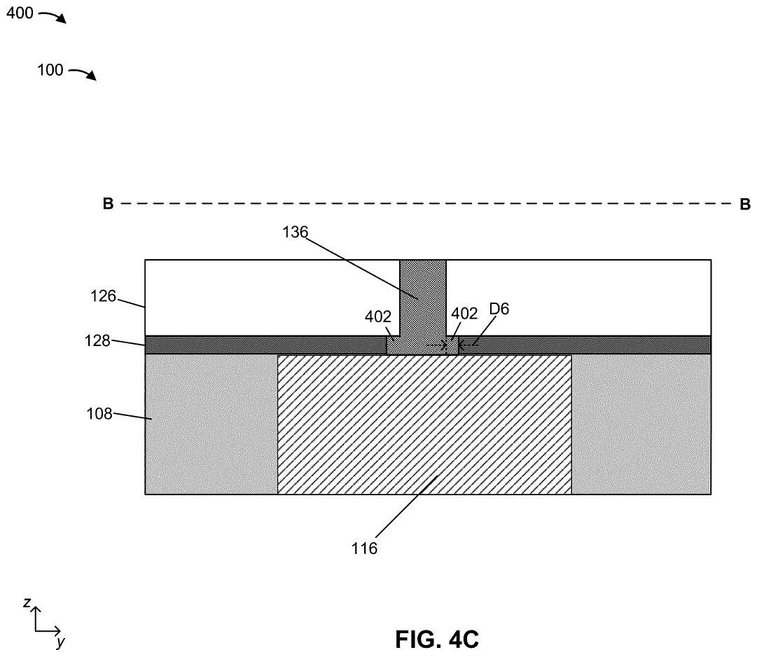

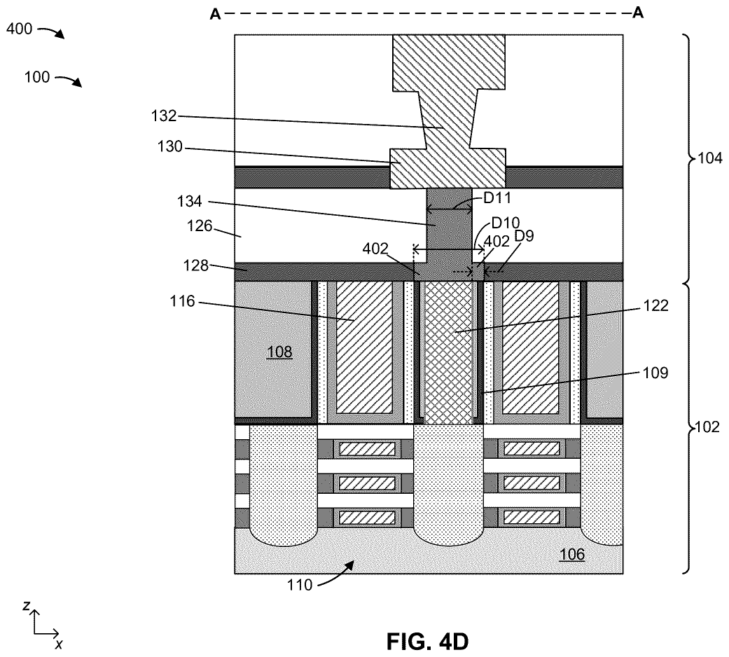

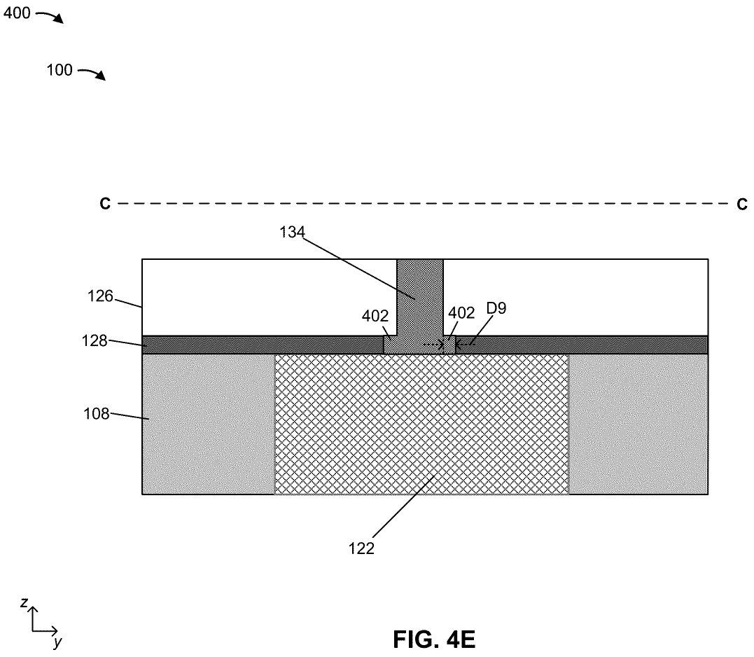

FIGS. 4A-4E are diagrams of examples 400 of interconnect structures that may be included in the semiconductor device 100 described herein. FIG. 4A illustrates an example 400 of a merged interconnect structure 138, FIGS. 4B and 4C illustrate an example 400 of a gate interconnect structure 136, and FIGS. 4D and 4E illustrate an example 400 of a source/drain interconnect structure 134.

As shown in FIGS. 4A-4E, the examples 400 of the source/drain interconnect structure 134, the gate interconnect structure 136, and the merged interconnect structure 138 are similar to the source/drain interconnect structures 134, the gate interconnect structures 136, and the merged interconnect structures 138 illustrated in FIGS. 1A-1D. However, the examples 400 of the source/drain interconnect structure 134, the gate interconnect structure 136, and the merged interconnect structure 138 each include protrusions 402 in the ESL 128.

As shown in FIG. 4A, the protrusions 402 of a merged interconnect structure 138 extend laterally outward from the main body of the merged interconnect structure 138. A protrusion 402 may extend laterally outward from the main body of the merged interconnect structure 138 by a distance (indicated in FIG. 4A as a dimension D3). In some implementations, the distance is greater than 0 nanometers and up to approximately 3 nanometers. However, other ranges and values are within the scope of the present disclosure.

The protrusions 402 result in a bottom portion of the merged interconnect structure 138 in the ESL 128 having a greater lateral width (indicated in FIG. 4A as a dimension D4) than a lateral width of a top portion of the merged interconnect structure 138 in the ILD layer 126 (indicated in FIG. 4A as a dimension D5).

As shown in FIGS. 4B and 4C, the protrusions 402 of a gate interconnect structure 136 extend laterally outward from the main body of the gate interconnect structure 136. A protrusion 402 may extend laterally outward from the main body of the gate interconnect structure 136 by a distance (indicated in FIG. 4B as a dimension D6). In some implementations, the distance is greater than 0 nanometers and up to approximately 3 nanometers. However, other ranges and values are within the scope of the present disclosure.

The protrusions 402 result in a bottom portion of the gate interconnect structure 136 in the ESL 128 having a greater lateral width (indicated in FIG. 4B as a dimension D7) than a lateral width of a top portion of the gate interconnect structure 136 in the ILD layer 126 (indicated in FIG. 4B as a dimension D8).

As shown in FIGS. 4D and 4E, the protrusions 402 of a source/drain interconnect structure 134 extend laterally outward from the main body of the source/drain interconnect structure 134. A protrusion 402 may extend laterally outward from the main body of the source/drain interconnect structure 134 by a distance (indicated in FIG. 4D as a dimension D9). In some implementations, the distance is greater than 0 nanometers and up to approximately 3 nanometers. However, other ranges and values are within the scope of the present disclosure.

The protrusions 402 result in a bottom portion of the source/drain interconnect structure 134 in the ESL 128 having a greater lateral width (indicated in FIG. 4D as a dimension D10) than a lateral width of a top portion of the source/drain interconnect structure 134 in the ILD layer 126 (indicated in FIG. 4D as a dimension D11).

As indicated above, FIGS. 4A-4E are provided as examples. Other examples may differ from what is described with regard to FIGS. 4A-4E.

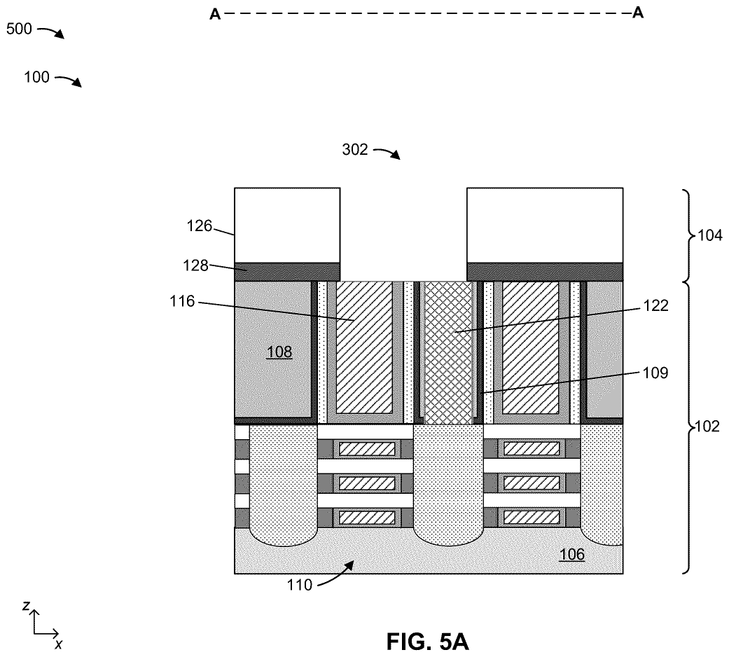

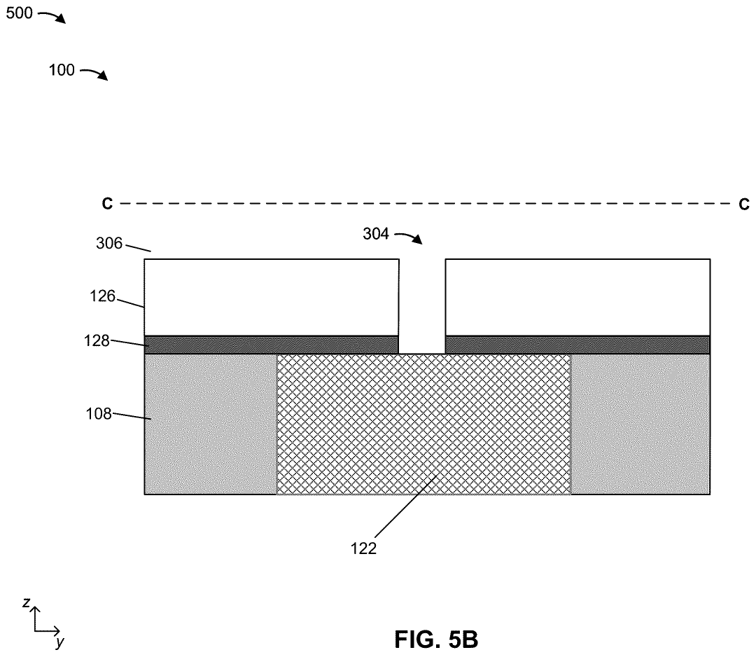

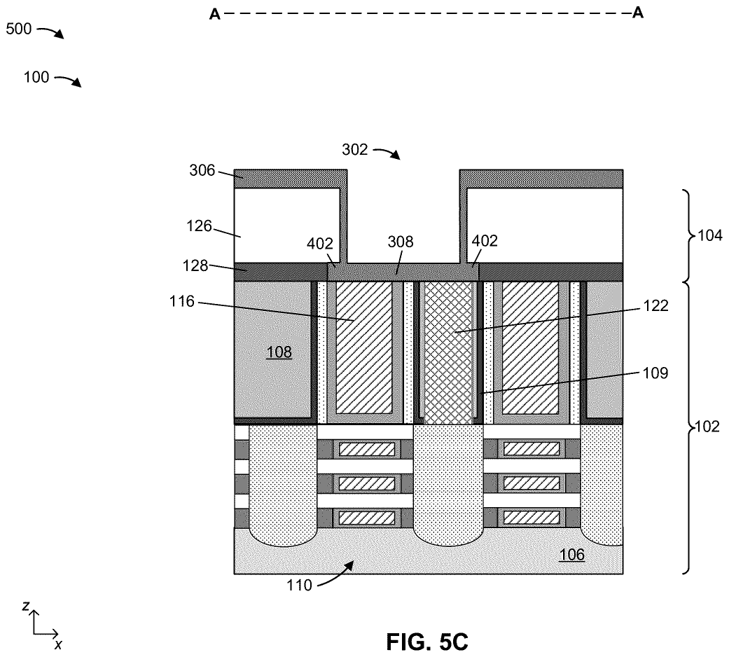

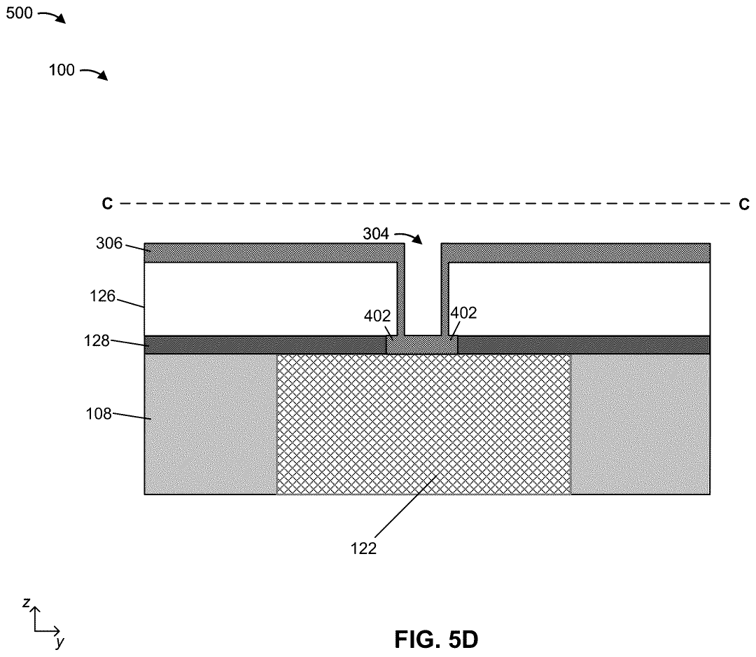

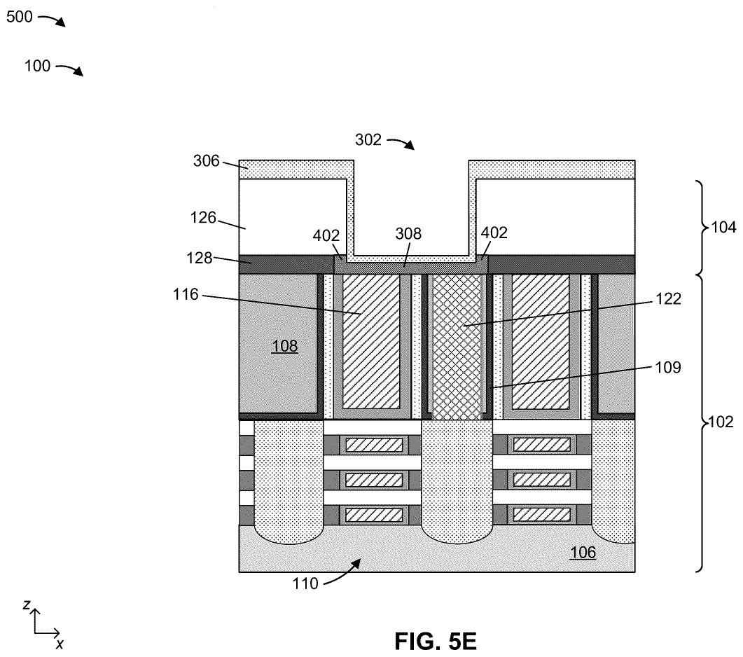

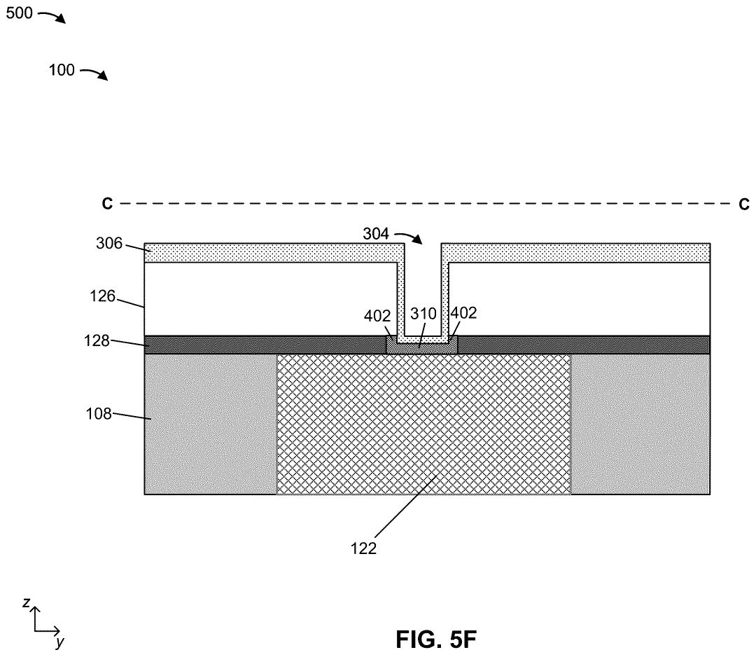

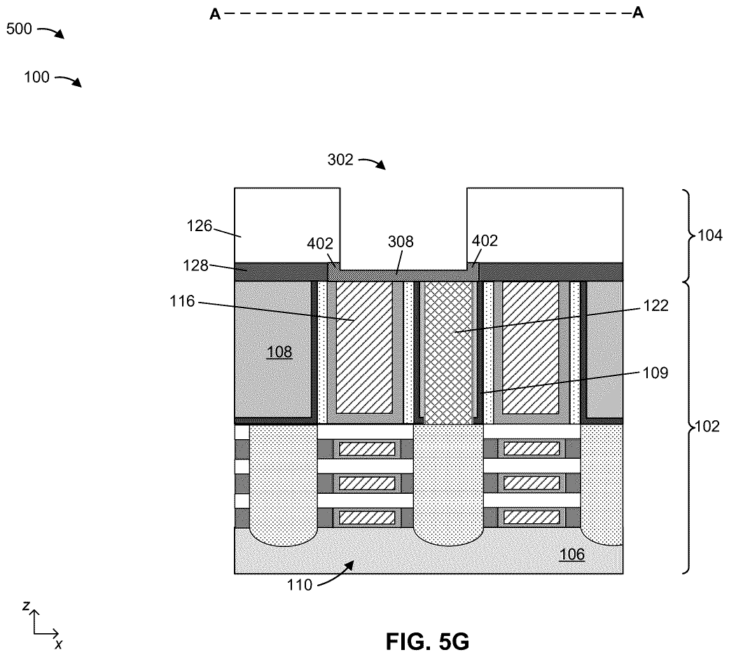

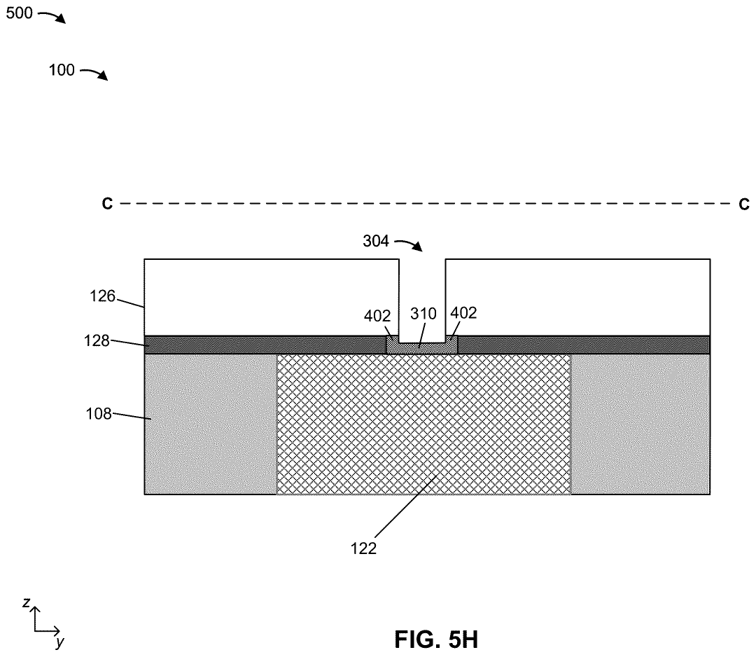

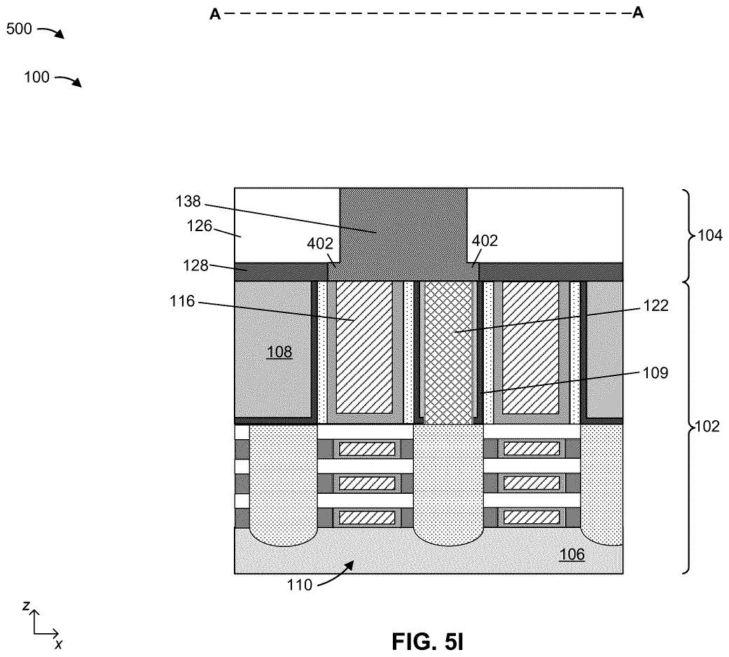

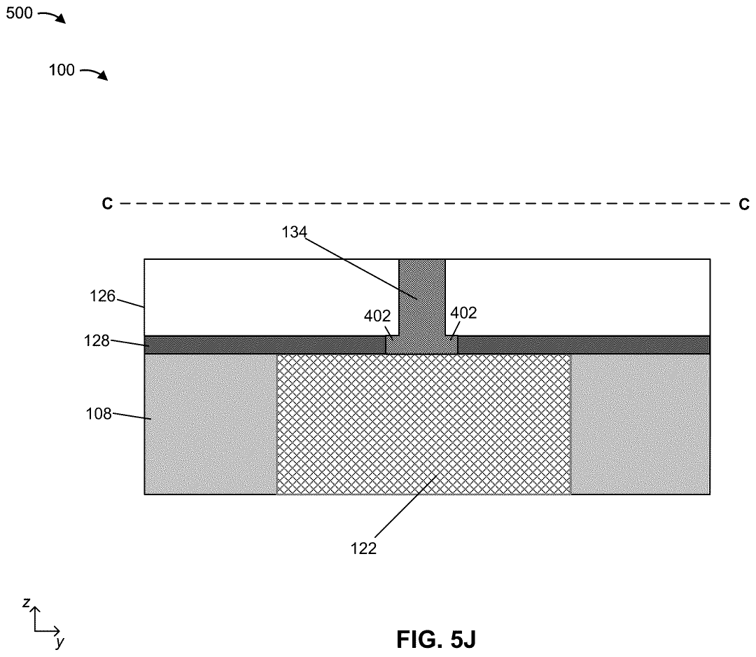

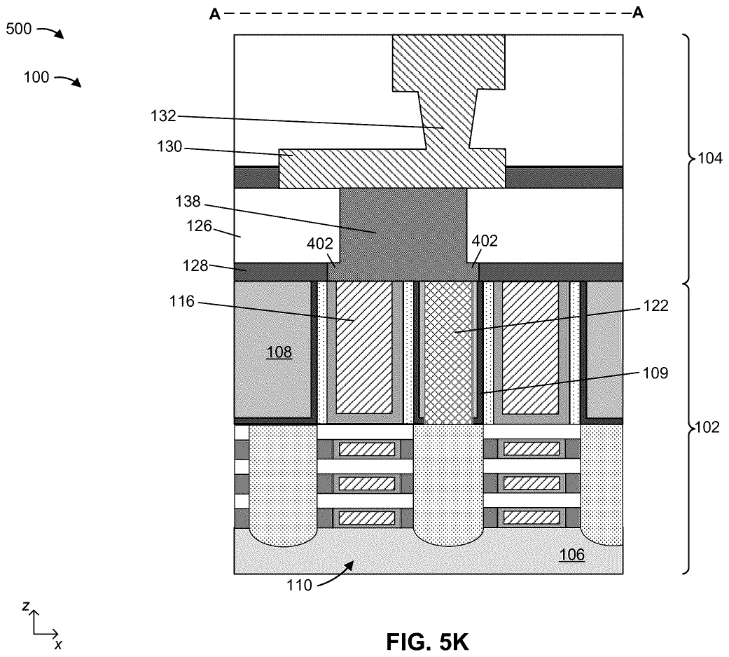

FIGS. 5A-5K are diagrams of an example implementation 500 of forming an interconnect layer 104 (or a portion thereof) of the semiconductor device 100 described herein. In particular, the example implementation 500 includes an example of forming interconnect structures that include protrusions 402, as illustrated in connection with FIGS. 4A-4E. In some implementations, one or more of the semiconductor processing operations described in connection with FIGS. 5A-5K may be performed after one or more processes described in connection with FIGS. 2A-2D. In some implementations, one or more of the semiconductor processing operations described in connection with FIGS. 5A-5K may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

As shown in FIGS. 5A and 5B, the first ILD layer 126, the first ESL 128, and the recesses 302, 304 may be formed in a similar manner as described in connection with FIGS. 3A-3D.

As shown in FIGS. 5C and 5D, the seed layer 306 may be deposited over the ILD layer 126 and in the recesses 302, 304 in a similar manner as described in connection with FIGS. 3E and 3F. In particular, the seed layer 306 may be deposited on the sidewalls and on the bottom surfaces of the recesses 302, 304. The seed layer 306 may be formed as a growth substrate for the interconnect structures that are to be formed in the recesses 302, 304. The seed layer 306 may promote a particular direction of material growth, and may promote adhesion of the material of the interconnect structures to the surfaces of the recesses 302, 304.

However, in the example implementation 500, protrusions 402 are formed in the seed layer 306. The protrusions 402 result due to lateral etching of the ESL 128 during deposition of the material of the seed layer 306. The material of the seed layer 306 may be deposited using a physical deposition technique such as PVD (e.g., sputtering). The bombardment of the material of the seed layer 306 on the exposed ends of the ESL 128 in the recesses 302, 304 may cause etching of the ends of the ESL 128 to occur. This results in the ends of the ESL 128 becoming recessed, and the recesses in the ends of the ESL 128 are filled in with the material of the seed layer 306, resulting in formation of the protrusions 402. The ILD layer 126 may be formed of a dielectric material that is more resistant to sputter etching than the ESL 128, and may therefore experience minimal to no etching during deposition of the material of the seed layer 306.

As shown in FIGS. 5E and 5F, an oxidation treatment operation may be performed for the seed layer 306 to oxidize portions of the seed layer 306. The unoxidized portions remain in the recesses 302, 304 respectively as remaining portions 308, 310 of the seed layer 306. The oxidation treatment operation may be performed in a similar manner as described in connection with FIGS. 3G and 3H.

As shown in FIGS. 5G and 5H, the seed layer 306 may be etched to remove the oxidized portions of the seed layer 306 from the semiconductor device 100. The remaining portions 308, 310 (e.g., the unoxidized portions) remain at the bottom of the recesses 302, 304 as growth substrates for the material of the interconnect structures that are subsequently formed in the recesses 302, 304. The etch operation may be performed in a similar manner as described in connection with FIGS. 3I and 3J.

As shown in FIGS. 5I and 5J, the material of the interconnect structures may be deposited on the remaining portions of the seed layer 306 in the recesses 302, 304 so that the interconnect structures grow on the remaining portions of the seed layer 306 from a bottoms of the recesses 302, 304 to a tops of the recesses 302, 304. For example, and as shown in FIG. 5I, the material of the merged interconnect structure 138 may be deposited on the remaining portion 308 of the seed layer 306 at the bottom of the recess 302 to achieve bottom-up growth of the merged interconnect structure 138 in the recess 302. As another example, and as shown in FIG. 5J, the material of the source/drain interconnect structure 134 may be deposited on the remaining portion 310 of the seed layer 306 at the bottom of the recess 304 to achieve bottom-up growth of the source/drain interconnect structure 134 in the recess 304. The material of a gate interconnect structure 136 may be deposited on a remaining portion of the seed layer 306 to achieve bottom-up growth in a similar manner. The material of the interconnect structures may be deposited in a similar manner as described in connection with FIGS. 3K-3N.

As shown in FIG. 5K, additional layers of the interconnect layer 104 of the semiconductor device 100 may be formed above the layer of interconnect structures (e.g., the layer that includes the source/drain interconnect structures 134, the gate interconnect structures 136, the merged interconnect structures 138). The additional layers of the interconnect layer 104 may be formed in a similar manner as described in connection with FIG. 3O.

As indicated above, FIGS. 5A-5K are provided as an example. Other examples may differ from what is described with regard to FIGS. 5A-5K.

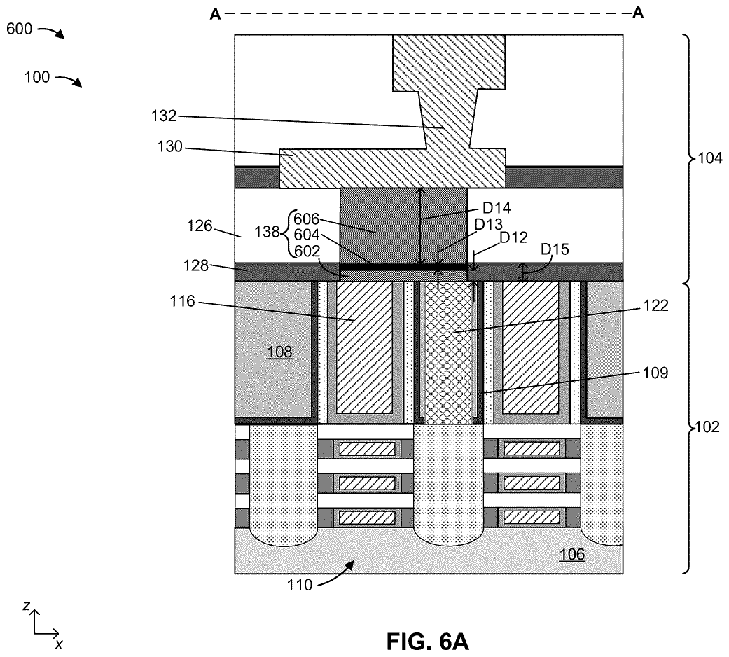

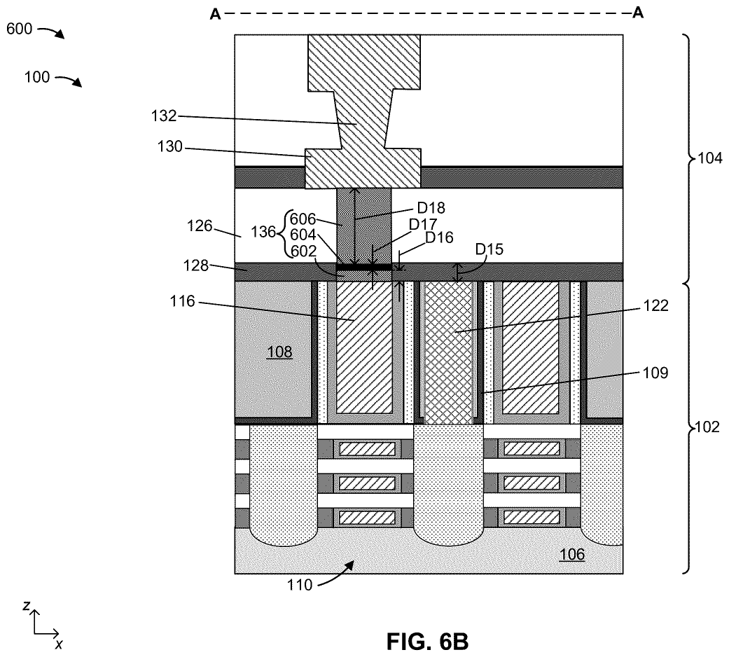

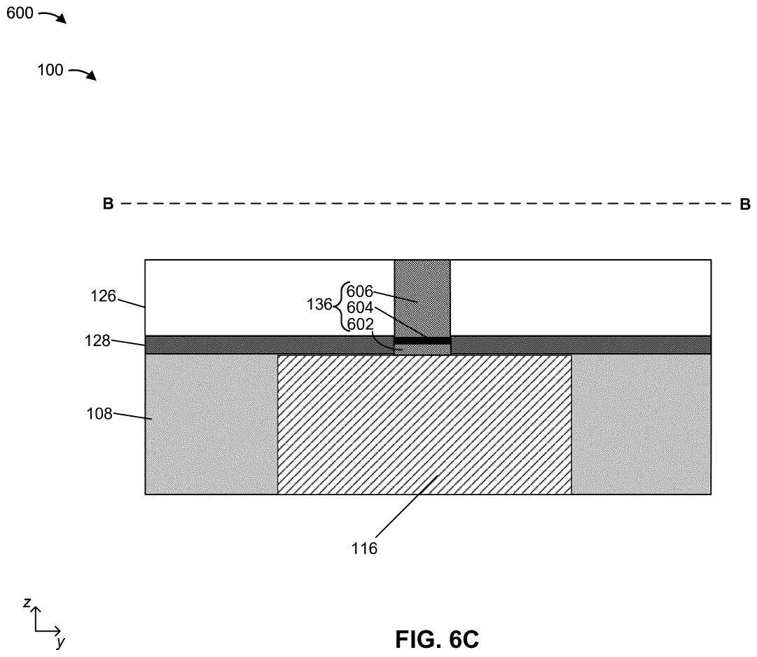

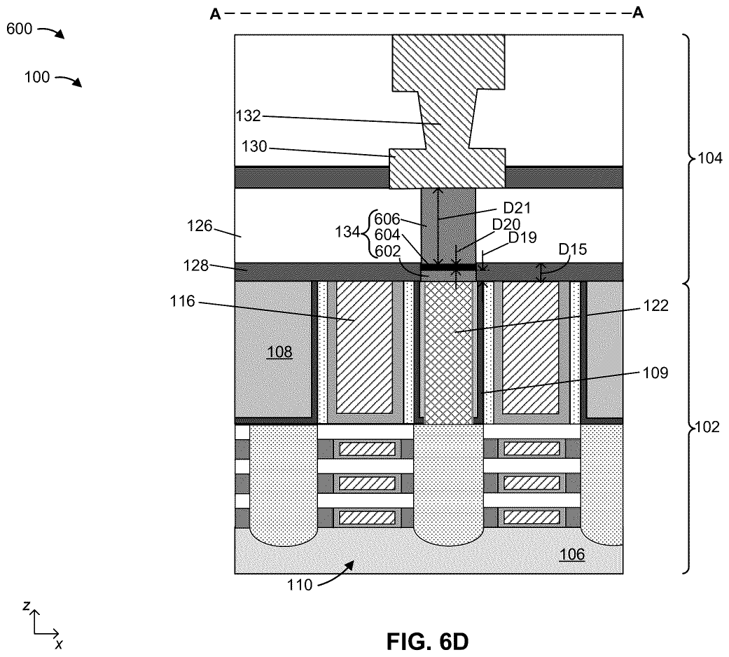

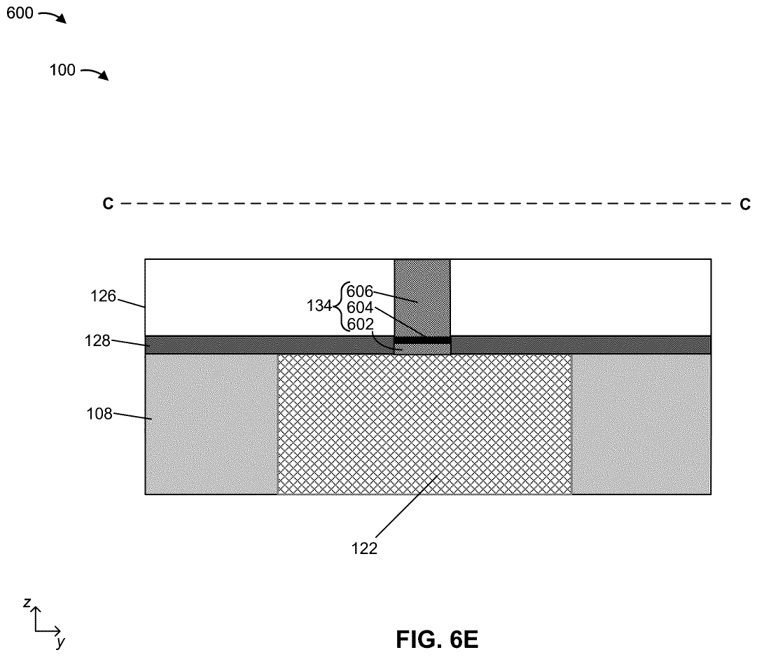

FIGS. 6A-6E are diagrams of examples 600 of interconnect structures that may be included in the semiconductor device 100 described herein. FIG. 6A illustrates an example 600 of a merged interconnect structure 138, FIGS. 6B and 6C illustrate an example 600 of a gate interconnect structure 136, and FIGS. 6D and 6E illustrate an example 600 of a source/drain interconnect structure 134.

As shown in FIGS. 6A-6E, the examples 600 of the source/drain interconnect structure 134, the gate interconnect structure 136, and the merged interconnect structure 138 are similar to the source/drain interconnect structures 134, the gate interconnect structures 136, and the merged interconnect structures 138 illustrated in FIGS. 1A-1D. However, the examples 600 of the source/drain interconnect structure 134, the gate interconnect structure 136, and the merged interconnect structure 138 each include a multiple-layer stack.

As shown in FIG. 6A, a merged interconnect structure 138 includes a multiple-layer stack that includes a bottom layer 602, an oxide layer 604, and a top layer 606. The bottom layer 602 may be included over and/or on the top surfaces of an underlying gate structure 116 and an underlying source/drain contact structure 122. The oxide layer 604 may be included over and/or on the bottom layer 602. The top layer 606 may be included over and/or on the oxide layer 604.

The bottom layer 602 may correspond to the remaining portion 308 of the seed layer 306 on which the merged interconnect structure 138 was formed, and may therefore include one or more metal materials. The oxide layer 604 may be a native oxide that natively formed on the bottom layer 602 due to exposure to atmospheric oxygen (O₂), among other sources of oxygen. The top layer 606 may include the main body of the merged interconnect structure 138 that also includes one or more metal materials.

Because the oxide layer 604 natively grows on the bottom layer 602 of the merged interconnect structure 138, the oxide layer 604 may include an oxide of a metal of the bottom layer 602. For example, if the bottom layer 602 includes tungsten (W), the oxide layer 604 may include tungsten oxide (WOₓ).

The bottom layer 602 may have a thickness indicated in FIG. 6A as a dimension D12, the oxide layer 604 may have a thickness indicated in FIG. 6A as a dimension D13, and the top layer 606 may have a thickness indicated in FIG. 6A as a dimension D14. The thickness of the bottom layer 602 may be greater than the thickness of the oxide layer 604 (e.g., D12>D13), and the thickness of the top layer 606 may be greater than the thickness of the bottom layer 602 (e.g., D14>D12). In some implementations, the thicknesses of the bottom layer 602 and the oxide layer 604 may be less than a thickness of the ESL 128 indicated in FIG. 6A as a dimension D15 (e.g., D15>D12, D15>D13). In some implementations, the thickness of the top layer 606 may be greater than the thickness of the ESL 128 (e.g., D14>D15).

In some implementations, a ratio of the thickness of the bottom layer 602 to the thickness of the oxide layer 604 (e.g., D12:D13) may be included in a range of approximately 1.5:1 to approximately 2:1. However, other values and ranges are within the scope of the present disclosure. In some implementations, a ratio of the thickness of the top layer 606 to the thickness of the bottom layer 602 (e.g., D14:D12) may be included in a range of approximately 7.5:1 to approximately 30:1. However, other values and ranges are within the scope of the present disclosure.

In some implementations, the thickness of the bottom layer 602 (e.g., D12) is included in a range of approximately 2 nanometers to approximately 8 nanometers. However, other values and ranges are within the scope of the present disclosure. In some implementations, the thickness of the oxide layer 604 (e.g., D13) is included in a range of approximately 1 nanometer to approximately 5 nanometers. However, other values and ranges are within the scope of the present disclosure. In some implementations, the thickness of the top layer 606 (e.g., D14) is included in a range of approximately 30 nanometers to approximately 60 nanometers. However, other values and ranges are within the scope of the present disclosure. In some implementations, the thickness of the ESL 128 (e.g., D15) is included in a range of approximately 3 nanometers to approximately 15 nanometers. However, other values and ranges are within the scope of the present disclosure.

As shown in FIGS. 6B and 6C, a gate interconnect structure 136 includes a multiple-layer stack that includes a bottom layer 602, an oxide layer 604, and a top layer 606. The bottom layer 602 may be included over and/or on the top surface of an underlying gate structure 116. The oxide layer 604 may be included over and/or on the bottom layer 602. The top layer 606 may be included over and/or on the oxide layer 604.

The bottom layer 602 may correspond to the remaining portion 308 of the seed layer 306 on which the gate interconnect structure 136 was formed, and may therefore include one or more metal materials. The oxide layer 604 may be a native oxide that natively formed on the bottom layer 602 due to exposure to atmospheric oxygen (O₂), among other sources of oxygen. The top layer 606 may include the main body of the gate interconnect structure 136 that also includes one or more metal materials.

Because the oxide layer 604 natively grows on the bottom layer 602 of the gate interconnect structure 136, the oxide layer 604 may include an oxide of a metal of the bottom layer 602. For example, if the bottom layer 602 includes tungsten (W), the oxide layer 604 may include tungsten oxide (WOₓ).

The bottom layer 602 may have a thickness indicated in FIG. 6B as a dimension D16, the oxide layer 604 may have a thickness indicated in FIG. 6B as a dimension D17, and the top layer 606 may have a thickness indicated in FIG. 6B as a dimension D18. The thickness of the bottom layer 602 may be greater than the thickness of the oxide layer 604 (e.g., D16>D17), and the thickness of the top layer 606 may be greater than the thickness of the bottom layer 602 (e.g., D18>D16). In some implementations, the thicknesses of the bottom layer 602 and the oxide layer 604 may be less than the thickness of the ESL 128 (e.g., D15>D16, D15>D17). In some implementations, the thickness of the top layer 606 may be greater than the thickness of the ESL 128 (e.g., D18>D15).

In some implementations, a ratio of the thickness of the bottom layer 602 to the thickness of the oxide layer 604 (e.g., D16:D17) may be included in a range of approximately 1.5:1 to approximately 2:1. However, other values and ranges are within the scope of the present disclosure. In some implementations, a ratio of the thickness of the top layer 606 to the thickness of the bottom layer 602 (e.g., D18:D16) may be included in a range of approximately 7.5:1 to approximately 30:1. However, other values and ranges are within the scope of the present disclosure.

In some implementations, the thickness of the bottom layer 602 (e.g., D16) is included in a range of approximately 2 nanometers to approximately 8 nanometers. However, other values and ranges are within the scope of the present disclosure. In some implementations, the thickness of the oxide layer 604 (e.g., D17) is included in a range of approximately 1 nanometer to approximately 5 nanometers. However, other values and ranges are within the scope of the present disclosure. In some implementations, the thickness of the top layer 606 (e.g., D18) is included in a range of approximately 30 nanometers to approximately 60 nanometers. However, other values and ranges are within the scope of the present disclosure.

As shown in FIGS. 6D and 6E, a source/drain interconnect structure 134 includes a multiple-layer stack that includes a bottom layer 602, an oxide layer 604, and a top layer 606.

The bottom layer 602 may be included over and/or on the top surface of an underlying source/drain contact structure 122. The oxide layer 604 may be included over and/or on the bottom layer 602. The top layer 606 may be included over and/or on the oxide layer 604.

The bottom layer 602 may correspond to the remaining portion 308 of the seed layer 306 on which the source/drain interconnect structure 134 was formed, and may therefore include one or more metal materials. The oxide layer 604 may be a native oxide that natively formed on the bottom layer 602 due to exposure to atmospheric oxygen (O₂), among other sources of oxygen. The top layer 606 may include the main body of the source/drain interconnect structure 134 that also includes one or more metal materials.

Because the oxide layer 604 natively grows on the bottom layer 602 of the source/drain interconnect structure 134, the oxide layer 604 may include an oxide of a metal of the bottom layer 602. For example, if the bottom layer 602 includes tungsten (W), the oxide layer 604 may include tungsten oxide (WOₓ).

The bottom layer 602 may have a thickness indicated in FIG. 6D as a dimension D19, the oxide layer 604 may have a thickness indicated in FIG. 6D as a dimension D20, and the top layer 606 may have a thickness indicated in FIG. 6D as a dimension D21. The thickness of the bottom layer 602 may be greater than the thickness of the oxide layer 604 (e.g., D19>D20), and the thickness of the top layer 606 may be greater than the thickness of the bottom layer 602 (e.g., D21>D19). In some implementations, the thicknesses of the bottom layer 602 and the oxide layer 604 may be less than the thickness of the ESL 128 (e.g., D15>D19, D15>D20). In some implementations, the thickness of the top layer 606 may be greater than the thickness of the ESL 128 (e.g., D21>D15).

In some implementations, a ratio of the thickness of the bottom layer 602 to the thickness of the oxide layer 604 (e.g., D19:D20) may be included in a range of approximately 1.5:1 to approximately 2:1. However, other values and ranges are within the scope of the present disclosure. In some implementations, a ratio of the thickness of the top layer 606 to the thickness of the bottom layer 602 (e.g., D21:D19) may be included in a range of approximately 7.5:1 to approximately 30:1. However, other values and ranges are within the scope of the present disclosure.

In some implementations, the thickness of the bottom layer 602 (e.g., D19) is included in a range of approximately 2 nanometers to approximately 8 nanometers. However, other values and ranges are within the scope of the present disclosure. In some implementations, the thickness of the oxide layer 604 (e.g., D20) is included in a range of approximately 1 nanometer to approximately 5 nanometers. However, other values and ranges are within the scope of the present disclosure. In some implementations, the thickness of the top layer 606 (e.g., D21) is included in a range of approximately 30 nanometers to approximately 60 nanometers. However, other values and ranges are within the scope of the present disclosure.

As indicated above, FIGS. 6A-6E are provided as examples. Other examples may differ from what is described with regard to FIGS. 6A-6E.

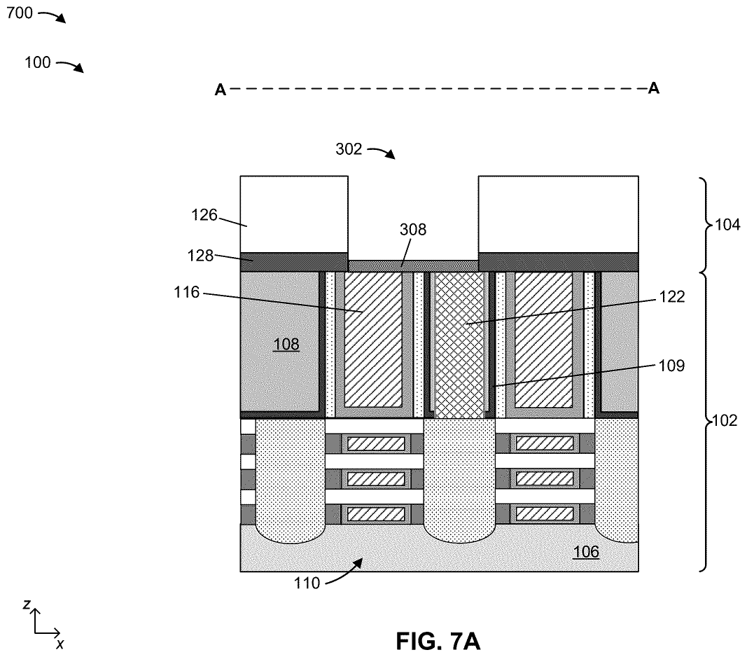

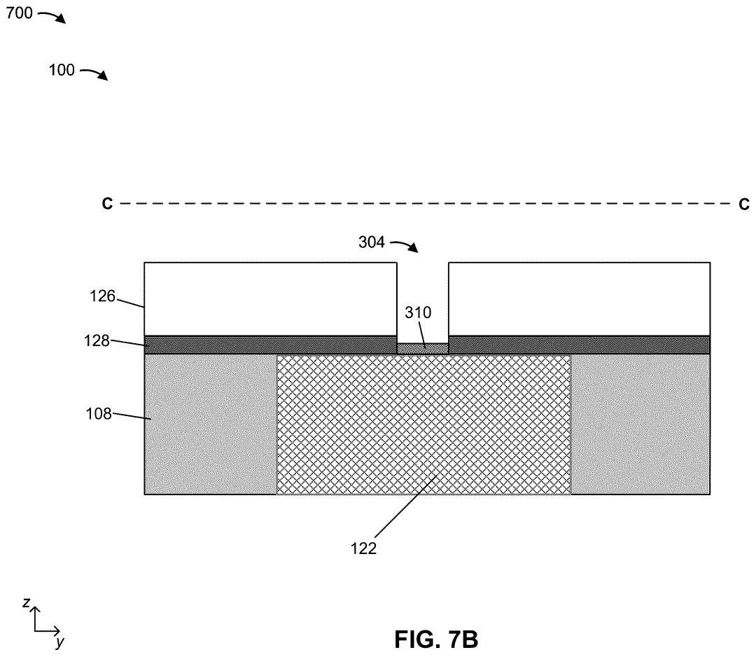

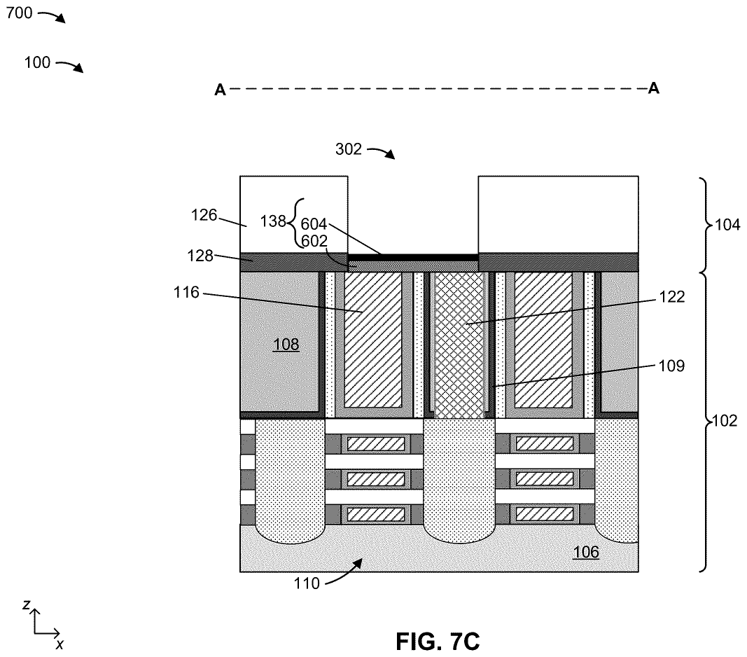

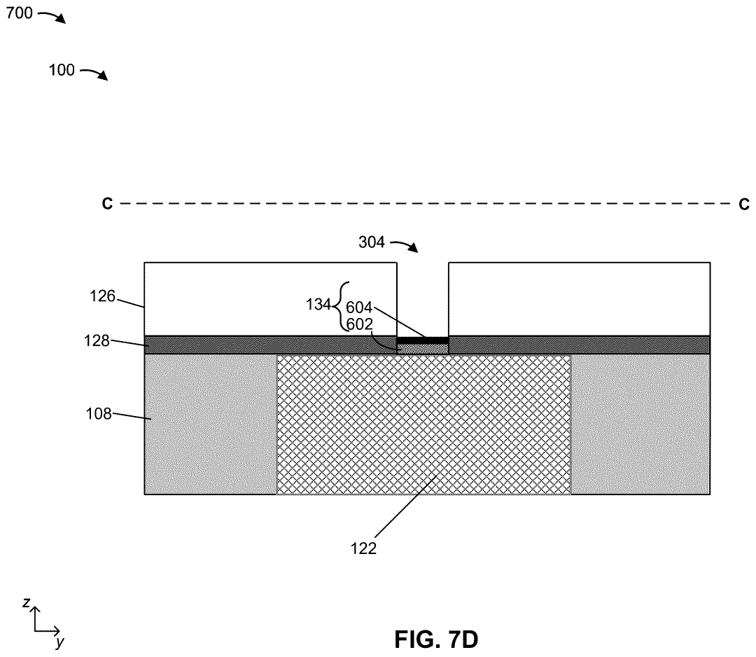

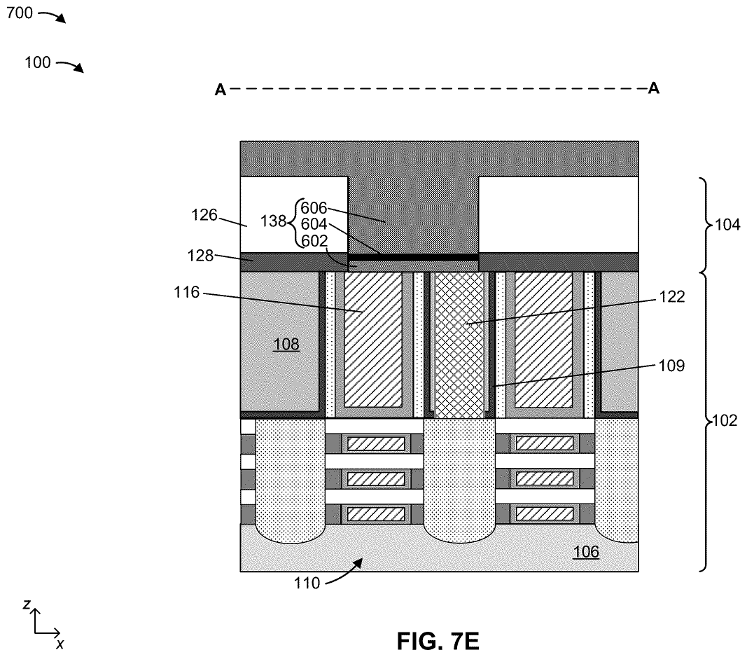

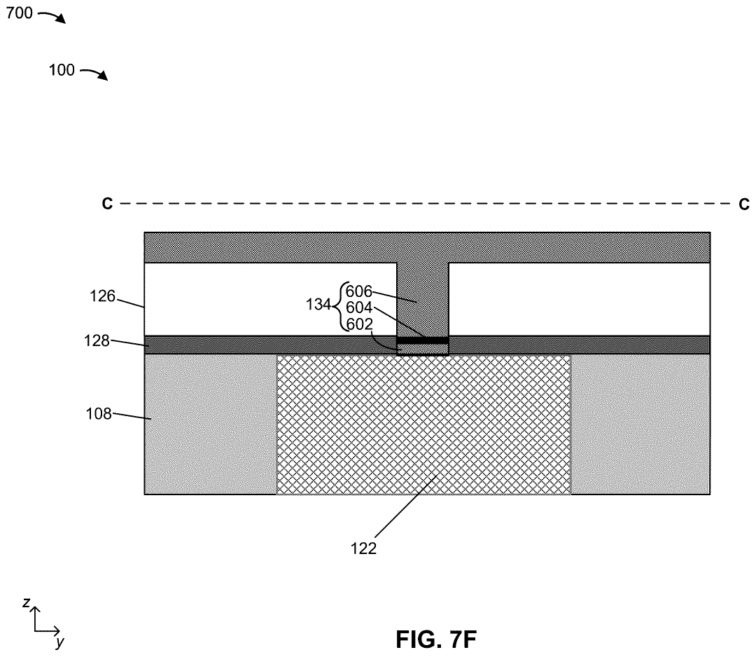

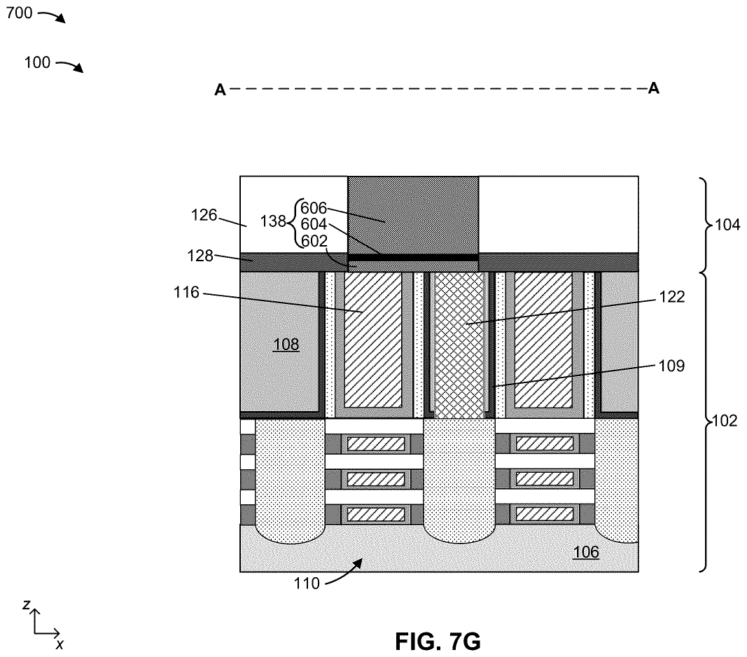

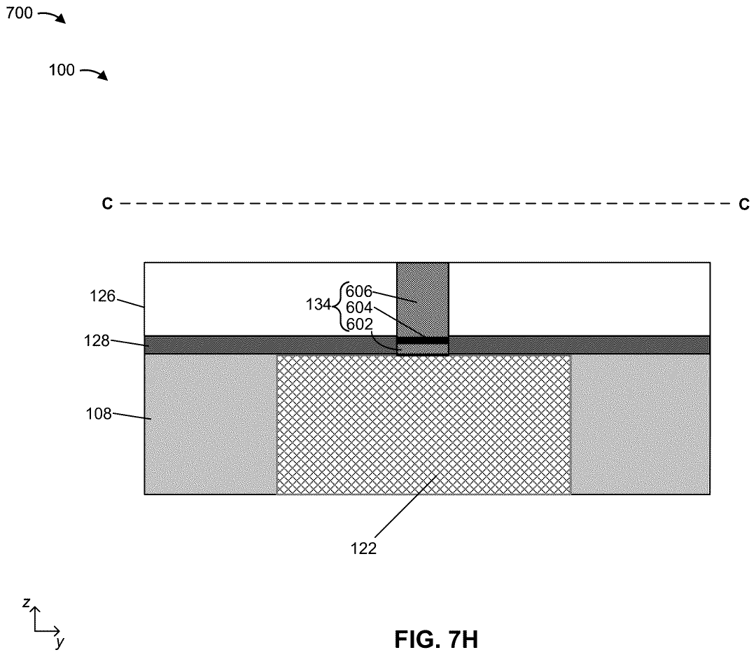

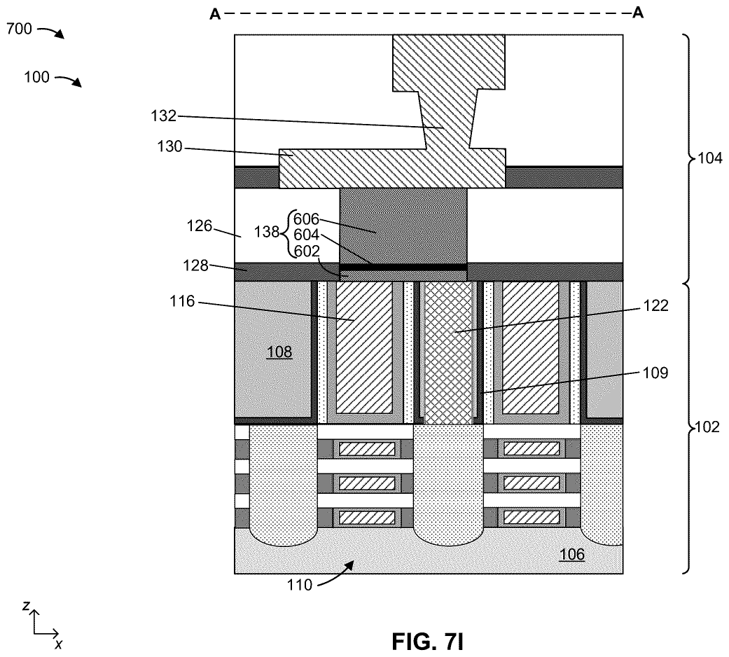

FIGS. 7A-7I are diagrams of an example implementation 700 of forming an interconnect layer 104 (or a portion thereof) of the semiconductor device 100 described herein. In particular, the example implementation 700 includes an example of forming interconnect structures that include a multiple-layer stack, as illustrated in connection with FIGS. 6A-6E. In some implementations, one or more of the semiconductor processing operations described in connection with FIGS. 7A-7I may be performed after one or more processes described in connection with FIGS. 2A-2D. In some implementations, one or more of the semiconductor processing operations described in connection with FIGS. 7A-7I may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

As shown in FIGS. 7A and 7B, the first ILD layer 126, the first ESL 128, the recesses 302, 304, and the remaining portions 308, 310 of the seed layer 306 may be formed in a similar manner as described in connection with FIGS. 3A-3J.

As shown in FIGS. 7C and 7D, the semiconductor device 100 may be transferred to a processing chamber of a deposition tool for depositing the material of the interconnect structures in the recesses 302, 304. When the semiconductor device 100 is transferred between processing chambers of semiconductor processing tools, the semiconductor device 100 may be exposed to various sources of oxygen, such as atmospheric oxygen. These various sources of oxygen may cause a thin layer of oxide material, corresponding to the oxide layers 604 of the source/drain interconnect structures 134, the gate interconnect structures 136, and/or the merged interconnect structures 138 to form on the bottom layers 602 (which may correspond to the remaining portions 308, 310 of the seed layer 306) of the source/drain interconnect structures 134, the gate interconnect structures 136, and/or the merged interconnect structures 138. In particular, the metal material of the remaining portions 308, 310 of the seed layer 306 may be exposed to oxygen, resulting in oxidation of the surfaces of the remaining portions 308, 310 of the seed layer 306, which results in formation of the oxide layers 604.

As shown in FIGS. 7E and 7F, the material of the top layers 606 of the interconnect structures may be deposited on the oxide layers 604 above the bottom layers 602 in the recesses 302, 304 so that the interconnect structures grow on the bottom layers 602. For example, and as shown in FIG. 7E, the material of the merged interconnect structure 138 may be deposited on the oxide layer 604 that is on the bottom layer 602 (e.g., the remaining portion 308 of the seed layer 306) at the bottom of the recess 302 to achieve bottom-up growth of the merged interconnect structure 138 in the recess 302. As another example, and as shown in FIG. 7F, the material of the source/drain interconnect structure 134 may be deposited on the oxide layer 604 that is on the bottom layer 602 (e.g., the remaining portion 310 of the seed layer 306) at the bottom of the recess 304 to achieve bottom-up growth of the source/drain interconnect structure 134 in the recess 304. The material of a gate interconnect structure 136 may be deposited on an oxide layer 604 that is on a bottom layer 602 (e.g., a remaining portion of the seed layer 306) to achieve bottom-up growth in a similar manner. The material of the interconnect structures may be deposited in a similar manner as described in connection with FIGS. 3K and 3L.

In some implementations, the material of the seed layer 306 (and thus, the material of the bottom layers 602) and the material of the top layers 606 are deposited using different deposition techniques. For example, the material of the seed layer 306 (and thus, the material of the bottom layers 602) may be deposited using a PVD technique so that the seed layer 306 (and thus, the material of the bottom layers 602) is substantially fluorine-free and substantially chlorine-free. The material of the top layers 606 may instead be deposited using a CVD technique or another chemical-based deposition technique to achieve a high step coverage to minimize void formation in the source/drain interconnect structures 134, the gate interconnect structures 136, and the merged interconnect structures 138. The CVD technique may involve the use of chemical precursors of the material of the top layers 606, which may contain fluorine (F) and/or chlorine (Cl). Thus, the material of the top layers 606 may have a greater fluorine concentration and/or a greater chlorine concentration than the material of the bottom layers 602.

As shown in FIGS. 7G and 7H, the top layers 606 of the interconnect structures may be planarized using a planarization tool. In this way, the top surfaces of the top layers 606 are approximately co-planar with the top surface of the ILD layer 126.

As shown in FIG. 7I, additional layers of the interconnect layer 104 of the semiconductor device 100 may be formed above the layer of interconnect structures (e.g., the layer that includes the source/drain interconnect structures 134, the gate interconnect structures 136, the merged interconnect structures 138). The additional layers of the interconnect layer 104 may be formed in a similar manner as described in connection with FIG. 3O.

As indicated above, FIGS. 7A-7I are provided as an example. Other examples may differ from what is described with regard to FIGS. 7A-7I.

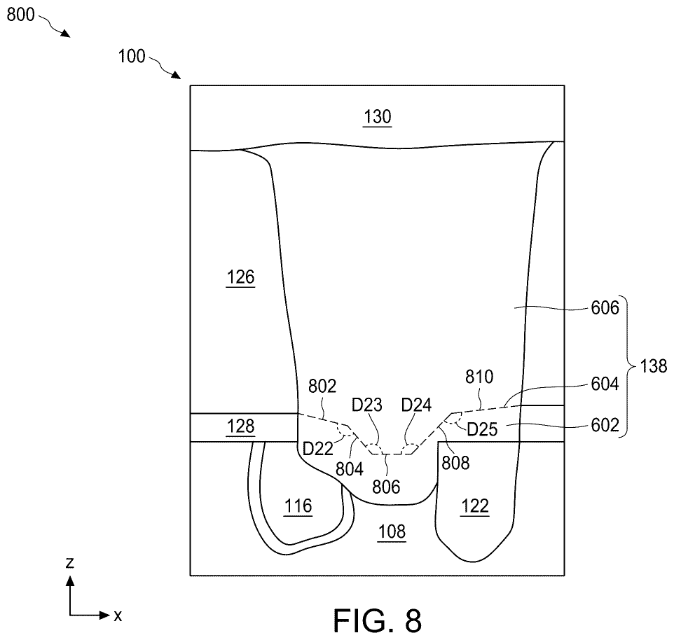

FIG. 8 is a diagram of an example 800 of an interconnect structure that may be included in the semiconductor device 100 described herein. FIG. 8 illustrates an example 800 of a merged interconnect structure 138. As shown in FIG. 8, the example 800 of the merged interconnect structure 138 may be similar to the example 600 of the merged interconnect structures 138 illustrated in FIG. 6A.

However, the example 800 of the merged interconnect structure 138 illustrated in FIG. 8, the merged interconnect structure 138 includes a non-planar oxide layer 604. Thus, the interface between bottom layer 602 and the top layer 606 of the merged interconnect structure 138 is also non-planar.

As shown in FIG. 8, the oxide layer 604 may include a plurality of segments, including a segment 802 over an underlying gate structure 116, a segment 804 over a transition between the gate structure 116 and a portion of the dielectric layer 108 between the gate structure 116 and the source/drain contact structure 122, a segment 806 over the dielectric layer 108, a segment 808 over a transition between the source/drain contact structure 122 and the dielectric layer 108 between the gate structure 116 and the source/drain contact structure 122, and/or a segment 810 over the source/drain contact structure 122, among other examples.

The segments 802 and 804 may be oriented at an angle (indicated in FIG. 8 as a dimension D22) relative to each other. The angle may be greater than approximately 90 degrees, and included in a range of approximately 100 degrees to approximately 170 degrees. However, other values and ranges for the angle are within the scope of the present disclosure.

The segments 804 and 806 may be oriented at an angle (indicated in FIG. 8 as a dimension D23) relative to each other. The angle may be greater than approximately 90 degrees, and included in a range of approximately 100 degrees to approximately 170 degrees. However, other values and ranges for the angle are within the scope of the present disclosure.

The segments 806 and 808 may be oriented at an angle (indicated in FIG. 8 as a dimension D24) relative to each other. The angle may be greater than approximately 90 degrees, and included in a range of approximately 100 degrees to approximately 170 degrees. However, other values and ranges for the angle are within the scope of the present disclosure.

The segments 808 and 810 may be oriented at an angle (indicated in FIG. 8 as a dimension D25) relative to each other. The angle may be greater than approximately 90 degrees, and included in a range of approximately 100 degrees to approximately 170 degrees. However, other values and ranges for the angle are within the scope of the present disclosure.

A first end of the segment 804 facing the segment 802 may be higher in the semiconductor device 100 than a second end of the segment 804 facing the segment 806. Thus, the segment 804 slopes downward from the segment 802 to the segment 806. A first end of the segment 808 facing the segment 810 may be higher in the semiconductor device 100 than a second end of the segment 808 facing the segment 806. Thus, the segment 808 slopes downward from the segment 810 to the segment 806.

The segment 806 may be the lowest part of the oxide layer 604. In some implementations, the segment 806 may be substantially flat. However, in other implementations the segment 806 may be angled upward or downward in the semiconductor device 100.

As indicated above, FIG. 8 is provided as an example. Other examples may differ from what is described with regard to FIG. 8.

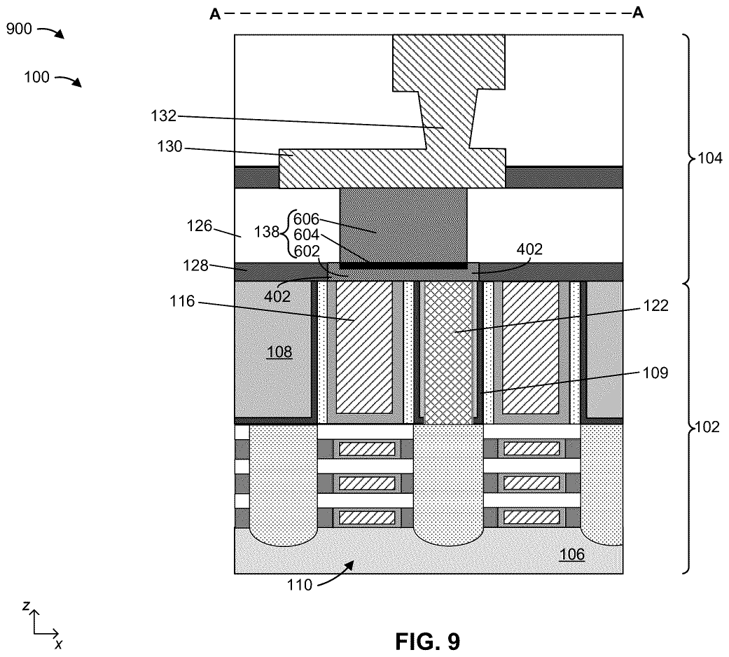

FIG. 9 is a diagram of an example 900 of an interconnect structure that may be included in the semiconductor device 100 described herein. FIG. 9 illustrates an example 900 of a merged interconnect structure 138. As shown in FIG. 9, the example 900 of the merged interconnect structure 138 may be similar to the example 600 of the merged interconnect structures 138 illustrated in FIG. 6A.

However, in the example 900 of the merged interconnect structure 138 illustrated in FIG. 9, the merged interconnect structure 138 includes protrusions in the ESL 128, similar to the example 400 of the merged interconnect structure 138 illustrated in FIG. 4A, in addition to the multiple-layer stack that includes the bottom layer 602, the oxide layer 604, and the top layer 606.

The protrusions 402 may be formed during formation of the seed layer 306 on which the top layer 606 of the multiple-layer stack is formed. In particular, the protrusions 402 may form due to lateral etching of the ends of the ESL 128 when sputtering the material of the seed layer 306 in the recess 302.

The oxide layer 604 may form due to exposure to oxygen after formation of the seed layer 306 and etching of the seed layer 306 to define the bottom layer 602.

As indicated above, FIG. 9 is provided as an example. Other examples may differ from what is described with regard to FIG. 9.

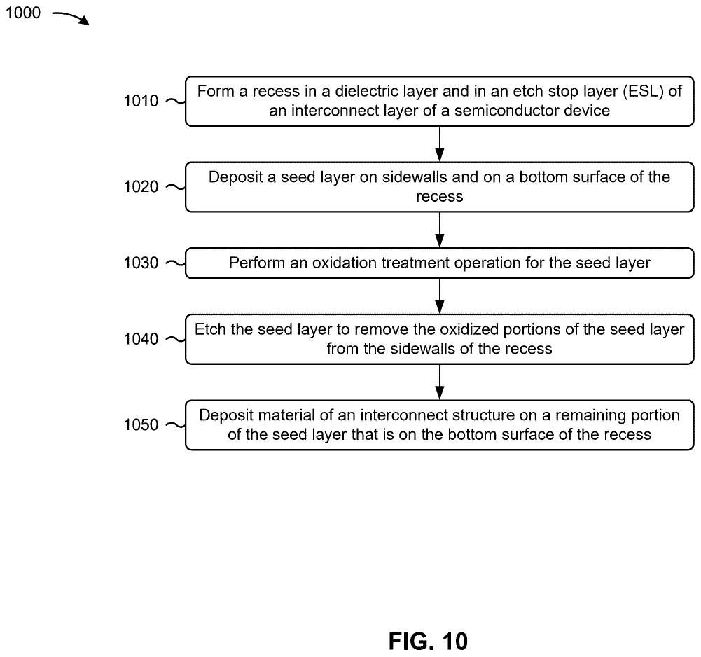

FIG. 10 is a flowchart of an example process 1000 associated with forming a semiconductor device described herein. In some implementations, one or more process blocks of FIG. 10 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 10, process 1000 may include forming a recess in a dielectric layer and in an ESL of an interconnect layer of a semiconductor device (block 1010). For example, one or more semiconductor processing tools may be used to form a recess (e.g., a recess 302, a recess 304) in a dielectric layer (e.g., an ILD layer 126) and in an ESL (e.g., an ESL 128) of an interconnect layer (e.g., an interconnect layer 104) of a semiconductor device (e.g., a semiconductor device 100), as described herein. In some implementations, the dielectric layer is above the ESL. In some implementations, the ESL is above a contact structure (e.g., a source/drain contact structure 122) and a gate structure (e.g., a gate structure 116) of an integrated circuit device (e.g., an integrated circuit device 110) in a device layer (e.g., a device layer 102) of the semiconductor device.

As further shown in FIG. 10, process 1000 may include depositing a seed layer on sidewalls and on a bottom surface of the recess (block 1020). For example, one or more semiconductor processing tools may be used to deposit a seed layer (e.g., a seed layer 306) on sidewalls and on a bottom surface of the recess, as described herein.

As further shown in FIG. 10, process 1000 may include performing an oxidation treatment operation for the seed layer (block 1030). For example, one or more semiconductor processing tools may be used to perform an oxidation treatment operation for the seed layer, as described herein. In some implementations, the oxidation treatment operation results in formation of oxidized portions of the seed layer on the sidewalls of the recess. In some implementations, the oxidized portions contain an oxide of a material of the seed layer.

As further shown in FIG. 10, process 1000 may include etching the seed layer to remove the oxidized portions of the seed layer from the sidewalls of the recess (block 1040). For example, one or more semiconductor processing tools may be used to etch the seed layer to remove the oxidized portions of the seed layer from the sidewalls of the recess, as described herein.

As further shown in FIG. 10, process 1000 may include depositing material of an interconnect structure on a remaining portion of the seed layer that is on the bottom surface of the recess (block 1050). For example, one or more semiconductor processing tools may be used to deposit material of an interconnect structure on a remaining portion (e.g., a remaining portion 308, a remaining portion 310) of the seed layer that is on the bottom surface of the recess, as described herein. In some implementations, the material of the interconnect structure grows on the remaining portion of the seed layer from a bottom of the recess to a top of the recess.

Process 1000 may include additional implementations, such as any single implementation or any combination of implementations described below and/or in connection with one or more other processes described elsewhere herein.

In a first implementation, performing the oxidation treatment operation includes performing the oxidation treatment operation using an oxygen-containing reactant that includes an oxygen-containing plasma.

In a second implementation, alone or in combination with the first implementation, performing the oxidation treatment operation includes performing the oxidation treatment operation using a hydrogen-containing plasma.

In a third implementation, alone or in combination with one or more of the first and second implementations, performing the oxidation treatment operation includes performing the oxidation treatment operation using an oxygen-containing reactant that includes an oxygen-containing gas.

In a fourth implementation, alone or in combination with one or more of the first through third implementations, the oxygen-containing gas includes at least one of oxygen (O₂), a nitrogen oxide (NₓO_{y}), or ozone (O₃).

In a fifth implementation, alone or in combination with one or more of the first through fourth implementations, performing the oxidation treatment operation includes performing the oxidation treatment operation using a wet oxygen-containing reactant.

In a sixth implementation, alone or in combination with one or more of the first through fifth implementations, the wet oxygen-containing reactant includes at least one of hydrochloric acid (HCL), ozone-deionized water, or sulfuric acid (H₂SO₄).

In a seventh implementation, alone or in combination with one or more of the first through sixth implementations, performing the oxidation treatment operation results in oxidation of ends of the ESL exposed in the recess.

In an eighth implementation, alone or in combination with one or more of the first through seventh implementations, performing the oxidation treatment operation results in oxidation of a top portion of the seed layer that is on the bottom surface of the recess, etching the seed layer to remove the oxidized portions of the seed layer includes etching the seed layer to remove the top portion of the seed layer from the bottom surface of the recess, where a bottom portion of the seed layer, that is on the bottom surface of the recess, remains unoxidized and corresponds to the remaining portion of the seed layer, and depositing the material of the interconnect structure on the remaining portion of the seed layer that is on the bottom surface of the recess includes depositing the material of the interconnect structure on the bottom portion of the seed layer that is on the bottom surface of the recess.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

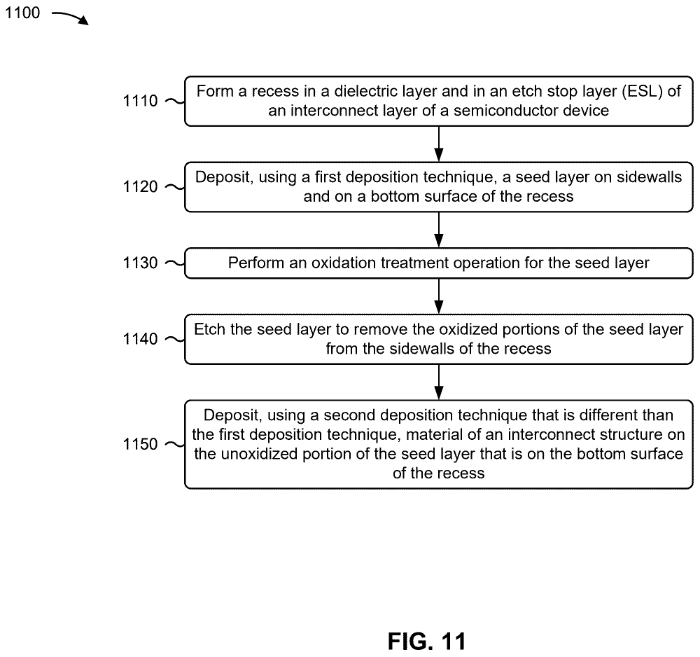

FIG. 11 is a flowchart of an example process 1100 associated with forming a semiconductor device described herein. In some implementations, one or more process blocks of FIG. 11 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 11, process 1100 may include forming a recess in a dielectric layer and in an ESL of an interconnect layer of a semiconductor device (block 1110). For example, one or more semiconductor processing tools may be used to form a recess (e.g., a recess 302, a recess 304) in a dielectric layer (e.g., an ILD layer 126) and in an ESL (e.g., an ESL 128) of an interconnect layer (e.g., an interconnect layer 104) of a semiconductor device (e.g., a semiconductor device 100), as described herein. In some implementations, the dielectric layer is above the ESL. In some implementations, the ESL is above a contact structure (e.g., a source/drain contact structure 122) and a gate structure (e.g., a gate structure 116) of an integrated circuit device (e.g., an integrated circuit device 110) in a device layer (e.g., a device layer 102) of the semiconductor device.

As further shown in FIG. 11, process 1100 may include depositing, using a first deposition technique, a seed layer on sidewalls and on a bottom surface of the recess (block 1120). For example, one or more semiconductor processing tools may be used to deposit, using a first deposition technique, a seed layer (e.g., a seed layer 306) on sidewalls and on a bottom surface of the recess, as described herein.

As further shown in FIG. 11, process 1100 may include performing an oxidation treatment operation for the seed layer (block 1130). For example, one or more semiconductor processing tools may be used to perform an oxidation treatment operation for the seed layer, as described herein. In some implementations, the oxidation treatment operation results in formation of oxidized portions of the seed layer on the sidewalls and the bottom surface of the recess. In some implementations, the oxidized portions contain an oxide of a material of the seed layer.

As further shown in FIG. 11, process 1100 may include etching the seed layer to remove the oxidized portions of the seed layer from the sidewalls of the recess (block 1140). For example, one or more semiconductor processing tools may be used to etch the seed layer to remove the oxidized portions of the seed layer from the sidewalls of the recess, as described herein. In some implementations, an unoxidized portion (e.g., a remaining portion 308, a remaining portion 310) of the seed layer remains on the bottom surface of the recess.

As further shown in FIG. 11, process 1100 may include depositing, using a second deposition technique that is different than the first deposition technique, material of an interconnect structure on the unoxidized portion of the seed layer that is on the bottom surface of the recess (block 1150). For example, one or more semiconductor processing tools may be used to deposit, using a second deposition technique that is different than the first deposition technique, material of an interconnect structure (e.g., a source/drain interconnect structure 134, a gate interconnect structure 136, a merged interconnect structure 138) on the unoxidized portion of the seed layer that is on the bottom surface of the recess, as described herein. In some implementations, the material of the interconnect structure grows on the unoxidized portion of the seed layer from a bottom of the recess to a top of the recess. In some implementations, the material of the interconnect structure and the material of the seed layer contain different fluorine (F) concentrations.

Process 1100 may include additional implementations, such as any single implementation or any combination of implementations described below and/or in connection with one or more other processes described elsewhere herein.

In a first implementation, etching the seed layer to remove the oxidized portions of the seed layer includes etching the seed layer using a gas-based etchant that contains a metal that is included in the material of the seed layer.

In a second implementation, alone or in combination with the first implementation, the gas-based etchant includes at least one of a chloride of the metal that is included in the material of the seed layer, or a fluoride of the metal that is included in the material of the seed layer.

In a third implementation, alone or in combination with one or more of the first and second implementations, etching the seed layer to remove the oxidized portions of the seed layer includes etching the seed layer using a gas-based etchant that contains a metal precursor that is used to deposit the material of the interconnect layer.

In a fourth implementation, alone or in combination with one or more of the first through third implementations, the material of the seed layer, the gas-based etchant, and the material of the interconnect structure contain a same metal element.

Although FIG. 11 shows example blocks of process 1100, in some implementations, process 1100 includes additional blocks, fewer blocks, different blocks, or differently arranged blocks than those depicted in FIG. 11. Additionally, or alternatively, two or more of the blocks of process 1100 may be performed in parallel.

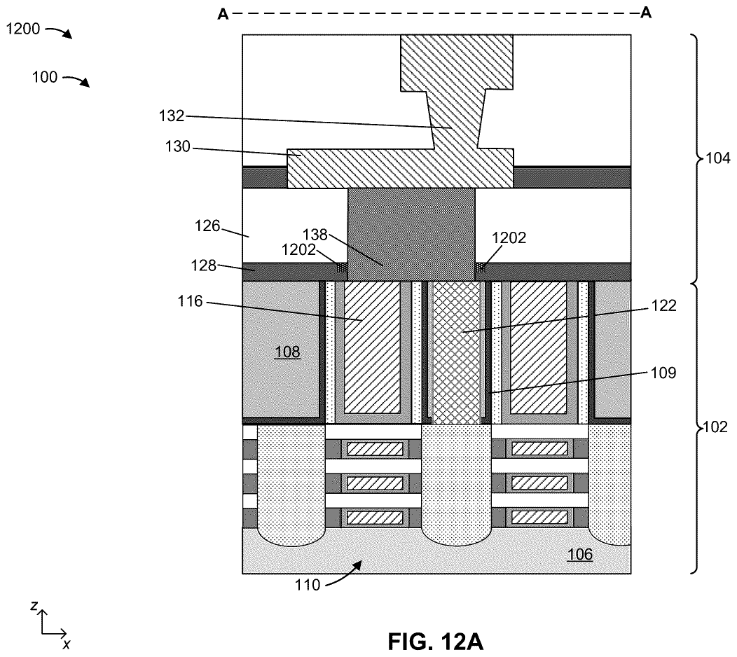

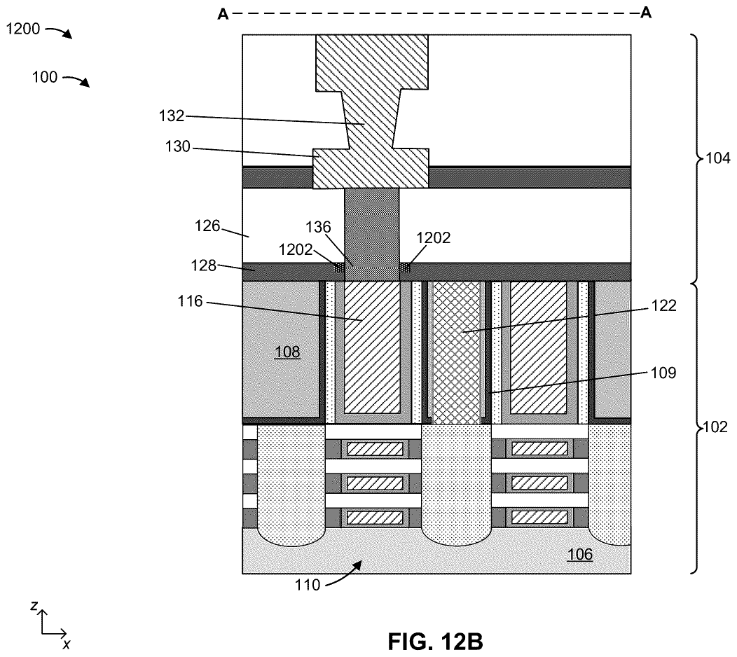

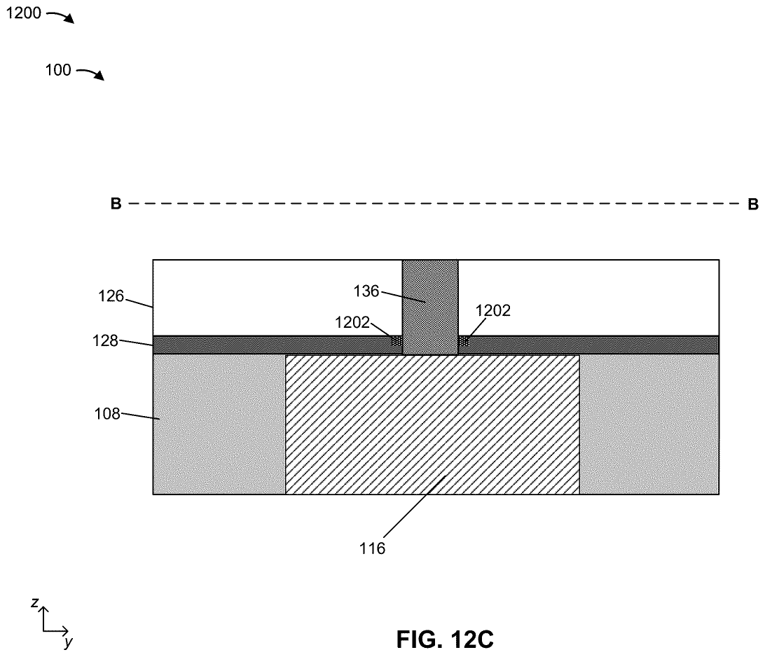

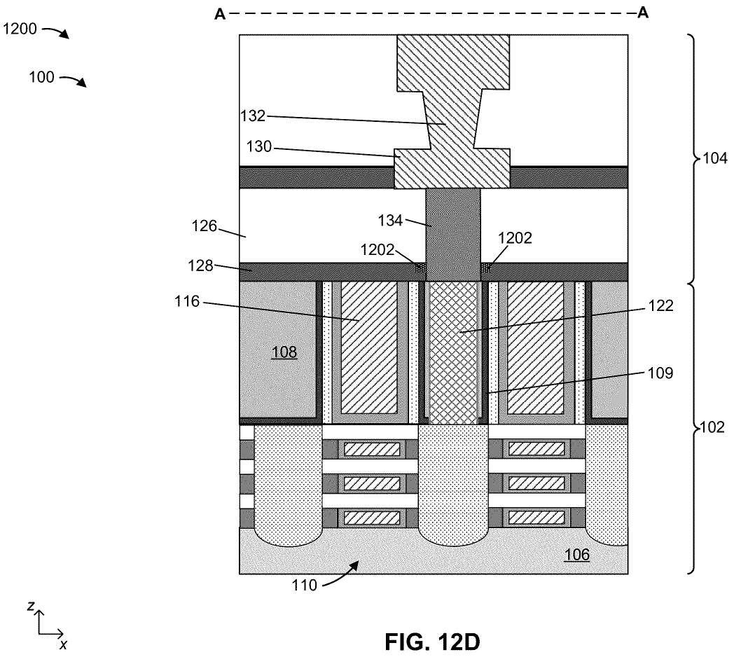

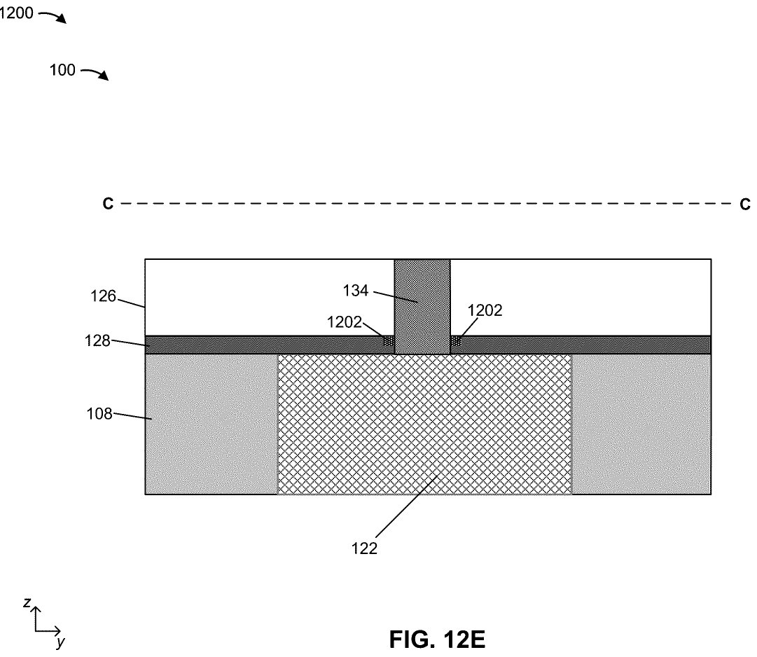

FIGS. 12A-12E are diagrams of examples 1200 of interconnect structures that may be included in the semiconductor device 100 described herein. FIG. 12A illustrates an example 1200 of a merged interconnect structure 138, FIGS. 12B and 12C illustrate an example 1200 of a gate interconnect structure 136, and FIGS. 12D and 12E illustrate an example 1200 of a source/drain interconnect structure 134.

As shown in FIGS. 12A-12E, the examples 1200 of the source/drain interconnect structure 134, the gate interconnect structure 136, and the merged interconnect structure 138 are similar to the source/drain interconnect structures 134, the gate interconnect structures 136, and the merged interconnect structures 138 illustrated in FIGS. 1A-1D. However, the examples 1200 of the source/drain interconnect structure 134, the gate interconnect structure 136, and the merged interconnect structure 138 each include oxidized regions 1202 in the ESL 128 around portions of the source/drain interconnect structure 134, the gate interconnect structure 136, and/or the merged interconnect structure 138. The oxidized regions 1202 are portions of the ESL 128 that were oxidized during the oxidation treatment operation performed for the seed layer 306 to oxidize portions of the seed layer 306. Oxygen from the oxygen source may penetrate through the seed layer 306 and into the ESL 128, thereby resulting in formation of the oxidized regions 1202 of the ESL 128, which may contain a higher oxygen concentration than other portions of the ESL 128. The portions of the ESL 128 around the remaining portions 308, 310 that were not oxidized during the oxidation treatment may remain unoxidized (or have minimal oxidation), and these portions of the ESL 128 may be located vertically between the oxidized region 1202 and underlying layers and/or structures, such as the dielectric layer 108, the gate structures 116, and/or the source/drain contact structures 122.

As indicated above, FIGS. 12A-12E are provided as examples. Other examples may differ from what is described with regard to FIGS. 12A-12E.

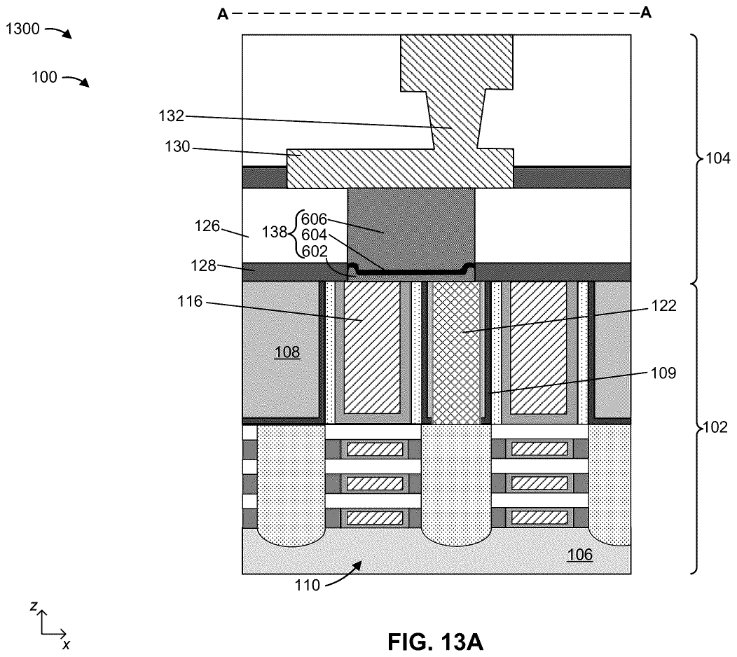

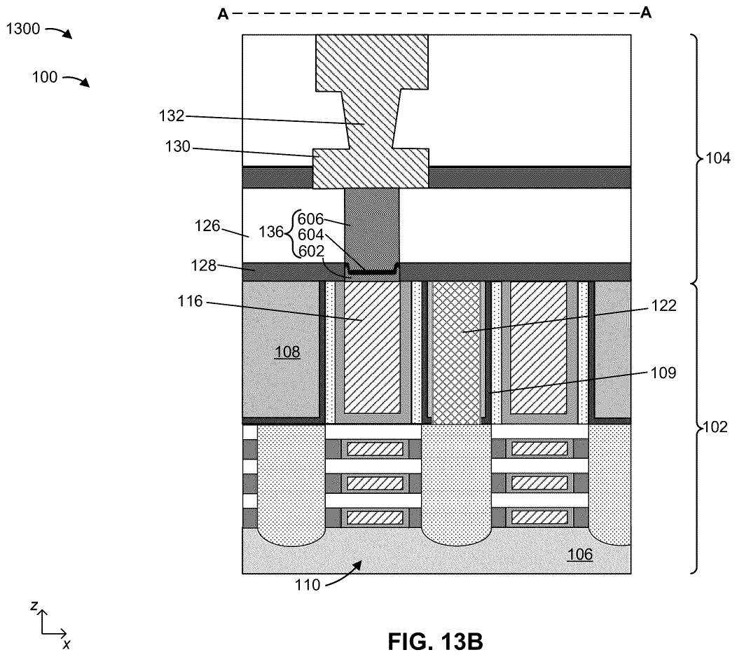

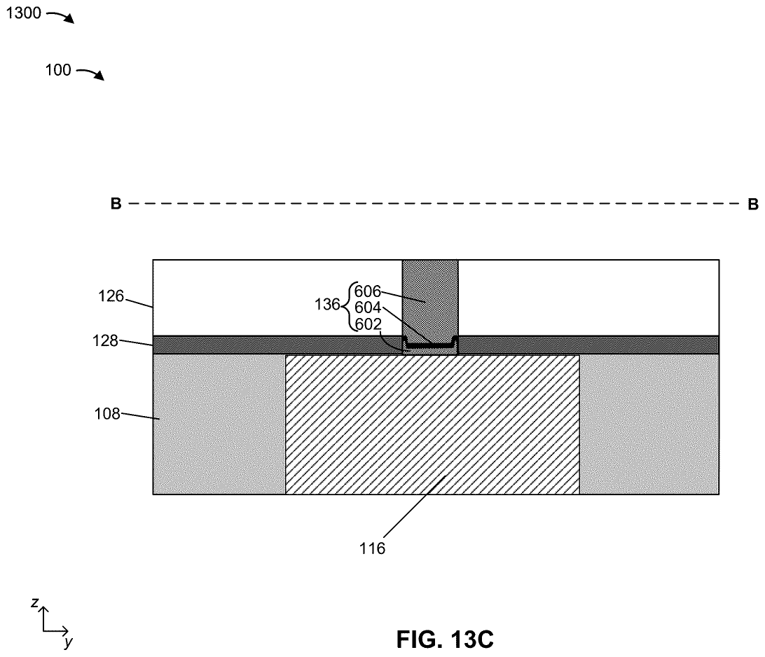

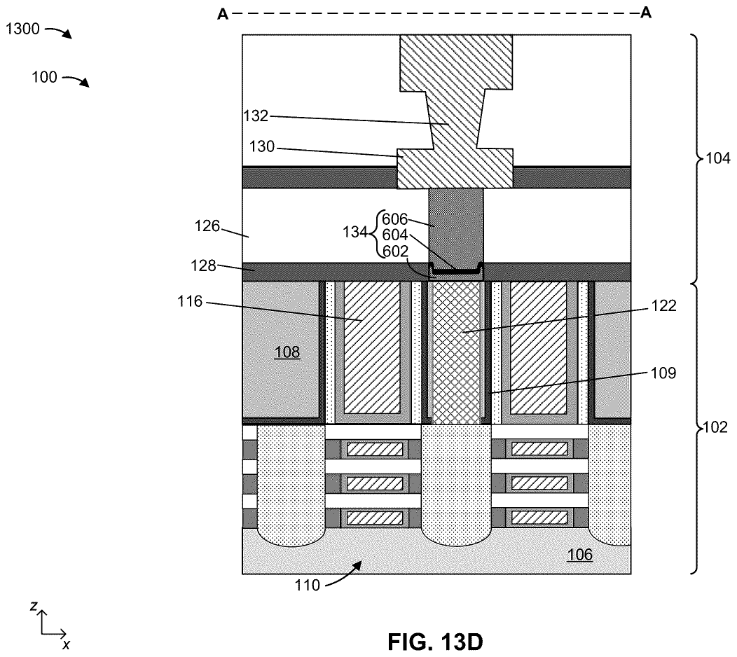

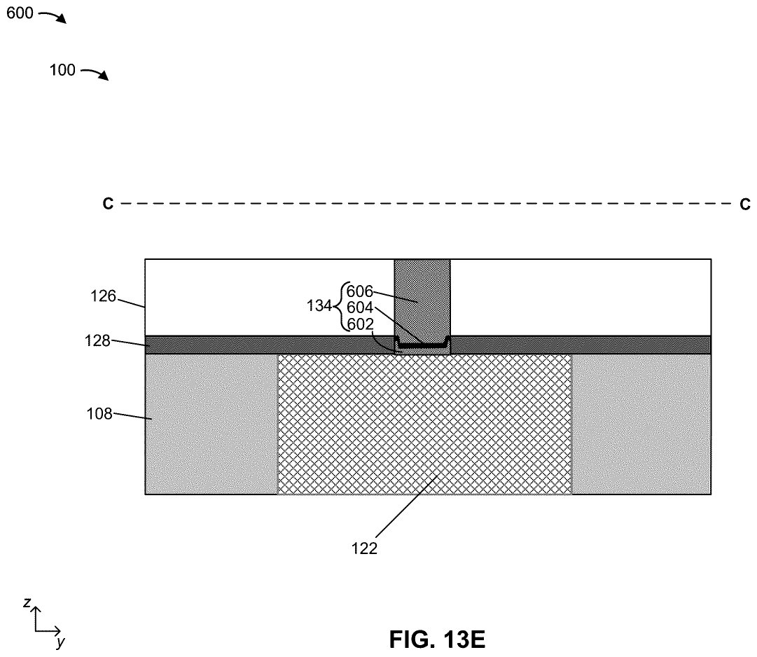

FIGS. 13A-13E are diagrams of examples 1300 of interconnect structures that may be included in the semiconductor device 100 described herein. FIG. 13A illustrates an example 1300 of a merged interconnect structure 138, FIGS. 13B and 13C illustrate an example 1300 of a gate interconnect structure 136, and FIGS. 13D and 13E illustrate an example 1300 of a source/drain interconnect structure 134.

As shown in FIGS. 13A-13E, the examples 1300 of the source/drain interconnect structure 134, the gate interconnect structure 136, and the merged interconnect structure 138 are similar to the examples 600 of the source/drain interconnect structures 134, the gate interconnect structures 136, and the merged interconnect structures 138 illustrated in FIGS. 6A-6E. However, the examples 1300 of the source/drain interconnect structure 134, the gate interconnect structure 136, and/or the merged interconnect structure 138 may have a bottom layer 602 that has a non-planar top surface. Therefore, the oxide layer 604 may also be non-planar and may conform to the non-planar top surface of the bottom layer 602. Moreover, the bottom surface of the top layer 606 may be non-planar and may conform to the non-planer oxide layer 604.

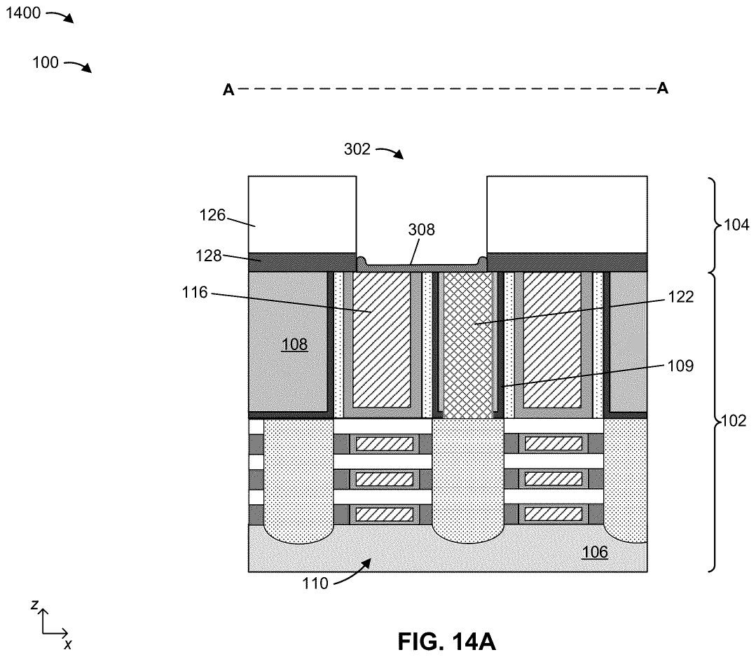

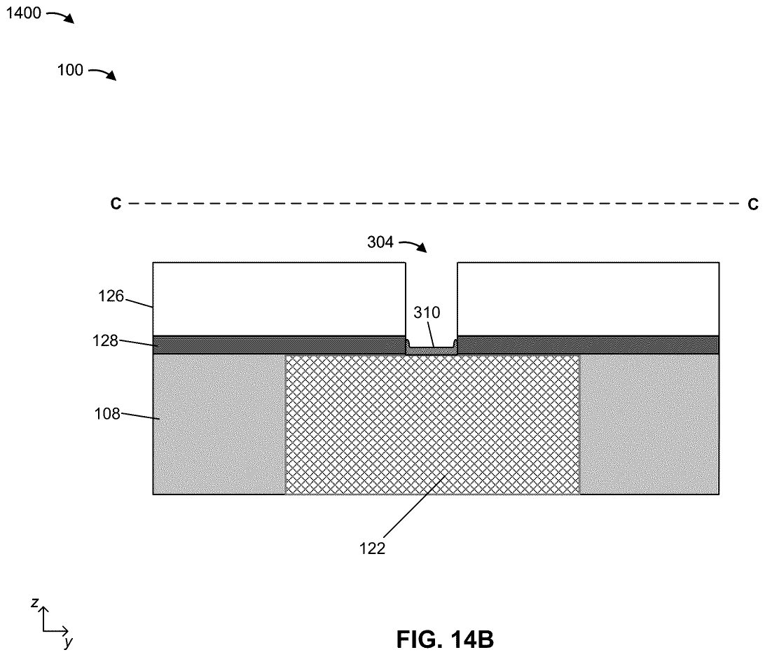

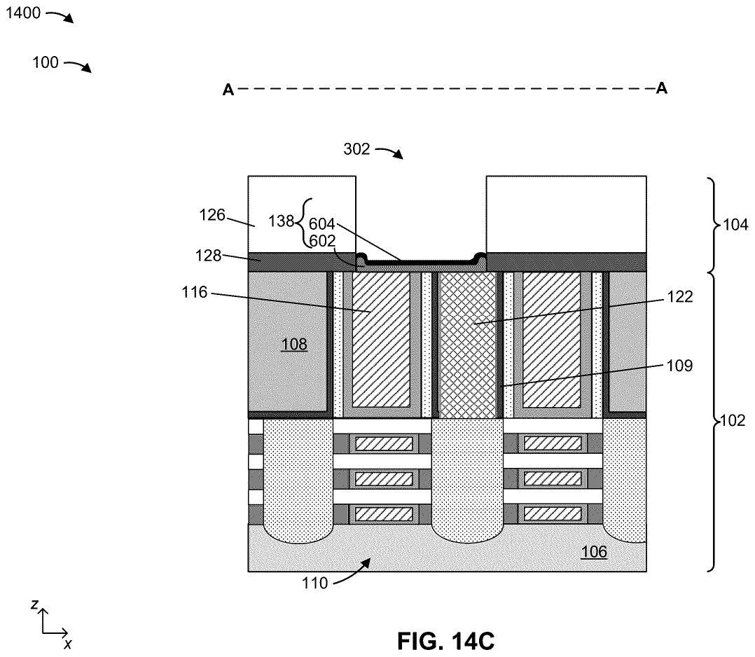

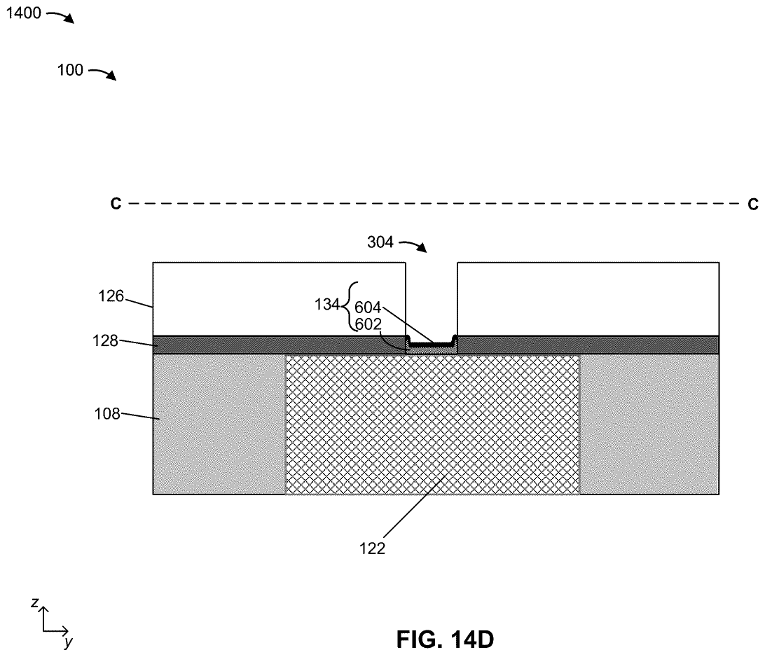

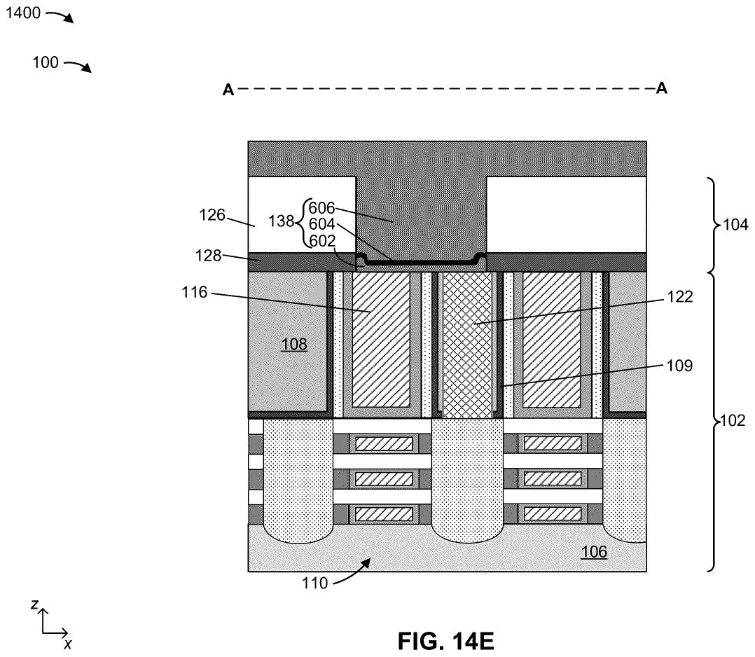

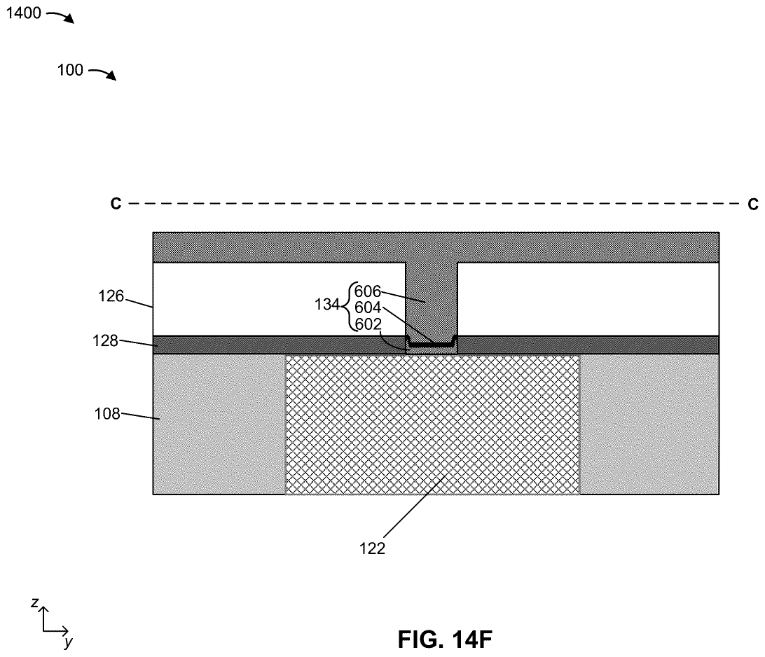

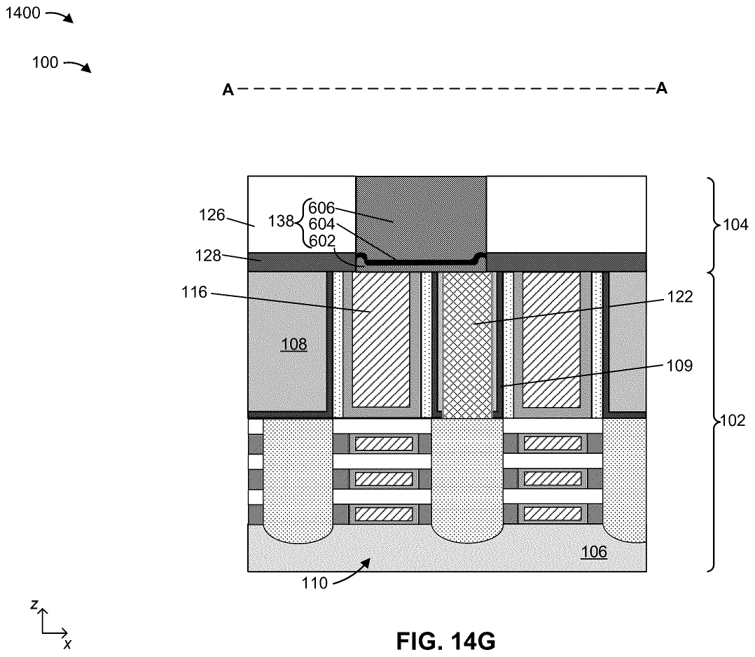

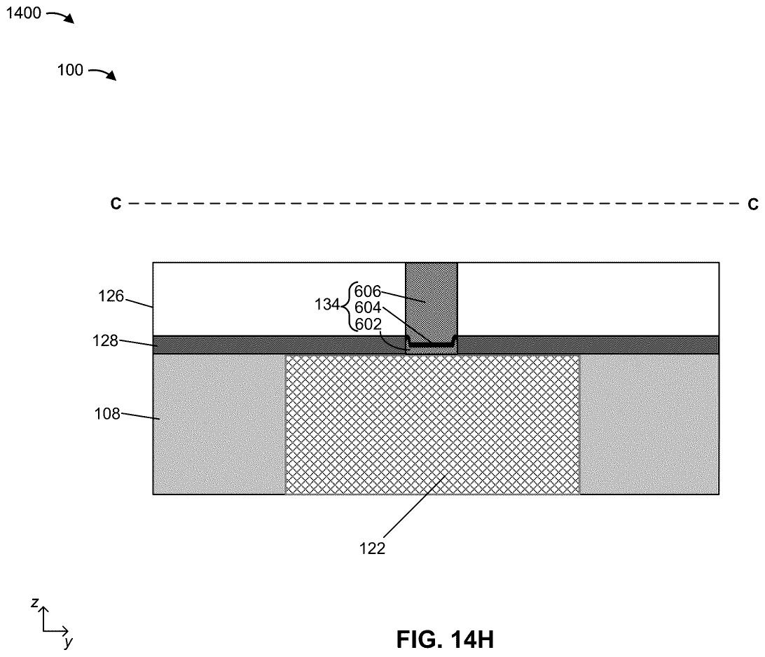

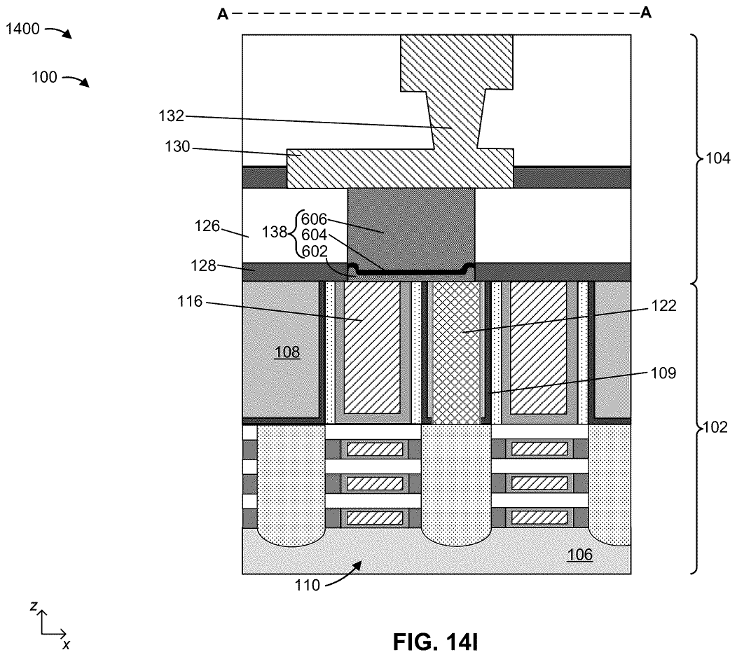

As described in greater detail in connection with FIGS. 14A-14I, the non-planar top surface of the bottom layer 602 of the source/drain interconnect structure 134, the gate interconnect structure 136, and/or the merged interconnect structure 138 may result from non-uniform oxidation when oxidizing the seed layer 306 and/or from non-uniform material removal rates when etching the oxidized portion of the seed layer 306. The oxidation rates and/or etch rates near the center of the recesses 302, 304 may be higher than at the edges of the recesses 302, 304.

As indicated above, FIGS. 13A-13E are provided as examples. Other examples may differ from what is described with regard to FIGS. 13A-13E.

FIGS. 14A-14I are diagrams of an example implementation 1400 of forming an interconnect layer 104 (or a portion thereof) of the semiconductor device 100 described herein. In particular, the example implementation 1400 includes an example of forming interconnect structures that include a multiple-layer stack, as illustrated in connection with FIGS. 13A-13E. In some implementations, one or more of the semiconductor processing operations described in connection with FIGS. 14A-14I may be performed after one or more processes described in connection with FIGS. 2A-2D. In some implementations, one or more of the semiconductor processing operations described in connection with FIGS. 14A-14I may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

As shown in FIGS. 14A and 14B, the first ILD layer 126, the first ESL 128, the recesses 302, 304, and the remaining portions 308, 310 of the seed layer 306 may be formed in a similar manner as described in connection with FIGS. 3A-3J. However, in the example implementation 1400, the oxidation and/or etching of the seed layer 306 may be non-uniform across the recesses 302, 304, thereby resulting in the top surfaces of the remaining portions 308, 310 being non-planar.

As shown in FIGS. 14C and 14D, the semiconductor device 100 may be transferred to a processing chamber of a deposition tool for depositing the material of the interconnect structures in the recesses 302, 304. When the semiconductor device 100 is transferred between processing chambers of semiconductor processing tools, the semiconductor device 100 may be exposed to various sources of oxygen, such as atmospheric oxygen. These various sources of oxygen may cause a thin layer of oxide material, corresponding to the oxide layers 604 of the source/drain interconnect structures 134, the gate interconnect structures 136, and/or the merged interconnect structures 138 to form on the bottom layers 602 (which may correspond to the remaining portions 308, 310 of the seed layer 306) of the source/drain interconnect structures 134, the gate interconnect structures 136, and/or the merged interconnect structures 138. In particular, the metal material of the remaining portions 308, 310 of the seed layer 306 may be exposed to oxygen, resulting in oxidation of the surfaces of the remaining portions 308, 310 of the seed layer 306, which results in formation of the oxide layers 604. The oxide layers 604 may conform to the non-planar profile of the bottom layers 602, and may therefore also have a non-planar profile.

As shown in FIGS. 14E and 14F, the material of the top layers 606 of the interconnect structures may be deposited on the oxide layers 604 above the bottom layers 602 in the recesses 302, 304 so that the interconnect structures grow on the bottom layers 602. For example, and as shown in FIG. 14E, the material of the merged interconnect structure 138 may be deposited on the oxide layer 604 that is on the bottom layer 602 (e.g., the remaining portion 308 of the seed layer 306) at the bottom of the recess 302 to achieve bottom-up growth of the merged interconnect structure 138 in the recess 302. As another example, and as shown in FIG. 14F, the material of the source/drain interconnect structure 134 may be deposited on the oxide layer 604 that is on the bottom layer 602 (e.g., the remaining portion 310 of the seed layer 306) at the bottom of the recess 304 to achieve bottom-up growth of the source/drain interconnect structure 134 in the recess 304. The material of a gate interconnect structure 136 may be deposited on an oxide layer 604 that is on a bottom layer 602 (e.g., a remaining portion of the seed layer 306) to achieve bottom-up growth in a similar manner.

The material of the interconnect structures may be deposited in a similar manner as described in connection with FIGS. 3K and 3L. However, in the example implementation 1400, the material of the interconnect structures conform to the non-planar oxide layers 604 such that the bottom surface of the top layer 606 of the source/drain contact structure 134 conforms to the oxide layer 604 of the source/drain contact structure 134 (and is therefore non-planar), the bottom surface of the top layer 606 of the gate interconnect structure 136 conforms to the oxide layer 604 of the gate interconnect structure 136 (and is therefore non-planar), and/or the bottom surface of the top layer 606 of the merged interconnect structure 138 conforms to the oxide layer 604 of the merged interconnect structure 138 (and is therefore non-planar).

In some implementations, the material of the seed layer 306 (and thus, the material of the bottom layers 602) and the material of the top layers 606 are deposited using different deposition techniques. For example, the material of the seed layer 306 (and thus, the material of the bottom layers 602) may be deposited using a PVD technique so that the seed layer 306 (and thus, the material of the bottom layers 602) is substantially fluorine-free and substantially chlorine-free. The material of the top layers 606 may instead be deposited using a CVD technique or another chemical-based deposition technique to achieve a high step coverage to minimize void formation in the source/drain interconnect structures 134, the gate interconnect structures 136, and the merged interconnect structures 138. The CVD technique may involve the use of chemical precursors of the material of the top layers 606, which may contain fluorine (F) and/or chlorine (Cl). Thus, the material of the top layers 606 may have a greater fluorine concentration and/or a greater chlorine concentration than the material of the bottom layers 602.

As shown in FIGS. 14G and 14H, the top layers 606 of the interconnect structures may be planarized using a planarization tool. In this way, the top surfaces of the top layers 606 are approximately co-planar with the top surface of the ILD layer 126.

As shown in FIG. 14I, additional layers of the interconnect layer 104 of the semiconductor device 100 may be formed above the layer of interconnect structures (e.g., the layer that includes the source/drain interconnect structures 134, the gate interconnect structures 136, the merged interconnect structures 138). The additional layers of the interconnect layer 104 may be formed in a similar manner as described in connection with FIG. 3O.

As indicated above, FIGS. 14A-14I are provided as an example. Other examples may differ from what is described with regard to FIGS. 14A-14I.

In this way, electrically conductive material of an interconnect structure (e.g., a source/drain interconnect structure, a gate interconnect structure) in an interconnect layer of a semiconductor device is deposited in a manner that reduces the likelihood of void formation in the interconnect structure. A recess may be formed in a dielectric layer in the interconnect layer. A seed layer may be deposited on sidewalls and on a bottom surface of the recess. An oxidation treatment operation may be performed to oxidize portions of the seed layer on the sidewalls of the recess, and an etch operation may be performed to etch the seed layer to remove the oxidized portions of the seed layer from the sidewalls. The remaining portions of the seed layer at the bottom of the recess is then used as a base on which additional material of the interconnect structure is deposited. The seed layer at the bottom of the recess facilitates bottom-up growth of the interconnect structure with minimal to now growth from the sidewalls of the recess, which reduces the likelihood that the electrically conductive material will coalesce at the top of the recess and form a void. In this way, the interconnect structure may be formed substantially free of voids, which enables a low electrical resistance to be achieved for the interconnect structure and reduces the likelihood of an electrical open circuit being formed in the interconnect structure. This enables a high performance and a high yield to be achieved for semiconductor devices formed on a semiconductor substrate.

As described in greater detail above, some implementations described herein provide a method. The method includes forming a recess in a dielectric layer and in an ESL of an interconnect layer of a semiconductor device, where the dielectric layer is above the ESL, and where the ESL is above a contact structure and a gate structure of an integrated circuit device in a device layer of the semiconductor device. The method includes depositing a seed layer on sidewalls and on a bottom surface of the recess. The method includes performing an oxidation treatment operation for the seed layer, where the oxidation treatment operation results in formation of oxidized portions of the seed layer on the sidewalls of the recess, and where the oxidized portions contain an oxide of a material of the seed layer. The method includes etching the seed layer to remove the oxidized portions of the seed layer from the sidewalls of the recess. The method includes depositing material of an interconnect structure on a remaining portion of the seed layer that is on the bottom surface of the recess, where the material of the interconnect structure grows on the remaining portion of the seed layer from a bottom of the recess to a top of the recess.

As described in greater detail above, some implementations described herein provide a method. The method includes forming a recess in a dielectric layer and in an ESL of an interconnect layer of a semiconductor device, where the dielectric layer is above the ESL, and where the ESL is above a contact structure and a gate structure of an integrated circuit device in a device layer of the semiconductor device. The method includes depositing, using a first deposition technique, a seed layer on sidewalls and on a bottom surface of the recess. The method includes performing an oxidation treatment operation for the seed layer, where the oxidation treatment operation results in formation of oxidized portions of the seed layer on the sidewalls and the bottom surface of the recess, and where the oxidized portions contain an oxide of a material of the seed layer. The method includes etching the seed layer to remove the oxidized portions of the seed layer from the sidewalls of the recess, where an unoxidized portion of the seed layer remains on the bottom surface of the recess. The method includes depositing, using a second deposition technique that is different than the first deposition technique, material of an interconnect structure on the unoxidized portion of the seed layer that is on the bottom surface of the recess, where the material of the interconnect structure grows on the unoxidized portion of the seed layer from a bottom of the recess to a top of the recess, and where the material of the interconnect structure and the material of the seed layer contain different fluorine concentrations.

As described in greater detail above, some implementations described herein provide a semiconductor device. The semiconductor device includes a device layer. The semiconductor device includes an integrated circuit device in the device layer. The semiconductor device includes an interconnect layer, over the integrated circuit device, that includes a plurality of ILD layers and a plurality of ESLs interleaving the plurality of ILD layers. The interconnect layer includes a plurality of metallization structures in the plurality of ILD layers and a plurality of interconnect structures. A first interconnect structure of the plurality of interconnect structures extends vertically through a first ESL of the plurality of ESLs and a first ILD layer of the plurality of ILD layers to couple two or more of the plurality of metallization structure. A second interconnect structure extends vertically through a second ESL of the plurality of ESLs and a second ILD layer of the plurality of ILD layers to couple the integrated circuit device to the interconnect layer. A first dielectric constant of the second ESL is greater than a second dielectric constant of the second ILD layer. A lateral width of a first portion of the second interconnect structure in the second ESL is greater than a lateral width of a second portion of the second interconnect structure in the second ILD layer.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a recess in a dielectric layer and in an etch stop layer (ESL) of an interconnect layer of a semiconductor device,
wherein the dielectric layer is above the ESL, and
wherein the ESL is above a contact structure and a gate structure of an integrated circuit device in a device layer of the semiconductor device;
depositing a seed layer on sidewalls and on a bottom surface of the recess;
performing an oxidation treatment operation for the seed layer,
wherein the oxidation treatment operation results in formation of oxidized portions of the seed layer on the sidewalls of the recess, and
wherein the oxidized portions contain an oxide of a material of the seed layer;
etching the seed layer to remove the oxidized portions of the seed layer from the sidewalls of the recess; and
depositing material of an interconnect structure on a remaining portion of the seed layer that is on the bottom surface of the recess,
wherein the material of the interconnect structure grows on the remaining portion of the seed layer from a bottom of the recess to a top of the recess.

2. The method of claim 1, wherein performing the oxidation treatment operation comprises:
performing the oxidation treatment operation using an oxygen-containing reactant that includes an oxygen-containing plasma.

3. The method of claim 2, wherein performing the oxidation treatment operation comprises:
performing the oxidation treatment operation using a hydrogen-containing plasma.

4. The method of claim 1, wherein performing the oxidation treatment operation comprises:
performing the oxidation treatment operation using an oxygen-containing reactant that includes an oxygen-containing gas.

5. The method of claim 4, wherein the oxygen-containing gas comprises at least one of:
oxygen (O₂),
a nitrogen oxide (NₓO_{y}), or
ozone (O₃).

6. The method of claim 1, wherein performing the oxidation treatment operation comprises:
performing the oxidation treatment operation using a wet oxygen-containing reactant.

7. The method of claim 6, wherein the wet oxygen-containing reactant comprises at least one of:
hydrochloric acid (HCL),
ozone-deionized water, or
sulfuric acid (H₂SO₄).

8. The method of claim 1, wherein performing the oxidation treatment operation results in oxidation of a top portion of the seed layer that is on the bottom surface of the recess;
wherein etching the seed layer to remove the oxidized portions of the seed layer comprises:
etching the seed layer to remove the top portion of the seed layer from the bottom surface of the recess,
wherein a bottom portion of the seed layer, that is on the bottom surface of the recess, remains unoxidized and corresponds to the remaining portion of the seed layer.

9. The method of claim 8, wherein depositing the material of the interconnect structure on the remaining portion of the seed layer that is on the bottom surface of the recess comprises:
depositing the material of the interconnect structure on the bottom portion of the seed layer that is on the bottom surface of the recess.

10. A method, comprising:
forming a recess in a dielectric layer and in an etch stop layer (ESL) of an interconnect layer of a semiconductor device,
wherein the dielectric layer is above the ESL, and
wherein the ESL is above a contact structure and a gate structure of an integrated circuit device in a device layer of the semiconductor device;
depositing, using a first deposition technique, a seed layer on sidewalls and on a bottom surface of the recess;
performing an oxidation treatment operation for the seed layer,
wherein the oxidation treatment operation results in formation of oxidized portions of the seed layer on the sidewalls and the bottom surface of the recess, and
wherein the oxidized portions contain an oxide of a material of the seed layer;
etching the seed layer to remove the oxidized portions of the seed layer from the sidewalls of the recess,
wherein an unoxidized portion of the seed layer remains on the bottom surface of the recess; and
depositing, using a second deposition technique that is different than the first deposition technique, material of an interconnect structure on the unoxidized portion of the seed layer that is on the bottom surface of the recess,
wherein the material of the interconnect structure grows on the unoxidized portion of the seed layer from a bottom of the recess to a top of the recess, and
wherein the material of the interconnect structure and the material of the seed layer contain different fluorine concentrations.

11. The method of claim 10, wherein etching the seed layer to remove the oxidized portions of the seed layer comprises:
etching the seed layer using a gas-based etchant that contains a metal that is included in the material of the seed layer.

12. The method of claim 11, wherein the gas-based etchant comprises at least one of:
a chloride of the metal that is included in the material of the seed layer, or
a fluoride of the metal that is included in the material of the seed layer.

13. The method of claim 10, wherein etching the seed layer to remove the oxidized portions of the seed layer comprises:
etching the seed layer using a gas-based etchant that contains a metal precursor that is used to deposit the material of the interconnect layer.

14. The method of claim 13, wherein the material of the seed layer, the gas-based etchant, and the material of the interconnect structure contain a same metal element.

15. A semiconductor device, comprising:
a device layer;
an integrated circuit device in the device layer; and
an interconnect layer, over the integrated circuit device, comprising:
a plurality of interlayer dielectric (ILD) layers;
a plurality of etch stop layers (ESLs) interleaving the plurality of ILD layers;
a plurality of metallization structures in the plurality of ILD layers; and
a plurality of interconnect structures,
wherein a first interconnect structure of the plurality of interconnect structures extends vertically through a first ESL of the plurality of ESLs and a first ILD layer of the plurality of ILD layers to couple two or more of the plurality of metallization structures,
wherein a second interconnect structure extends vertically through a second ESL of the plurality of ESLs and a second ILD layer of the plurality of ILD layers to couple the integrated circuit device to the interconnect layer,
wherein a first dielectric constant of the second ESL is greater than a second dielectric constant of the second ILD layer, and
wherein a lateral width of a first portion of the second interconnect structure in the second ESL is greater than a lateral width of a second portion of the second interconnect structure in the second ILD layer.

16. The semiconductor device of claim 15, wherein the second interconnect structure further comprises:
an oxide layer vertically between the first portion and the second portion.

17. The semiconductor device of claim 16, wherein the oxide layer contains an oxide of a metal of the second interconnect structure.

18. The semiconductor device of claim 16, wherein the oxide layer is non-planar.

19. The semiconductor device of claim 18, wherein the oxide layer comprises a plurality of segments; and
wherein an angle between a first set of segments of the plurality of segments, and an angle between a second set of segments of the plurality of segments, are different angles.

20. The semiconductor device of claim 15, wherein a fluorine concentration of the second portion is greater than a fluorine concentration of the first portion.
